(19) United States
(12) Patent Application Publication
(10) Pub. No.: US 2026/0353552 A1
(43) Pub. Date: Nov. 5, 2026

(54) FOLDABLE SUBSTRATES, FOLDABLE APPARATUS, AND METHODS OF MAKING

(71) Applicant: CORNING INCORPORATED, CORNING, NY (US)

(72) Inventors: Gabriel Pierce Agnello, Corning, NY (US); Joy Banerjee, Corning, NY (US); Jared Kittleson, Corning, NY (US); Konstantin Sergeevich Koreshkov, Espoo (FI); Balamurugan Meenakshi Sundaram, Painted Post, NY (US); Vitor Marino Schneider, Painted Post, NY (US)

(21) Appl. No.: 19/662,358

(22) Filed: Apr. 29, 2026

Related U.S. Application Data
(60) Provisional application No. 63/798,273, filed on May 1, 2025.
(60) Provisional application No. 64/003,618, filed on Mar. 12, 2026.

(51) Int. Cl. H05K 1/02; G06F 1/16; H05K 3/00

(52) U.S. Cl. CPC H05K 1/028; G06F 1/1616; H05K 3/002; H05K 3/0055; H05K 2201/055; H05K 2201/10136

(57) ABSTRACT

Foldable substrates and foldable apparatus containing the same have a central portion positioned between a first portion and a second portion. The central portion has a central thickness less than a substrate thickness in the first portion and the second portion. In aspects, a lithium difference between a central concentration at a central midpoint minus a first concentration of lithium oxide at a first midpoint of the first portion is from 0.2 mol % to 2 mol %. In aspects, a central surface larger alkali difference between a first central concentration at the first central surface area and a central concentration at the central midpoint of a larger alkali can be from 4 mol % to 14 mol %. Methods include buckling a substrate by chemically strengthening the substrate and then etching the substrate to produce a foldable substrate with a central portion that is free of buckling.

### CROSS-REFERENCE TO RELATED APPLICATIONS

This application claims the benefit of priority under 35 U.S.C. § 119 of U.S. Provisional Application Ser. No. 64/003,618 filed on Mar. 12, 2026 and U.S. Provisional Application Ser. No. 63/798,273 filed on May 1, 2025, the contents of each of which are relied upon and incorporated herein by reference in their entireties.

### FIELD

The present disclosure relates generally to foldable substrates, foldable apparatus, and methods of making and, more particularly, to foldable substrates comprising a non-zero concentration profile of lithium oxide, foldable apparatus including foldable substrates, and methods of making foldable substrates comprising multiple ion-exchange treatments.

### BACKGROUND

Glass-based substrates are commonly used, for example, in display devices, for example, liquid crystal displays (LCDs), electrophoretic displays (EPD), organic light-emitting diode displays (OLEDs), plasma display panels (PDPs), or the like.

There is a desire to develop foldable versions of displays as well as foldable protective covers to mount on foldable displays. Foldable displays and covers should have good impact and puncture resistance. At the same time, foldable displays and covers should have a small parallel plate distance (e.g., 10 millimeters (mm) or less). However, plastic displays and covers with a small parallel plate distance tend to have poor impact and/or puncture resistance. Consequently, there is a need to develop foldable apparatus that have low minimum parallel plate distance, good impact resistance, good puncture resistance, and free of buckling.

### SUMMARY

There are set forth herein foldable apparatus comprising foldable substrates, foldable substrates, and method of making the same comprising a first portion, a second portion, and a central portion positioned therebetween. The foldable substrate can comprise a glass-based and/or ceramic-based material, which can provide good dimensional stability, reduced incidence of mechanical instabilities, good impact resistance, and/or good puncture resistance. The glass-based and/or ceramic-based material of the foldable substrate comprises one or more compressive stress regions, which can further provide increased impact resistance and/or increased puncture resistance while simultaneously facilitating good folding performance. Providing foldable substrates comprising a central portion comprising a central thickness that is less than a substrate thickness (e.g., first thickness of the first portion and/or second thickness of the second portion) (e.g., by 10 μm or more) can enable a small parallel plate distance (e.g., 10 millimeters or less) based on the reduced thickness in the central portion, which can enable the foldability and/or rollability of the foldable substrate and/or foldable apparatus.

The present disclosure demonstrates that buckling-free and low warp foldable substrates can be obtained that have high compressive stress in the central portion. It has unexpectedly been demonstrated that a foldable substrate can be formed from a precursor (e.g., strengthened substrate) with a buckled central portion that is etched to become free of buckling. Previously, it was thought to be beneficial to avoid buckling throughout the entire process of making a foldable substrate because it was believed that buckling could not be undone once induced due to the non-linear behavior that occurs when the critical buckling strain is exceeded. However, allowing the presence of buckling during methods of the present disclosure enables higher compressive stress to be achieved for foldable substrates (and through methods of present disclosure). Further, the resulting foldable substrate herein can be closer to the critical buckling strain than previously thought possible that have a low warp and a free of buckling. Additionally, as demonstrated herein, foldable substrates that are free of buckling and have low warp can be achieved through a series of chemical strengthening steps.

Additionally, methods of present disclosure allow for the formation of foldable substrates without masks or other barriers during the chemical strengthening steps. Consequently, in aspects, a first depth of layer in the first portion can be equal to a first central depth of layer in the central portion, and/or a first maximum compressive stress in the first portion can be substantially equal to a first central maximum compressive stress in the central portion. Providing a first depth of layer that is equal to the first central depth of layer can be consistent with the first portion and the central portion being subjected to similar and/or simultaneous chemical strengthening treatment(s).

Foldable substrates can have a higher concentration of lithium at a midpoint of the central portion having the central thickness than at the midpoint of the first portion having the substrate thickness such that the foldable substrate exhibits a non-zero central surface lithium difference. Without wishing to be bound by theory, the central surface lithium difference can reflect the final chemical strengthening treatment performed since the alkali metal ions (including lithium) exchanged between the substrate and the corresponding molten salt solution are located near the surface, especially when the duration of the corresponding chemical strengthening treatment is short. Consequently, a negative central surface lithium difference can correspond to a final (e.g., second) chemical strengthening treatment having less (compared to an earlier chemical strengthening treatment) or even being substantially free of lithium. Further, a negative central surface lithium difference in combination with a positive midpoint lithium difference can correspond to or otherwise be consistent with the methods of the present disclosure since (1) an earlier (e.g., first) chemical strengthening treatment added lithium through the central portion (including the central midpoint) but that earlier chemical strengthening treatment did not add lithium throughout the entire first portion (including the first midpoint) and (2) the molten salt solution for the final (e.g., second, later) chemical strengthening treatment had lower lithium concentration than the earlier chemical strengthening treatments (and/or the molten salt bath for the later chemical strengthening treatment was substantially free of lithium) and/or high amounts of a larger alkali metal ion (e.g., the alkali metal described by the depth of compression associated with the corresponding compressive stress regions).

Providing from 0.1 wt % to 2.0 wt % (e.g., from 0.25 wt % to 1.0 wt %, from 0.45 wt % to 0.85 wt %) of a lithium salt in the first molten salt solution can generate an expansion-induced strain difference between the first portion and the second portion that is opposite of that normally encountered when chemically strengthening a foldable substrate having a central portion thinner than an adjacent first portion since lithium has the opposite effect of the larger alkali metal. This can be the case even when the first molten salt solution comprises both the lithium salt and a larger alkali metal salt (e.g., potassium salt). It is believed that without the lithium salt in the first molten salt bath it would not be possible to achieve the compressive stress and mechanical performance of the resulting foldable substrate without buckling or severe warping of the central portion and/or making the central portion frangible, especially when no masks or other barriers are placed between any portion of the foldable substrate and the corresponding molten salt solution throughout the chemical strengthening steps herein.

As demonstrated by the Examples herein, the etching can remove enough of the corresponding compressive stress region(s) (including the near-surface portions potentially having the highest concentration of the larger alkali metal oxide) to reduce the expansion-induced strain experience by the central portion below the critical buckling strain, which is evidenced by the absence of buckling in the resulting foldable substrate.

Some example aspects of the disclosure are described below with the understanding that any of the features of the various aspects may be used alone or in combination with one another.

Aspect 1. A foldable apparatus comprising a substrate comprising:
a substrate thickness defined between a first major surface and a second major surface opposite the first major surface, the substrate comprising a glass-based material;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface;
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, the first central surface area is recessed from the first major surface by a first distance, and the central thickness is less than the substrate thickness;
a midpoint lithium difference defined as a central concentration of lithium oxide at a central midpoint of the central portion minus a first concentration of lithium oxide at a first midpoint of the first portion is from greater than or equal to 0.2 mol % to less than or equal to 2 mol %, wherein the central midpoint is midway between the first central surface area and the second central surface area, and the first midpoint is midway between the first major surface and the second major surface in the first portion; and
a central surface larger alkali difference defined as a first central surface concentration of a larger alkali metal oxide at the first central surface area minus a central concentration of the larger alkali metal oxide at the central midpoint is from greater than or equal to 4 mol % to less than or equal to 14 mol %, wherein the larger alkali metal oxide is selected from a group of potassium oxide, rubidium oxide, cesium oxide, and francium oxide.

Aspect 2. The foldable apparatus of aspect 1, wherein a ratio of the midpoint lithium difference to the central surface larger alkali difference is from greater than or equal to 0.01 to less than or equal to 0.40.

Aspect 3. The foldable apparatus of any one of aspects 1-2, wherein a central surface lithium difference defined as a first central surface concentration of lithium oxide minus the central concentration of lithium oxide at the central midpoint of the central portion is from greater than or equal to −0.5 mol % to less than or equal to 0.5 mol %, wherein the central midpoint is midway between the first central surface area and the second central surface area, and the first midpoint is midway between the first major surface and the second major surface in the first portion.

Aspect 4. The foldable apparatus of aspect 3, wherein a ratio of the central surface lithium difference to the central surface larger alkali difference is from greater than or equal to −0.13 to less than or equal to 0.13.

Aspect 5. A foldable apparatus comprising a substrate comprising:
a substrate thickness defined between a first major surface and a second major surface opposite the first major surface, the substrate comprising a glass-based material;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface;
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, the first central surface area is recessed from the first major surface by a first distance, and the central thickness is less than the substrate thickness;
a midpoint lithium difference defined as a central concentration of lithium oxide at a central midpoint of the central portion minus a first concentration of lithium oxide at a first midpoint of the first portion is from greater than or equal to 0.2 mol % to less than or equal to 2 mol %, wherein the central midpoint is midway between the first central surface area and the second central surface area, and the first midpoint is midway between the first major surface and the second major surface in the first portion; and
a central surface mixed alkali difference defined as a first central surface concentration of a sum of sodium oxide and a larger alkali metal oxide at the first central surface area minus a central concentration of a sum of sodium oxide and the larger alkali metal oxide at the central midpoint is from greater than or equal to −0.5 mol % to less than or equal to 0.5 mol %, wherein the larger alkali metal oxide is selected from a group of potassium oxide, rubidium oxide, cesium oxide, and francium oxide.

Aspect 6. The foldable apparatus of aspect 5, wherein an absolute value of a ratio of the midpoint lithium difference to the central surface mixed alkali difference is from greater than or equal to 0.4 to less than or equal to 50.

Aspect 7. The foldable apparatus of any one of aspects 5-6, wherein a central surface lithium difference defined as a first central surface concentration of lithium oxide minus the central concentration of lithium oxide at the central midpoint of the central portion is from greater than or equal to −0.5 mol % to less than or equal to 0.5 mol %, wherein the central midpoint is midway between the first central surface area and the second central surface area, and the first midpoint is midway between the first major surface and the second major surface in the first portion.

Aspect 8. The foldable apparatus of aspect 7, wherein a ratio of the central surface lithium difference to the central surface mixed alkali difference is from greater than or equal to 0.7 to less than or equal to 1.5.

Aspect 9. The foldable apparatus of any one of aspects 1-8, wherein the larger alkali metal oxide is potassium oxide.

Aspect 10. The foldable apparatus of any one of aspects 1-9, wherein a surface profile of the first central surface area along a midline midway between the first portion and the second portion exhibits a warp of less than or equal to 1 millimeter.

Aspect 11. The foldable apparatus of aspect 10, wherein the surface profile of the first central surface area has an average gradient of less than or equal to 0.018 mm/mm.

Aspect 12. The foldable apparatus of any one of aspects 10-11, wherein the surface profile of the central portion has a maximum local curvature of less than or equal to 5 Diopters.

Aspect 13. The foldable apparatus of any one of aspects 1-9, wherein a surface profile of the first central surface area has an average gradient of less than or equal to 0.018 mm/mm.

Aspect 14. The foldable apparatus of any one of aspects 1-9, wherein a surface profile of the central portion has a maximum local curvature of less than or equal to 5 Diopters.

Aspect 15. The foldable apparatus of any one of aspects 1-9, wherein the first central surface area is substantially parabolic or substantially planar.

Aspect 16. The foldable apparatus of any one of aspects 1-15, wherein the central portion is free of buckling.

Aspect 17. The foldable apparatus of any one of aspects 1-16, wherein a first maximum compressive stress at the first major surface is from greater than or equal to 600 MegaPascals to less than or equal to 1,500 MegaPascals, and a first central maximum compressive stress at the first central surface area is from greater than or equal to 600 MegaPascals to less than or equal to 1,500 MegaPascals.

Aspect 18. A foldable apparatus comprising a substrate comprising:
a substrate thickness defined between a first major surface and a second major surface opposite the first major surface, the substrate comprising a glass-based material;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface;
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, the first central surface area is recessed from the first major surface by a first distance, and the central thickness is less than the substrate thickness, wherein a central midpoint is located midway between the first central surface area and the second central surface area, and a first midpoint is located midway between the first major surface and the second major surface in the first portion; and
a surface profile of the first central surface area along a midline midway between the first portion and the second portion, wherein the surface profile exhibits a warp of less than or equal to 1 millimeter, and the central portion is free of buckling,
wherein a first maximum compressive stress at the first major surface is from greater than or equal to 600 MegaPascals to less than or equal to 1,500 MegaPascals, and a first central maximum compressive stress at the first central surface area is from greater than or equal to 600 MegaPascals to less than or equal to 1,500 MegaPascals.

Aspect 19. A foldable apparatus comprising a substrate comprising:
a substrate thickness defined between a first major surface and a second major surface opposite the first major surface, the substrate comprising a glass-based material;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface;
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, the first central surface area is recessed from the first major surface by a first distance, and the central thickness is less than the substrate thickness, wherein a central midpoint is located midway between the first central surface area and the second central surface area, and a first midpoint is located midway between the first major surface and the second major surface in the first portion; and
a surface profile of the first central surface area along a midline midway between the first portion and the second portion, wherein the surface profile exhibits a warp of less than or equal to 1 millimeter, and the central portion further exhibits one or more of an average gradient of less than or equal to 0.018 mm/mm or a maximum local curvature of less than or equal to 5 Diopters,
wherein a first maximum compressive stress at the first major surface is from greater than or equal to 600 MegaPascals to less than or equal to 1,500 MegaPascals, and a first central maximum compressive stress at the first central surface area is from greater than or equal to 600 MegaPascals to less than or equal to 1,500 MegaPascals.

Aspect 20. The foldable apparatus of aspect 19, wherein the central portion is free of buckling.

Aspect 21. The foldable apparatus of aspect 18, wherein the surface profile of the first central surface area has an average gradient of less than or equal to 0.018 mm/mm.

Aspect 22. The foldable apparatus of aspect 18 or aspect 21, wherein the surface profile of the central portion has a maximum local curvature of less than or equal to 5 Diopters.

Aspect 23. The foldable apparatus of any one of aspects 18-22, wherein the first central surface area is substantially parabolic or substantially planar.

Aspect 24. The foldable apparatus of any one of aspects 18-23, wherein a midpoint lithium difference defined as a central concentration of lithium oxide at the central midpoint of the central portion minus a first concentration of lithium oxide at the first midpoint of the first portion is from greater than or equal to 0.2 mol % to less than or equal to 2 mol %.

Aspect 25. The foldable apparatus of any one of aspects 18-23, wherein a central surface lithium difference defined as a first central surface concentration of lithium oxide minus a central concentration of lithium oxide at the central midpoint of the central portion is from greater than or equal to −0.5 mol % to less than or equal to 0.5 mol %.

Aspect 26. The foldable apparatus of any one of aspects 18-25, wherein a central surface larger alkali difference defined as a first central surface concentration of a larger alkali metal oxide at the first central surface area minus a central concentration of the larger alkali metal oxide at the central midpoint is from greater than or equal to 4 mol % to less than or equal to 14 mol %, wherein the larger alkali metal oxide is selected from a group of potassium oxide, rubidium oxide, cesium oxide, and francium oxide.

Aspect 27. The foldable apparatus of aspect 26, wherein a ratio of the midpoint lithium difference to the central surface larger alkali difference is from greater than or equal to 0.02 to less than or equal to 1.0.

Aspect 28. The foldable apparatus of aspect 26, wherein a ratio of the central surface lithium difference to the central surface larger alkali difference is from greater than or equal to −0.13 to less than or equal to 0.13, wherein the central surface lithium difference is defined as a first central surface concentration of lithium oxide minus the central concentration of lithium oxide at the central midpoint of the central portion.

Aspect 29. The foldable apparatus of any one of aspects 17-28, wherein the first maximum compressive stress is from greater than or equal to 700 MegaPascals to less than or equal to 1,300 MegaPascals, and the first central maximum compressive stress is from greater than or equal to 700 MegaPascals to less than or equal to 1,300 MegaPascals.

Aspect 30. The foldable apparatus of any one of aspects 17-29, wherein an absolute value of a difference between the first maximum compressive stress and the first central maximum compressive stress is from greater than or equal to 0 MegaPascals to less than or equal to 100 MegaPascals.

Aspect 31. The foldable apparatus of any one of aspects 17-30, comprising a first depth of layer of the larger alkali metal oxide in the first portion from the first major surface, a first central depth of layer of the larger alkali metal oxide in the central portion from the first central surface area, wherein a ratio of the first depth of layer to the first central depth of layer is from greater than or equal to 0.7 to less than or equal to 1.5.

Aspect 32. The foldable apparatus of any one of aspects 17-30, wherein a first depth of layer of the larger alkali metal oxide in the first compressive stress region is from greater than or equal to 4 micrometers to less than or equal to 10 micrometers, and a first central depth of layer of the larger alkali metal oxide in the first central compressive stress region is from greater than or equal to 4 micrometers to less than or equal to 10 micrometers.

Aspect 33. The foldable apparatus of any one of aspects 1-32, wherein the foldable substrate achieves a parallel plate distance of 10 millimeters.

Aspect 34. The foldable apparatus of any one of aspects 1-33, wherein the foldable substrate comprises a minimum parallel plate distance from greater than or equal to 0.5 millimeters to less than or equal to 10 millimeters.

Aspect 35. The foldable apparatus of any one of aspects 1-34, wherein the central thickness is from greater than or equal to 20 micrometers to less than or equal to 120 micrometers, the substrate thickness as a multiple of the central thickness is from greater than or equal to 2 to less than or equal to 200.

Aspect 36. The foldable apparatus of any one of aspects 1-35, wherein the central thickness is from greater than or equal to 25 micrometers to less than or equal to 75 micrometers, and the central thickness is from greater than or equal to 75 micrometers to less than or equal to 3 millimeters.

Aspect 37. The foldable apparatus of any one of aspects 1-36, wherein the first distance is from 25% to 70% of the substrate thickness.

Aspect 38. The foldable apparatus of any one of aspects 1-37, wherein the second major surface is coplanar with the second central surface area.

Aspect 39. The foldable apparatus of any one of aspects 1-37, wherein the second central surface area is recessed from the second major surface by a second distance, the second distance is from 25% to 45% of the substrate thickness, and the first distance is from 25% to 45%.

Aspect 40. A consumer electronic device comprising:
a housing comprising a front surface, a back surface, and side surfaces;
electrical components at least partially within the housing, the electrical components comprising a controller, a memory, and a display, the display is at or adjacent to the front surface of the housing; and
a cover substrate disposed over the display,
wherein at least one of a portion of the housing or the cover substrate comprises the foldable apparatus of any one of aspects 1-39.

Aspect 42. A method of making a foldable substrate comprising:
chemically strengthening a substrate in a first molten salt solution maintained at from greater than or equal to 350 °C to less than or equal to 500 °C for a first period of time from greater than or equal to 1 minute to less than or equal to 0.5 hours to form an intermediate substrate, the first molten salt solution comprises from greater than or equal to 0.1 wt % to less than or equal to 2.0 wt % of a lithium salt based on 100 wt % of the first molten salt solution, the substrate being chemically strengthened comprises:
an existing first major surface and an existing second major surface opposite the first major surface present in a first portion and a second portion; and
a central portion positioned between the first portion and the second portion, the central portion comprising an existing central thickness defined between an existing first central surface area and an existing second central surface area opposite the existing first central surface area, the existing first central surface area is recessed from the existing first major surface by an existing first distance;
immersing the intermediate substrate in a second molten salt solution comprising a potassium salt maintained at from greater than or equal to 350 °C to less than or equal to 500 °C for a second period of time from greater than or equal to 1 minute to less than or equal to 0.5 hours to form a strengthened substrate; and then
etching the strengthened substrate with an etchant solution to remove at least a first outer layer from the existing first central surface area having a first outer thickness from greater than or equal to 10 nanometers to less than or equal to 10 micrometers to form the foldable substrate,
wherein the foldable substrate is a glass-based substrate comprising:
   the first portion comprising a substrate thickness, a first compressive stress region extending to a first depth of compression from a first major surface, a second compressive stress region extending to a second depth of compression from a second major surface;
   the second portion comprising the substrate thickness, a third compressive stress region extending to a third depth of compression from the first major surface, a fourth compressive stress region extending to a fourth depth of compression from the second major surface; and
   the central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from a second central surface area, the first central surface area is recessed from the first major surface by a first distance, and the central thickness is less than the substrate thickness.

Aspect 43. The method of aspect 42, wherein the central portion of the strengthened substrate is buckled, and the central portion of the foldable substrate is free of buckling.

Aspect 44. The method of aspect 42, wherein a surface profile of the central portion of the strengthened substrate has a maximum local curvature of greater than or equal to 5 Diopters, and a surface profile of the central portion of the foldable substrate has a maximum local curvature of less than or equal to 5 Diopters, and the surface profile of the first central surface area is taken along a midline midway between the first portion and the second portion.

Aspect 45. The method of aspect 42, wherein the existing first central surface area of the strengthened substrate is non-planar and non-parabolic, and the first central surface area of the foldable substrate is substantially parabolic or substantially planar.

Aspect 46. The method of any one of aspects 42-45, wherein a surface profile of the first central surface area along a midline midway between the first portion and the second portion of the foldable substrate exhibits a warp of less than or equal to 1 millimeter.

Aspect 47. The method of any one of aspects 42-46, wherein a surface profile of the first central surface area along a midline midway between the first portion and the second portion of the foldable substrate exhibits an average gradient of less than or equal to 0.018 mm/mm.

Aspect 48. The method of any one of aspects 42-47, wherein the first molten salt solution comprises, based on 100 wt % of the first molten salt solution, from greater than or equal to 95 wt % to less than or equal to 99.9 wt % of a potassium salt.

Aspect 49. The method of any one of aspects 42-48, wherein the first molten salt solution comprises, based on 100 wt % of the first molten salt solution, from greater than or equal to 0.45 wt % to less than or equal to 0.85 wt % of the lithium salt.

Aspect 50. The method of any one of aspects 42-49, wherein the first period of time is from greater than or equal to 1 minute to less than or equal to 5 minutes, and the first temperature is from greater than or equal to 370 °C to less than or equal to 430 °C.

Aspect 51. The method of any one of aspects 42-50, wherein the first molten salt solution simultaneously contacts the existing first major surface and the existing first central surface area.

Aspect 52. The method of any one of aspects 42-51, wherein the substrate is substantially unstrengthened prior to the chemically strengthening the substrate in the first molten salt solution.

Aspect 53. The method of any one of aspects 42-52, wherein the second molten salt solution comprises, based on 100 wt % of the second molten salt solution, from greater than or equal to 95 wt % to less than or equal to 100 wt % of the potassium salt.

Aspect 54. The method of any one of aspects 42-52, wherein the first molten salt solution comprises, based on 100 wt % of the first molten salt solution:
from greater than or equal to 20 wt % to less than or equal to 80 wt % of a sodium salt; and
from greater than or equal to 20 wt % to less than or equal to 80 wt % of a potassium salt.

Aspect 55. The method of any one of aspects 42-54, wherein the second period of time is from greater than or equal to 1 minute to less than or equal to 5 minutes, and the second temperature is from greater than or equal to 370 °C to less than or equal to 430 °C.

Aspect 56. The method of any one of aspects 42-55, wherein the second molten salt solution simultaneously contacts the existing first major surface and the existing first central surface area.

Aspect 57. The method of any one of aspects 42-56, wherein the first outer thickness removed by the etching is from greater than or equal to 100 nanometers to less than or equal to 2 micrometers.

Aspect 58. The method of any one of aspects 42-57, wherein the central thickness is from greater than or equal to 20 micrometers to less than or equal to 120 micrometers, the substrate thickness as a multiple of the central thickness is from greater than or equal to 2 to less than or equal to 200.

Aspect 59. The method of aspect 58, wherein the central thickness is from greater than or equal to 25 micrometers to less than or equal to 75 micrometers, and the central thickness is from greater than or equal to 75 micrometers to less than or equal to 3 millimeters.

Aspect 60. The method of any one of aspects 42-59, wherein the first distance is from 25% to 70% of the substrate thickness.

Aspect 61. The method of any one of aspects 42-60, wherein the second major surface is coplanar with the second central surface area.

Aspect 62. The method of any one of aspects 42-60, wherein the second central surface area is recessed from the second major surface by a second distance, the second distance is from 25% to 45% of the substrate thickness, and the first distance is from 25% to 45%.

Aspect 63. The method of any one of aspects 42-62, wherein the first maximum compressive stress of the first compressive stress region is from greater than or equal to 700 MegaPascals to less than or equal to 1300 MegaPascals, and a first central maximum compressive stress of the first central compressive stress region is from greater than or equal to 700 MegaPascals to less than or equal to 1300 MegaPascals.

Aspect 64. The method of any one of aspects 42-63, wherein an absolute value of a difference between the first maximum compressive stress and the first central maximum compressive stress is from greater than or equal to 0 MegaPascals to less than or equal to 100 MegaPascals.

Aspect 65. The method of any one of aspects 42-64, comprising a first depth of layer of potassium oxide in the first portion from the first major surface, a first central depth of layer of potassium oxide in the central portion from the first central surface area, wherein a ratio of the first depth of layer to the first central depth of layer is from greater than or equal to 0.7 to less than or equal to 1.5.

Aspect 66. The method of any one of aspects 42-64, wherein a first depth of layer of potassium oxide in the first compressive stress region is from greater than or equal to 4 micrometers to less than or equal to 10 micrometers, and a first central depth of layer of potassium oxide in the first central compressive stress region is from greater than or equal to 4 micrometers to less than or equal to 10 micrometers.

Aspect 67. The method of any one of aspects 42-66, wherein the foldable substrate achieves a parallel plate distance of 10 millimeters.

Aspect 68. The method of any one of aspects 42-66, wherein the foldable substrate comprises a minimum parallel plate distance from greater than or equal to 0.5 millimeters to less than or equal to 10 millimeters.

Aspect 69. The method of any one of aspects 42-68, wherein the foldable substrate comprises:
a midpoint lithium difference defined as a central concentration of lithium oxide at a central midpoint of the central portion minus a first concentration of lithium oxide at a first midpoint of the first portion is from greater than or equal to 0.2 mol % to less than or equal to 2 mol %, wherein the central midpoint is midway between the first central surface area and the second central surface area, and the first midpoint is midway between the first major surface and the second major surface in the first portion; and
a central surface larger alkali difference defined as a first central surface concentration of potassium oxide at the first central surface area minus a central concentration of potassium oxide at the central midpoint is from greater than or equal to 4 mol % to less than or equal to 14 mol %.

Aspect 70. The method of aspect 69, wherein a ratio of the midpoint lithium difference to the central surface larger alkali difference is from greater than or equal to 0.02 to less than or equal to 1.0.

Aspect 71. The method of any one of aspects 42-70, wherein the foldable substrate exhibits a central surface lithium difference defined as a first central surface concentration of lithium oxide minus the central concentration of lithium oxide at the central midpoint of the central portion is from greater than or equal to −0.5 mol % to less than or equal to 0.5 mol %, wherein the central midpoint is midway between the first central surface area and the second central surface area, and the first midpoint is midway between the first major surface and the second major surface in the first portion.

Aspect 72. The method of aspect 71, wherein a ratio of the central surface lithium difference to the central surface larger alkali difference is from greater than or equal to −0.13 to less than or equal to 0.13.

Aspect 73. The method of any one of aspects 42-68, wherein the foldable substrate comprises:
a midpoint lithium difference defined as a central concentration of lithium oxide at a central midpoint of the central portion minus a first concentration of lithium oxide at a first midpoint of the first portion is from greater than or equal to 0.2 mol % to less than or equal to 2 mol %, wherein the central midpoint is midway between the first central surface area and the second central surface area, and the first midpoint is midway between the first major surface and the second major surface in the first portion; and
a central surface mixed alkali difference defined as a first central surface concentration of a sum of sodium oxide and potassium oxide at the first central surface area minus a central concentration of a sum of sodium oxide and potassium oxide at the central midpoint is from greater than or equal to −0.5 mol % to less than or equal to 0.5 mol %.

Aspect 74. The method of aspect 73, wherein ana absolute value of a ratio of the midpoint lithium difference to the central surface mixed alkali difference is from greater than or equal to 0.4 to less than or equal to 50.

Aspect 75. The method of any one of aspects 42-74, wherein the second molten salt solution is substantially free of lithium before contacting the initially strengthened substrate with the second molten salt solution.

Aspect 76. A foldable substrate produced by the method of any one of aspects 42-75.

Aspect 77. A consumer electronic device comprising:
a housing comprising a front surface, a back surface, and side surfaces;
electrical components at least partially within the housing, the electrical components comprising a controller, a memory, and a display, the display is at or adjacent to the front surface of the housing; and
a cover substrate disposed over the display,
wherein at least one of a portion of the housing or the cover substrate comprises the foldable substrate produced by the method of any one of aspects 42-75.

Aspect 78. The method of any one of aspects 42-77, wherein the foldable substrate exhibits a failure strength of 1965 MegaPascals or more.

Aspect 79. The method of aspect 78, wherein the failure strength is from greater than or equal to 1990 MegaPascals to less than or equal to 2500 MegaPascals.

Aspect 80. The method of any one of aspects 42-79, wherein the foldable substrate exhibits a puncture resistance as measured in a Quasi-Static Puncture Test of 0.61 kgf or more.

Aspect 81. The method of aspect 80, wherein the puncture resistance is 0.66 kgf or more.

Aspect 82. The method of any one of aspects 42-81, wherein the foldable substrate exhibits a flaw depth of 0.3 micrometers or less.

Aspect 83. The method of aspect 82, wherein the flaw depth is 0.20 micrometers or less.

Aspect 84. The foldable apparatus of any one of aspects 1-36, wherein the foldable substrate exhibits a failure strength of 1965 MegaPascals or more.

Aspect 85. The foldable apparatus of aspect 84, wherein the failure strength is from greater than or equal to 1990 MegaPascals to less than or equal to 2500 MegaPascals.

Aspect 86. The foldable apparatus of any one of aspects 1-36 and 84-85 inclusive, wherein the foldable substrate exhibits a puncture resistance as measured in a Quasi-Static Puncture Test of 0.61 kgf or more.

Aspect 87. The foldable apparatus of aspect 86, wherein the puncture resistance is 0.66 kgf or more.

Aspect 88. The foldable apparatus of any one of aspects 1-36 and 84-87 inclusive, wherein the foldable substrate exhibits a flaw depth of 0.3 micrometers or less.

Aspect 89. The foldable apparatus of aspect 88, wherein the flaw depth is 0.20 micrometers or less.

Aspect 90. The method of any one of aspects 42-75, wherein the first outer thickness is from greater than or equal to 0.5 micrometers to less than or equal to 1.0 micrometer.

Aspect 91. The method of any one of aspects 42-75 and 90 inclusive, wherein the foldable substrate exhibits a failure strength of 1965 MegaPascals or more.

Aspect 92. The method of aspect 91, wherein the failure strength is from greater than or equal to 1990 MegaPascals to less than or equal to 2500 MegaPascals.

Aspect 93. The method of any one of aspects 42-75 and 90-92 inclusive, wherein the foldable substrate exhibits a puncture resistance as measured in a Quasi-Static Puncture Test of 0.61 kgf or more.

Aspect 94. The method of aspect 93, wherein the puncture resistance is 0.66 kgf or more.

Aspect 95. The method of any one of aspects 42-75 and 90-94 inclusive, wherein the foldable substrate exhibits a flaw depth of 0.3 micrometers or less.

Aspect 96. The method of aspect 95, wherein the flaw depth is 0.20 micrometers or less.

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### BRIEF DESCRIPTION OF THE DRAWINGS

The above and other features and advantages of aspects of the present disclosure are better understood when the following detailed description is read with reference to the accompanying drawings, in which:

FIG. 1 is a schematic view of an example foldable apparatus in a flat configuration according to aspects, wherein a schematic view of the folded configuration may appear as shown in FIG. 4;

FIG. 2 is a cross-sectional view of the foldable apparatus along line 2-2 of FIG. 1 including a foldable substrate having a pair of recesses opposite on another in accordance with aspects of the present disclosure;

FIG. 3 is a cross-sectional view of the foldable apparatus along line 2-2 of FIG. 1 including another foldable substrate having a single recess in accordance with aspects of the present disclosure;

FIG. 4 is a schematic view of example foldable apparatus of aspects of the disclosure in a folded configuration wherein a schematic view of the flat configuration may appear as shown in FIG. 1;

FIG. 5 is a cross-sectional view of a testing apparatus to determine the minimum parallel plate distance of an example foldable substrate along line 5-5 of FIG. 4;

FIG. 6 is a cross-sectional view of a testing apparatus to determine the minimum parallel plate distance of an example foldable substrate having a pair of recesses opposite one another in accordance with aspects of the present disclosure;

FIG. 7 is a schematic plan view of an example consumer electronic device according to aspects;

FIG. 8 is a schematic perspective view of the example consumer electronic device of FIG. 7;

FIG. 9 is a schematic perspective view of a foldable consumer electronic product;

FIG. 10 is a flow chart illustrating example methods making a foldable substrate and/or a foldable apparatus in accordance with aspects of the disclosure;

FIG. 11 schematically illustrates chemically strengthening a substrate having at least one recess to form an intermediate substrate in a step of methods of making a a foldable substrate and/or a foldable apparatus;

FIG. 12 schematically illustrates further chemically strengthening an intermediate substrate foldable substrate having at least one recess to form a strengthened substrate in a step of methods of making a foldable substrate and/or a foldable apparatus;

FIG. 13 schematically illustrates etching the strengthened substrate having at least one recess to form a foldable substrate in a step of methods of making a foldable substrate and/or a foldable apparatus;

FIG. 14 schematically illustrates strain difference (Δε) in parts-per-million (ppm) on the vertical axis (i.e., y-axis) as a function of lithium nitrate (LiNO₃) concentration in weight percent (wt %) of the first molten salt solution on the horizontal axis (i.e., x-axis) for examples in accordance with aspects of the present disclosure;

FIG. 15 schematically illustrates the effect on strain difference (Δε) in parts-per-million (ppm) on the vertical axis (i.e., y-axis) based on substrates treated with (a) a first molten salt solution having a lithium nitrate (LiNO₃) concentration in weight percent (wt %) indicated on the horizontal axis (i.e., x-axis) as shown in FIG. 14 and (b) a subsequent chemical strengthening treatment with a second molten salt solution in accordance with aspects of the present disclosure;

FIG. 16 illustrates compressive stress (CS) in MegaPascals (MPa) on the vertical axis (i.e., y-axis) in the first portion and the central portion, respectively, for examples treated with conditions L1-L5;

FIG. 17 illustrates depth of layer (DOL) of potassium in micrometers (μm) on the vertical axis (i.e., y-axis) in the first portion and the central portion, respectively, for examples treated with conditions L1-L5;

FIG. 18 illustrates compressive stress (CS) in MegaPascals (MPa) on the vertical axis (i.e., y-axis) in the first portion and the central portion, respectively, for examples treated with one of conditions L1-L5 followed by one of conditions S1-S4 before and after a subsequent etching treatment in accordance with aspects of the present disclosure (as compared against treatment with L1 alone with and without a subsequent etching treatment);

FIG. 19 illustrates depth of layer (DOL) of potassium in micrometers (μm) on the vertical axis (i.e., y-axis) in the first portion and the central portion, respectively, for examples treated with one of conditions L1-L5 followed by one of conditions S1-S4 after a subsequent etching treatment in accordance with aspects of the present disclosure;

FIG. 20 schematically illustrates stress profiles of the central portion before an etching treatment in accordance with aspects of the present disclosure, where compressive stress (CS) in MegaPascals (MPa) is illustrated on the vertical axis (i.e., y-axis) as a function of depth (d) from the first central surface area on the horizontal axis (i.e., x-axis);

FIG. 21 illustrates a contour map of deviations from reference planes for the first major surface and the first central surface of a glass-based substrate sequentially treated with condition L1, condition S4, and an etching treatment, in accordance with aspects of the present disclosure;

FIG. 22 illustrates a contour map of deviations from reference planes for the first major surface and the first central surface of a glass-based substrate sequentially treated with condition L2, condition S4, and an etching treatment, in accordance with aspects of the present disclosure;

FIG. 23 illustrates a contour map of deviations from reference planes for the first major surface and the first central surface of a glass-based substrate sequentially treated with condition L4, condition S4, and an etching treatment, in accordance with aspects of the present disclosure;

FIG. 24 illustrates a contour map of deviations from reference planes for the first major surface and the first central surface of a glass-based substrate sequentially treated with condition L5, condition S4, and an etching treatment, in accordance with aspects of the present disclosure;

FIG. 25 illustrates a contour map of deviations from reference planes for the first major surface and the first central surface of a glass-based substrate sequentially treated with condition L3, condition S4, and an etching treatment, in accordance with aspects of the present disclosure;

FIG. 26 illustrates a contour map of local curvature for the first major surface and the first central surface of a glass-based substrate sequentially treated with condition L1, condition S4, and an etching treatment, in accordance with aspects of the present disclosure;

FIG. 27 illustrates a contour map of local curvature for the first major surface and the first central surface of a glass-based substrate sequentially treated with condition L2, condition S4, and an etching treatment, in accordance with aspects of the present disclosure;

FIG. 28 illustrates a contour map of local curvature for the first major surface and the first central surface of a glass-based substrate sequentially treated with condition L4, condition S4, and an etching treatment, in accordance with aspects of the present disclosure;

FIG. 29 illustrates a contour map of local curvature for the first major surface and the first central surface of a glass-based substrate sequentially treated with condition L5, condition S4, and an etching treatment, in accordance with aspects of the present disclosure;

FIG. 30 illustrates a contour map of local curvature for the first major surface and the first central surface of a glass-based substrate sequentially treated with condition L3, condition S4, and an etching treatment, in accordance with aspects of the present disclosure;

FIG. 31 illustrates a contour map of a surface profile of the first central surface area of the central portion of a glass-based substrate sequentially treated with condition L2, condition S4, and an etching treatment, in accordance with aspects of the present disclosure;

FIG. 32 illustrates a contour map of a surface profile of the first central surface area of the central portion of a glass-based substrate sequentially treated with condition L3, condition S4, and an etching treatment, in accordance with aspects of the present disclosure;

FIG. 33 illustrates concentration profiles of lithium oxide (Li₂O) in mol % on the vertical axis (i.e., y-axis) as a function of depth (d) in micrometers (μm) from a corresponding surface (in the first portion or the central portion) on the horizontal axis (i.e., x-axis) for a glass-based substrate treated with (a) condition L1 or (b) sequentially condition L3 and condition S4;

FIG. 34 illustrates concentration profiles of lithium oxide (Li₂O) in mol % on the vertical axis (i.e., y-axis) as a function of depth (d) in micrometers (μm) from a corresponding surface (in the first portion or the central portion) on the horizontal axis (i.e., x-axis) for a glass-based substrate treated with (a) condition L1 followed by etching or (b) sequentially condition L3, condition S3, and an etching treatment;

FIG. 35 illustrates concentration profiles of sodium oxide (Na₂O) in mol % on the vertical axis (i.e., y-axis) as a function of depth (d) in micrometers (μm) from a corresponding surface (in the first portion or the central portion) on the horizontal axis (i.e., x-axis) for a glass-based substrate treated with (a) condition L1 or (b) sequentially condition L3 and condition S4;

FIG. 36 illustrates concentration profiles of sodium oxide (Na₂O) in mol % on the vertical axis (i.e., y-axis) as a function of depth (d) in micrometers (μm) from a corresponding surface (in the first portion or the central portion) on the horizontal axis (i.e., x-axis) for a glass-based substrate treated with (a) condition L1 followed by etching or (b) sequentially condition L3, condition S3, and an etching treatment;

FIG. 37 illustrates concentration profiles of potassium oxide (K₂O) in mol % on the vertical axis (i.e., y-axis) as a function of depth (d) in micrometers (μm) from a corresponding surface (in the first portion or the central portion) on the horizontal axis (i.e., x-axis) for a glass-based substrate treated with (a) condition L1 or (b) sequentially condition L3 and condition S4;

FIG. 38 illustrates concentration profiles of potassium oxide (K₂O) in mol % on the vertical axis (i.e., y-axis) as a function of depth (d) in micrometers (μm) from a corresponding surface (in the first portion or the central portion) on the horizontal axis (i.e., x-axis) for a glass-based substrate treated with (a) condition L1 followed by etching or (b) sequentially condition L3, condition S3, and an etching treatment;

FIG. 39 illustrates failure strength (FS) in MegaPascals (MPa) on the vertical axis (i.e., y-axis) for Examples AA1, BB1, 11, and 21;

FIG. 40 illustrates puncture resistance as measured in the Quasi-Static Puncture Test (QSP) in kilograms-force (kgf) on the vertical axis (i.e., y-axis) for Examples AA1, BB1, 11, and 21;

FIG. 41 illustrates failure strength (FS) in MegaPascals (MPa) on the vertical axis (i.e., y-axis) for Examples AA2, BB2, 12, and 22;

FIG. 42 illustrates puncture resistance as measured in the Quasi-Static Puncture Test (QSP) in kilograms-force (kgf) on the vertical axis (i.e., y-axis) for Examples AA2, BB2, 12, and 22;

FIG. 43 illustrates failure strength (FS) in MegaPascals (MPa) on the vertical axis (i.e., y-axis) for Examples AA3, BB3, 13, and 23;

FIG. 44 illustrates puncture resistance as measured in the Quasi-Static Puncture Test (QSP) in kilograms-force (kgf) on the vertical axis (i.e., y-axis) for Examples AA3, BB3, 13, and 23;

FIG. 45 illustrates failure strength (FS) in MegaPascals (MPa) on the vertical axis (i.e., y-axis) for Examples AA4, BB4, 14, and 24;

FIG. 46 illustrates puncture resistance as measured in the Quasi-Static Puncture Test (QSP) in kilograms-force (kgf) on the vertical axis (i.e., y-axis) for Examples AA4, BB4, 14, and 24;

FIG. 47 illustrates flaw depth (df) in micrometers (μm) on the vertical axis (i.e., y-axis) for Examples AA1, BB1, 11, and 21;

FIG. 48 illustrates flaw depth (df) in micrometers (μm) on the vertical axis (i.e., y-axis) for Examples AA2, BB2, 12, and 22;

FIG. 49 illustrates flaw depth (df) in micrometers (μm) on the vertical axis (i.e., y-axis) for Examples AA3, BB3, 13, and 23;

FIG. 50 illustrates flaw depth (df) in micrometers (μm) on the vertical axis (i.e., y-axis) for Examples AA4, BB4, 14, and 24;

FIG. 51 illustrates a Weibull distribution for Examples AA1, BB1, 11, and 21 showing failure probability in percent (%) on the vertical axis (i.e., y-axis) as a function of failure strength (FS) in MegaPascals (MPa) on the horizontal axis (i.e., x-axis); and

FIG. 52 illustrates a Weibull distribution for Examples AA4, BB4, 14, and 24 showing failure probability in percent (%) on the vertical axis (i.e., y-axis) as a function of failure strength (FS) in MegaPascals (MPa) on the horizontal axis (i.e., x-axis).

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

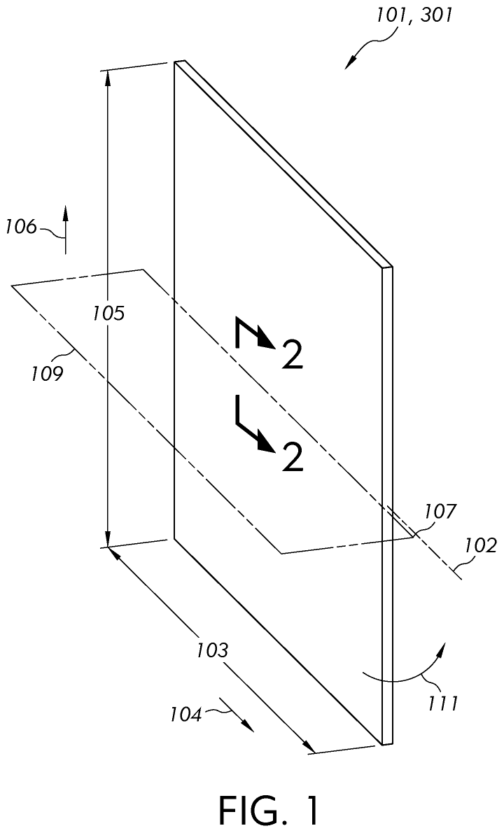

Aspects will now be described more fully hereinafter with reference to the accompanying drawings in which example aspects are shown. Whenever possible, the same reference numerals are used throughout the drawings to refer to the same or like parts. FIGS. 1-4 and 5-6 illustrate views of foldable apparatus 101, 301, 401, and 601 comprising a foldable substrate 201 in accordance with aspects of the disclosure. Unless otherwise noted, a discussion of features of aspects of one foldable apparatus can apply equally to corresponding features of any aspects of the disclosure. For example, identical part numbers throughout the disclosure can indicate that, in some aspects, the identified features are identical to one another and that the discussion of the identified feature of one aspect, unless otherwise noted, can apply equally to the identified feature of any of the other aspects of the disclosure.

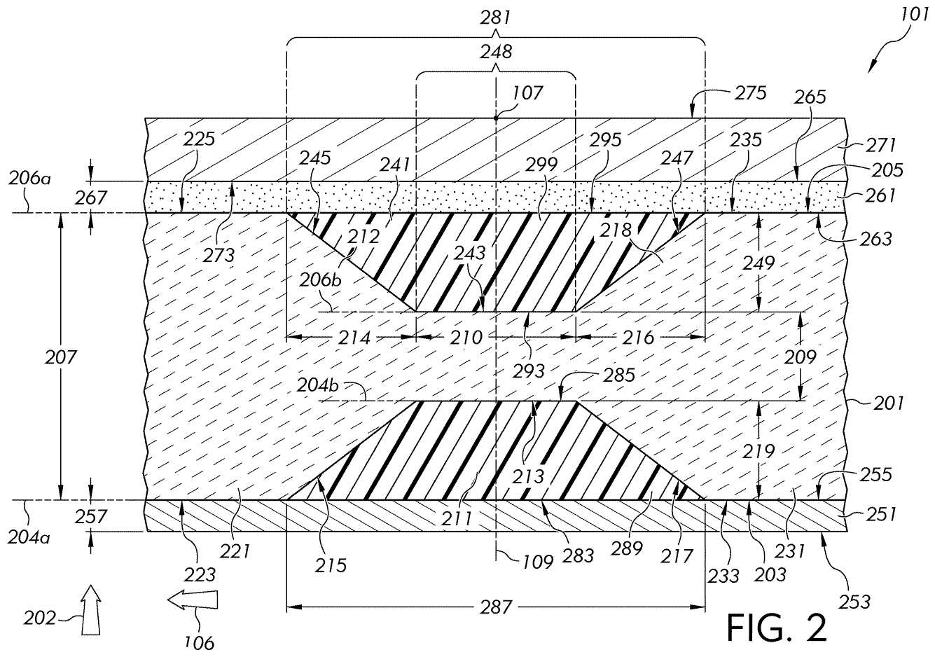

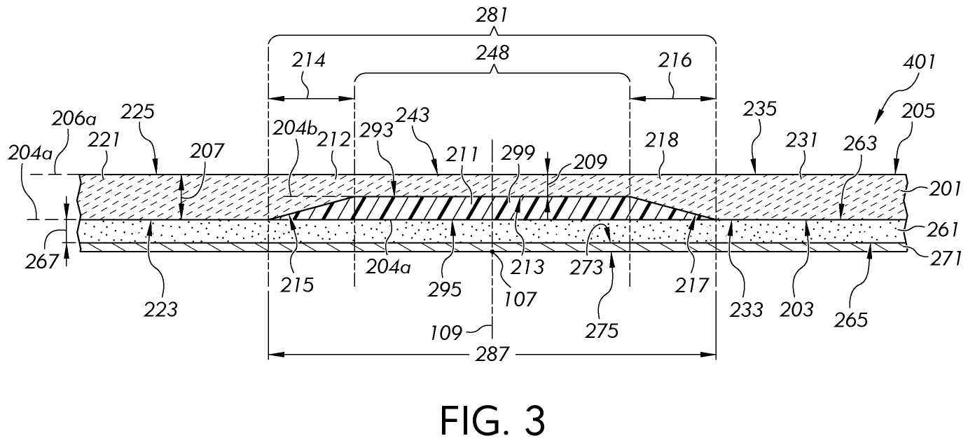

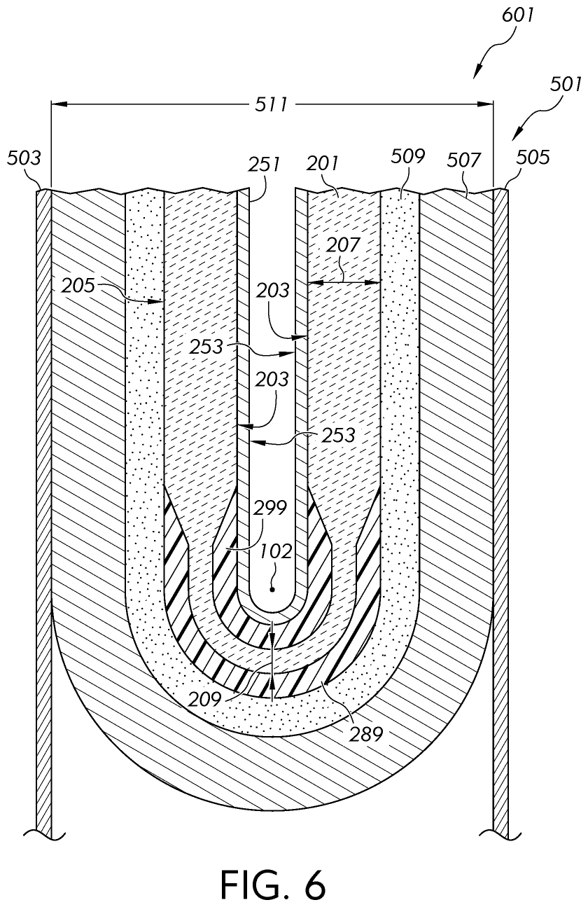

FIGS. 2-4 schematically illustrate example aspects of foldable apparatus 101 and 301 comprising the foldable substrate 201 in accordance with aspects of the disclosure in an unfolded (e.g., flat) configuration while FIGS. 5-6 illustrates an example aspect of a foldable apparatus 401 and 601 comprising the foldable substrate 201 in accordance with aspects of the disclosure in a folded configuration. The foldable apparatus 101 and 301 and the foldable substrate 201 comprise a first portion 221, a second portion 231, and a central portion 281 positioned between the first portion 221 and the second portion 231. In aspects, as shown in FIGS. 2-3, the foldable apparatus 101 and 301 can comprise a release liner 271 although other substrates (e.g., a glass-based substrate and/or a ceramic-based substrate discussed throughout the application) may be used in further aspects rather than with the illustrated release liner 271. In aspects, as shown in FIGS. 2 and 6, the foldable apparatus 101 and 601 can comprise a coating 251. In aspects, as shown in FIGS. 2-3, the foldable apparatus 101 and 301 can comprise an adhesive layer 261. In aspects, as shown in FIGS. 2-3 and 6, foldable apparatus 101, 301, and 601 can comprise a polymer-based portion 289 and/or 299. As shown in FIGS. 2-3 and 5-6, the foldable substrate 201 can comprise a first recess 211. In aspects, as shown in FIGS. 2 and 6, the foldable substrate 201 can further comprise a second recess 241 in addition to the first recess 211. It is to be understood that any of the foldable apparatus of the disclosure can comprise a second substrate (e.g., a glass-based substrate and/or a ceramic-based substrate), a release liner 271, a display device, a coating 251, an adhesive layer 261, and/or a polymer-based portion 289 and/or 299.

Throughout the disclosure, with reference to FIG. 1, the width 103 of the foldable apparatus 101, 301, 401, and/or 601 is considered the dimension of the foldable apparatus taken between opposed edges of the foldable apparatus in a direction 104 of a fold axis 102 of the foldable apparatus, wherein the direction 104 also comprises the direction of the width 103. Furthermore, throughout the disclosure, the length 105 of the foldable apparatus is considered the dimension of the foldable apparatus taken between opposed edges of the foldable apparatus in a direction 106 perpendicular to the fold axis 102 of the foldable apparatus. It is to be understood that the direction 104 of the width 103 and/or the direction 106 of the length 105 can correspond to corresponding directions in the foldable substrate 201. In aspects, as shown in FIGS. 1-2, the foldable apparatus of any aspects of the disclosure can comprise a fold plane 109 that includes the fold axis 102 when the foldable apparatus is in the flat configuration (see FIG. 2). In further aspects, as shown in FIG. 2, the fold plane 109 can extend along the fold axis 102 and in a direction 202 of the substrate thickness 207 when the foldable apparatus is in the flat configuration (see FIG. 2). The fold plane 109 may comprise a central axis 107 of the foldable apparatus. In aspects, the foldable apparatus can be folded in a direction 111 (see FIG. 1) about the fold axis 102 extending in the direction 104 of the width 103 to form a folded configuration (see FIG. 6). Likewise, folding the foldable substrate 201 (see FIG. 3) about the fold axis can form a folded configuration (see FIG. 5). As shown, the foldable apparatus and/or the foldable substrate may include a single fold axis to allow the foldable apparatus and/or the foldable substrate to comprise a bifold wherein, for example, the foldable apparatus and/or the foldable substrate may be folded in half. In further aspects, the foldable apparatus and/or the foldable substrate may include two or more fold axes with each fold axis including a corresponding central portion similar or identical to the central portion 281 discussed herein. For example, providing two fold axes can allow the foldable apparatus and/or the foldable substrate to comprise a trifold wherein, for example, the foldable apparatus and/or the foldable substrate may be folded with the first portion 221, the second portion 231, and a third portion similar or identical to the first portion or second portion with the central portion 281 and another central portion similar to or identical to the central portion positioned between the first portion and the second portion and between the second portion and the third portion, respectively.

Throughout the disclosure, a tensile strength, ultimate elongation (e.g., strain at failure), and yield point of a polymeric material (e.g., adhesive, polymer-based portion) is determined using ASTM D638 using a tensile testing machine, for example, an Instron 3400 or Instron 6800, at 23 °C and 50% relative humidity with a type I dogbone shaped sample. Throughout the disclosure, an elastic modulus (e.g., Young's modulus) and/or a Poisson's ratio is measured using ISO 527-1:2019. Throughout the disclosure, the Young's modulus of glass materials are measured using the resonant ultrasonic spectroscopy technique set forth in ASTM E2001-13, titled “Standard Guide for Resonant Ultrasound Spectroscopy for Defect Detection in Both Metallic and Non-metallic Parts.” In aspects, the foldable substrate 201 can comprise an elastic modulus of 50 GPa or more, 60 GPa or more, 65 GPa or more, 70 GPa or more, 72 GPa or more, 75 GPa or more, 120 GPa or less, 100 GPa or less, 90 GPa or less, 80 GPa or less, 75 GPa or less, 72 GPa or less, or 70 GPa or less. In further aspects, the foldable substrate 201 can comprise a glass material comprising an elastic modulus ranging from greater than or equal to 50 GPa to less than or equal to 120 GPa, from greater than or equal to 60 GPa to less than or equal to 100 GPa, from greater than or equal to 65 GPa to less than or equal to 90 GPa, from greater than or equal to 70 GPa to less than or equal to 80 GPa, from greater than or equal to 72 GPa to less than or equal to 75 GPa, or any range or subrange therebetween.

Foldable apparatus 101 and/or 301 of the disclosure comprise the foldable substrate 201. In aspects, the foldable substrate 201 can comprise a glass-based substrate having a pencil hardness of 8H or more, for example, 9H or more. As used herein, “glass-based” includes both glasses and glass-ceramics, wherein glass-ceramics have one or more crystalline phases and an amorphous, residual glass phase. A glass-based material (e.g., glass-based substrate) may comprise an amorphous material (e.g., glass) and optionally one or more crystalline materials (e.g., ceramic). Glass material comprises an amorphous material (e.g., glass) that may be strengthened. As used herein, the term “strengthened” may refer to a material that has been chemically strengthened, for example, through ion exchange of larger ions for smaller ions in the surface of the substrate, as discussed below. However, other strengthening methods, for example, thermal tempering, or utilizing a mismatch of the coefficient of thermal expansion between portions of the substrate to create compressive stress and central tension regions, may be utilized to form strengthened substrates. Exemplary glass materials, which may be free of lithia or not, comprise soda lime glass, alkali aluminosilicate glass, alkali-containing borosilicate glass, alkali-containing aluminoborosilicate glass, alkali-containing phosphosilicate glass, and alkali-containing aluminophosphosilicate glass. In aspects, the foldable substrate 201 can comprise a ceramic-based substrate. As used herein, “ceramic-based” includes both ceramics and glass-ceramics, wherein glass-ceramics have one or more crystalline phases and an amorphous, residual glass phase. Ceramic-based materials may be strengthened (e.g., chemically strengthened). In aspects, a ceramic-based material can be formed by heating a glass-based material to form ceramic (e.g., crystalline) portions. In further aspects, ceramic-based materials may comprise one or more nucleating agents that can facilitate the formation of crystalline phase(s).

In aspects, the composition of the foldable substrate 201 can comprise a glass-based material comprising from 40 mol % to 80 mol % SiO₂, from 5 mol % to 30 mol % Al₂O₃, from 5 mol % to 20 mol % Na₂O and/or R₂O, and optionally: from 0 mol % to 15 mol % RO; from 0 mol % to 10 mol % B₂O₃; and/or from 0 mol % to 5 mol % ZrO₂. In further aspects, the composition of the foldable substrate 201 can comprise a glass-based material comprising from 60 mol % to 72 mol % SiO₂, from 8 mol % to 17 mol % Al₂O₃, from 12 mol % to 20 mol % Na₂O and/or R₂O, from 3 mol % to 7 mol % MgO and/or RO, and optionally from 0 mol % to 2 mol % of one or more of B₂O₃ and/or P₂O₅. In even further aspects, the composition of the foldable substrate 201 can further comprise from 14 mol % to 19 mol % Na₂O, from 0 mol % to 1 mol % Li₂O, and/or from 0 mol % to 0.5 mol % K₂O. In further aspects, the composition of the foldable substrate 201 can comprise from 60 mol % to 72 mol % SiO₂, from 8 mol % to 16 mol % Al₂O₃, from 12 mol % to 18 mol % Na₂O and/or R₂O, from 2 mol % to 6 mol % MgO and/or RO, optionally from 0 mol % to 2 mol % of one or more of Li₂O, CaO, B₂O₃, and/or P₂O₅ (e.g., from 0.1 mol % to 2.0 mol % CaO) and optionally from 0 mol % to 1 mol % K₂O. In further aspects, the composition of the foldable substrate 201 can comprise from 64.0 mol % 70 mol % SiO₂, from 9.5 mol % to 14.5 mol % Al₂O₃, from 14 mol % to 17 mol % Na₂O, from 3.0 mol % to 5.5 mol % MgO, from 0 mol % to 1 mol % of one or more of Li₂O, CaO, B₂O₃, and/or P₂O₅, and from 0.0 mol % to 0.5 mol % K₂O. In further aspects, Al₂O₃—R₂O (e.g., Al₂O₃—Na₂O) can be from −6.0 mol % to −2.0 mol % or from −5.8 mol % to −2.2 mol %.

Throughout the disclosure, the composition of glass-based compositions and/or a bulk composition of a foldable substrate refers to the composition of the formed article as determined in wt % by: X-ray fluorescence and comparison with standard samples for alumina, phosphorous, alkaline earth metals, transition metals (e.g., ZnO, TiO₂, Fe₂O₃, SnO₂), sodium oxide, and potassium oxide; an amount of B₂O₃ is measured using inductively coupled plasma (ICP) methods; an amount of lithium oxide (Li₂O) is measured using flame emission spectroscopy; and an amount of SiO₂ is taken as the balance of material (i.e., 100%-materials measured using X-ray fluorescence, ICP, and flame emission spectroscopy), and then the composition is converted from wt % to mol %, as reported herein. The composition refers to the composition of the formed article—not the raw materials added to form the glass composition and/or the glass article.

In aspects, the glass-based substrate can be free of one or more of P₂O₅, B₂O₃, TiO₂, ZnO, ZrO₂, Ta₂O₅, HfO₂, La₂O₃, and/or Y₂O₃. Unless otherwise indicated, as used herein, the term “free” does not require absolute precision nor atomic-scale accuracy, but rather “free” means that the component may be present in the final glass-based composition in very small amounts (e.g., as a contaminant, such as less than 0.1 mol %) that could be practically obtained by a reasonable practitioner, which does include 0.0 mol % in some aspects. For example, the inclusion of ZrO₂ in the glass composition may result in the formation of undesirable zirconia inclusions in the glass material, due at least in part to the low solubility of ZrO₂ in the glass material. Also, the inclusion of Ta₂O₅, HfO₂, La₂O₃, and/or Y₂O₃ may increase the cost of raw materials associated with the glass-based substrate.

In aspects, the foldable substrate 201 can be optically transparent. As used herein, “optically transparent” or “optically clear” means an average transmittance of 70% or more in the wavelength range of 400 nm to 700 nm through a 1.0 mm thick piece of a material. In aspects, the foldable substrate 201 may have an average transmittance of 75% or more, 80% or more, 85% or more, or 90% or more, 92% or more, 94% or more, 96% or more in the wavelength range of 400 nm to 700 nm through a 1.0 mm thick piece of the material. The average transmittance in the wavelength range of 400 nm to 700 nm is calculated by measuring the transmittance of whole number wavelengths from 400 nm to 700 nm and averaging the measurements.

As shown in FIGS. 2-3, the foldable apparatus 101 and 301 comprise the foldable substrate 201 comprising a first major surface 203 and a second major surface 205 opposite the first major surface 203. As shown in FIGS. 2-3, the first major surface 203 can extend along a first plane 204a. The second major surface 205 can extend along a second plane 206a. In aspects, as shown, the second plane 206a can be parallel to the first plane 204a. As used herein, a substrate thickness 207 can be defined between the first major surface 203 and the second major surface 205 as a distance between the first plane 204a and the second plane 206a. In aspects, the substrate thickness 207 can be 75 μm or more, 80 μm or more, 90 μm or more, 100 μm or more, 125 μm or more, 150 μm or more, 200 μm or more, 300 μm or more, 3 millimeters (mm) or less, 2 mm or less, 1 mm or less, 800 μm or less, 500 μm or less, 300 μm or less, 200 μm or less, 180 μm or less, 150 μm or less, or 100 μm or less. In aspects, the substrate thickness 207 can range from greater than or equal to 75 μm to less than or equal to 3 mm, from greater than or equal to 80 μm less than or equal to 2 mm, from greater than or equal to 90 μm to less than or equal to 1 mm, from greater than or equal to 100 μm to less than or equal to 800 μm, from greater than or equal to 125 μm to less than or equal to 500 μm, from greater than or equal to 150 μm to less than or equal to 300 μm, from greater than or equal to 150 μm to less than or equal to 200 μm, or any range or subrange therebetween. In preferred aspects, the substrate thickness 207 can be from greater than or equal to 75 μm to less than or equal to 3 mm, from greater than or equal to 90 μm to less than or equal to 1 mm, from greater than or equal to 100 μm to less than or equal to 300 μm, or any range or subrange therebetween.

As shown in FIGS. 2-3, the first portion 221 of the foldable substrate 201 can comprise a first surface area 223 and a second surface area 225 opposite the first surface area 223. The first portion 221 will now be described with reference to the foldable apparatus 101 of FIG. 2 with the understanding that such description of the first portion 221, unless otherwise stated, can also apply to any aspects of the disclosure, for example, the foldable apparatus 301, 401, and/or 601 illustrated in FIGS. 3 and 5-6. In aspects, as shown, the first surface area 223 can comprise a planar surface, and/or the second surface area 225 of the first portion 221 can comprise a planar surface.

In further aspects, as shown, the second surface area 225 can be parallel to the first surface area 223. In aspects, as shown, the first major surface 203 can comprise the first surface area 223 and the second major surface 205 can comprise the second surface area 225. In further aspects, the first surface area 223 can extend along the first plane 204a. In further aspects, the second surface area 225 can extend along the second plane 206a. In aspects, the substrate thickness 207 can correspond to the distance between the first surface area 223 of the first portion 221 and the second surface area 225 of the first portion 221. In aspects, the substrate thickness 207 can be substantially uniform across the first surface area 223. In aspects, a first thickness defined between the first surface area 223 and the second surface area 225 can be within one or more of the ranges discussed above with regards to the substrate thickness 207. In further aspects, the first thickness can comprise the substrate thickness 207. In further aspects, the first thickness of the first portion 221 may be substantially uniform between the first surface area 223 and the second surface area 225 across its corresponding length (i.e., in the direction 106 of the length 105 of the foldable apparatus) and/or its corresponding width (i.e., in the direction 104 of the width 103 of the foldable apparatus). Unless otherwise noted herein, the term ‘planar surface,’ when used in reference to a glass-based or ceramic-based substrate, refers to a surface exhibiting a Sa value that is less than or equal to 1.0 nm when measured by interferometry in accordance with ISO (International Organization for Standards) 25178-2:2012. For example, the first surface area 223 and/or the third surface area 233 can be planar by exhibiting a Sa value that is less than or equal to 1.0 nm relative to the first plane 204a shown. Likewise, the second surface area 225 and/or the fourth surface area 235 can be planar by exhibiting a Sa value that is less than or equal to 1.0 nm relative to the second plane 206a shown. As shown in FIGS. 2-4, the second portion 231 of the foldable substrate 201 can comprise a third surface area 233 and a fourth surface area 235 opposite the third surface area 233. The second portion 231 will now be described with reference to the foldable apparatus 101 of FIG. 2 with the understanding that such description of the second portion 231, unless otherwise stated, can also apply to any aspects of the disclosure, for example, the foldable apparatus 301, 401, and/or 601 illustrated in FIGS. 3 and 5-6. In aspects, as shown, the third surface area 233 of the second portion 231 can comprise a planar surface, and/or the fourth surface area 235 of the second portion 231 can comprise a planar surface. In further aspects, the third surface area 233 of the second portion 231 can be in a common plane with the first surface area 223 of the first portion 221. In further aspects, as shown, the fourth surface area 235 can be parallel to the third surface area 233. In further aspects, the fourth surface area 235 of the second portion 231 can be in a common plane with the second surface area 225 of the first portion 221. A second thickness can be defined between the third surface area 233 of the second portion 231 and the fourth surface area 235 of the second portion 231. In aspects, the second thickness can be within the range discussed above with regards to the substrate thickness 207. In further aspects, the second thickness can comprise the substrate thickness 207 and/or be substantially equal to the substrate thickness 207 (e.g., first thickness). In aspects, the second thickness of the second portion 231 may be substantially uniform between the third surface area 233 and the fourth surface area 235.

As shown in FIGS. 2-4, the foldable substrate 201 can comprise a central portion 281 positioned between the first portion 221 and the second portion 231. The central portion 281 comprises a first central surface area 213 and a second central surface area 243 opposite the first central surface area 213. As shown, the first central surface area 213 can be positioned between the first surface area 223 and the third surface area 233. In further aspects, the first central surface area 213 can correspond to a central region 248 of the central portion 281. In further aspects, as shown, the first central surface area 213 can extend along a third plane 204b when the foldable apparatus 101, 301, and/or 401 is in a flat configuration. A first recess 211 can be defined between the first central surface area 213 (e.g., third plane 204b) and the first plane 204a.

In aspects, the third plane 204b can be substantially parallel to the first plane 204a and/or the second plane 206a. In further aspects, as shown in FIGS. 2-3, the first central surface area 213 can be recessed from the first major surface 203 by a first distance 219. In further aspects, the first distance 219 that the first central surface area 213 is recessed from the first plane 204a can be 5 μm or more, 10 μm or more, 20 μm or more, 25 μm or more, 40 μm or more, 60 μm or more, 75 μm or more, 100 μm or more, 125 μm or more, 150 μm or more, 200 μm or more, 250 μm or more, 1 mm or less, 800 μm or less, 500 μm or less, 300 μm or less, 200 μm or less, 150 μm or less, 100 μm or less, 75 μm or less, or 40 μm or less. In further aspects, the first distance 219 can range from 5 μm to 1 mm, from 10 μm to 800 μm, from 20 μm to 500 μm, from 25 μm to 300 μm, from 40 μm to 200 μm, from 60 μm to 150 μm, from 75 μm to 100 μm, or any range or subrange therebetween. In further aspects, the first distance 219, as a percentage of the substrate thickness 207, can be 1% or more, 2% or more, 5% or more, 10% or more, 15% or more, 20% or more, 25% or more, 70% or less, 60% or less, 50% or less, 40% or less, 35% or less, or 30% or less. In further aspects, the first distance 219, as a percentage of the substrate thickness 207, can range from 1% to 70%, from 2% to 60%, from 5% to 60%, from 10% to 50%, from 15% to 45%, from 20% to 35%, from 25% to 30%, or any range or subrange therebetween.

As shown in FIGS. 2-4, the second central surface area 243 of the central portion 281 is positioned between the second surface area 225 and the fourth surface area 235. In aspects, as shown in FIG. 3, the second central surface area 243 can extend along the second plane 206a so as to be coplanar with the second surface area 225 and the fourth surface area 235. In other aspects, as shown in FIG. 2, the second central surface area 243 can extend along a fourth plane 206b (e.g., different than the second plane 206a) when the foldable apparatus 101 and/or 301 is in a flat configuration. In further aspects, a second recess 241 is defined between the second central surface area 243 (e.g., fourth plane 206b) and the second plane 206a.

In aspects, as shown in FIG. 2, the second central surface area 243 can be recessed from the second major surface 205 by a second distance 249. In further aspects, the second distance 249 can be within one or more of the ranges discussed above for the first distance 219. In further aspects, the first distance can be greater than the second distance. In even further aspects, the second distance 249 that the second central surface area 243 is recessed from the second plane 206a, as a percentage of the substrate thickness 207, can be 20% or more, 25% or more, 30% or more, 35% or more, 40% or more, 45% or less, 40% or less, 35% or less, 30% or less, 25% or less, 20% or less, 18% or less, or 15% or less. In even further aspects, the second distance 249, as a percentage of the substrate thickness 207, can range from 20% to 45%, from 25% to 40%, from 30% to 35%, or any range or subrange therebetween. In further aspects, as shown in FIG. 2, the first distance 219 can be substantially equal to the second distance 249. Providing the first distance substantially equal to the second distance can further reduce the incidence of mechanical instabilities in the central portion, for example, because the foldable substrate is symmetric about a plane comprising a midpoint in the substrate thickness and the central thickness.

A central thickness 209 can be defined between the first central surface area 213 and the second central surface area 243 as the distance between the third plane 204b and the fourth plane 206b. In aspects, the central thickness 209 can be 20 μm or more, 25 μm or more, 40 μm or more, 50 μm or more, 60 μm or more, 75 μm or more, 100 μm or more, 125 μm or less, 100 μm or less, 75 μm or less, 60 μm or less, or 50 μm or less. In aspects, the central thickness 209 can be from greater than or equal to 20 μm to less than or equal to 125 μm, from greater than or equal to 25 μm to less than or equal to 100 μm, from greater than or equal to 40 μm to less than or equal to 75 μm, or any range or subrange therebetween. In aspects, the central thickness 209 as a percentage of the substrate thickness 207 can be 0.5% or more, 1% or more, 2% or more, 5% or more, 10% or more, 40% or less, 30% or less, 25% or less, 20% or less, 13% or less, 10% or less, or 8% or less. In aspects, the central thickness 209 as a percentage of the substrate thickness 207 can be from greater than or equal to 0.5% to less than or equal to 0%, from greater than or equal to 1% to less than or equal to 30%, from greater than or equal to 2% to less than or equal to 25%, from greater than or equal to 5% to less than or equal to 20%, from greater than or equal to 10% to less than or equal to 13%, or any range or subrange therebetween. In aspects, the substrate thickness 207 can be specified as a multiple of the central thickness 209 (i.e., substrate thickness=multiple*central thickness), where the multiple can be any real number within a predetermined range. In further aspects, the substrate thickness 207 as a multiple of the central thickness 209 can be 2 or more, 3 or more, 4 or more, 5 or more, 7 or more, 10 or more, 20 or more, 30 or more, 50 or more, 100 or more, 200 or more, 200 or less, 150 or less, 100 or less, 75 or less, 50 or less, 33 or less, 25 or less, 20 or less, 15 or less, 10 or less, 7 or less, or 5 or less. In further aspects, the substrate thickness 207 as a multiple of the central thickness 209 can be from greater than or equal to 2 to less than or equal to 200, from greater than or equal to 3 to less than or equal to 150, from greater than or equal to 4 to less than or equal to 100, from greater than or equal to 5 to less than or equal to 75, from greater than or equal to 7 to less than or equal to 50, from greater than or equal to 10 to less than or equal to 33, from greater than or equal to 20 to less than or equal to 25, or any range or subrange therebetween. In preferred aspects, the substrate thickness 207 as a multiple of the central thickness 209 can be from greater than or equal to 2 to less than or equal to 200, from greater than or equal to 3 to less than or equal to 50, from greater than or equal to 5 to less than or equal to 10, or any range or subrange therebetween. In aspects, the central region 248 of the central portion 281 can correspond to a region comprising the central thickness 209. By providing the first central surface area 213 of the central portion 281 extending along the third plane 204b parallel to the second central surface area 243 of the central portion 281 extending along the fourth plane 206b, a uniform central thickness 209 may extend across the central portion 281 that can provide enhanced folding performance at a predetermined thickness for the central thickness 209. A uniform central thickness 209 across the central portion 281 can improve folding performance by preventing stress concentrations that would occur if a portion of the central portion 281 was thinner than the rest of the central portion 281.

In aspects, as shown in FIGS. 2-3, the central portion 281 of the foldable substrate 201 can comprise a first transition region 212 comprising a first transition surface area 215 extending between the first surface area 223 and the first central surface area 213. In further aspects, as shown, a width (e.g., first transition width 214) of the first transition region 212 corresponding to the minimum distance in a direction 106 of the length 105 (see FIG. 1) between a portion of the first central surface area 213 extending along the third plane 204b and a portion of the first surface area 223. In even further aspects, the first transition width 214 of the first transition region 212 can be 0.15 mm or more, 0.3 mm or more, 0.5 mm or more, 0.6 mm or more, 0.7 mm or more, 0.8 mm or more, 2 mm or less, 1.8 mm or less, 1.5 mm or less, 1.2 mm or less, 1 mm or less, 0.8 mm or less, 0.7 mm or less, or 0.5 mm or less. In even further aspects, the first transition width 214 of the first transition region 212 can range from 0.15 mm to 2 mm, from 0.3 mm to 2 mm, from 0.5 mm to 1.8 mm, from 0.6 mm to 1.5 mm, from 0.7 mm to 1.2 mm, from 0.8 mm to 1 mm, or any range or subrange therebetween. In aspects, as shown in FIGS. 2-3, the first transition region 212 can comprise a second transition surface area 245 extending between the second surface area 225 and the second central surface area 243. A width of the second transition surface area 245 corresponding to the minimum distance in a direction 106 of the length 105 (see FIG. 1) between a portion of the second central surface area 243 extending along the fourth plane 206b and a portion of the second surface area 225 can be within one or more of the ranges discussed above for the first transition width 214 and/or substantially equal to the first transition width 214.

In aspects, as shown in FIGS. 2-3, a thickness of the first transition region 212 can decrease between the substrate thickness 207 of the first portion 221 and the central thickness 209 of the central portion 281. In further aspects, as shown, a thickness of the first transition region 212 can smoothly decrease, monotonically decrease, and/or smoothly and monotonically decrease (e.g., linearly change) between the substrate thickness 207 of the first portion 221 and the central thickness 209 of the central portion 281. As used herein, a thickness decreases smoothly if changes in the cross-sectional area are smooth (e.g., gradual) rather than abrupt (e.g., step) changes in thickness. As used herein, a thickness decreases monotonically in a direction if the thickness decreases for a portion and for the rest of the time either stays the same, decreases, or a combination thereof (i.e., the thickness decreases but never increases in the direction). A smooth shape of the first transition region and/or the second transition region can reduce optical distortions. In aspects, as shown in FIGS. 2-3, the first transition surface area 215 can comprise a linearly inclined surface extending between the first central surface area 213 and the first surface area 223. In aspects, although not shown, the first transition surface area can comprise a concave up shape, for example, with a local slope of the first transition surface area smoothly transitioning to a slope of the first central surface area 213 while a local slope of the first transition surface area is substantially different from a slope of the first surface area 223. In aspects, although not shown, the first transition surface area can comprise a sigmoid shape. In aspects, although not shown, a local slope of the first transition surface area can be greater at a midpoint of the first transition surface area than where the first transition surface area meets the first central surface area 213 and where the first transition surface area meets the first surface area 223. In aspects, although not shown, the first transition surface area can comprise a convex up shape, for example, with a local slope of the first transition surface area smoothly transitioning to a slope of the first surface area 223 while a local slope of the first transition surface area is substantially different from a slope of the first central surface area 213. In aspects, the second transition surface area can comprise one of the shapes or properties discussed above in this paragraph for the first transition surface area. For example, as shown in FIG. 2, the second transition surface area 245 can comprise a linearly inclined surface extending between the second central surface area 243 and the second surface area 225. The thickness of the substrate within the first and second transition regions 212 and 218 may not smoothly and monotonically transition in accordance with some aspects.

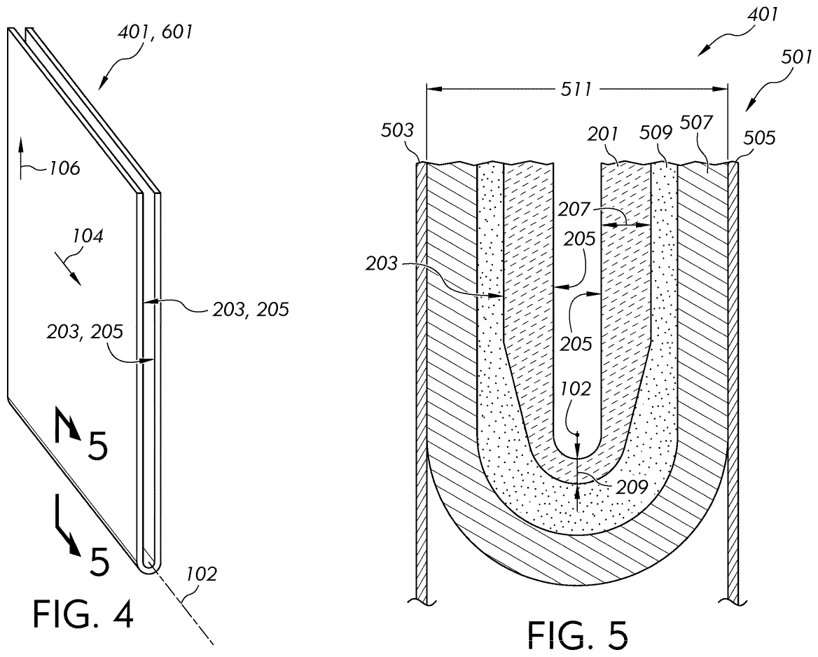

In aspects, as shown in FIGS. 2-3, the central portion 281 of the foldable substrate 201 can comprise a second transition region 218 comprising a third transition surface area 217 extending between the third surface area 233 and the first central surface area 213. In further aspects, as shown, a width (e.g., second transition width 216) of the second transition region 218 can be measured as the minimum distance in a direction 106 of the length 105 (see FIG. 1) between a portion of the first central surface area 213 extending along the third plane 204b and a portion of the third surface area 233. In even further aspects, the second transition width 216 of the second transition region 218 can be within one or more of the ranges discussed above for the first transition width 214. In still further aspects, the second transition width 216 of the second transition region 218 can be substantially equal to (e.g., equal to) the first transition width 214. In aspects, as shown in FIGS. 2-3, the second transition region 218 can comprise a fourth transition surface area 247 extending between the fourth surface area 235 and the second central surface area 243. In further aspects, a width of the fourth transition surface area 247 can be measured as the minimum distance in a direction 106 of the length 105 (see FIG. 1) between a portion of the second central surface area 243 extending along the fourth plane 206b and a portion of the fourth surface area 235. In even further aspects, the width of the fourth transition surface area 247 can be substantially equal to (e.g., equal to) the second transition width 216. In aspects, as shown in FIGS. 2-3, a thickness of the second transition region 218 can decrease between the substrate thickness 207 of the second portion 231 and the central thickness 209 of the central portion 281. In further aspects, as shown, a thickness of the first transition region 212 can smoothly decrease, monotonically decrease, or smoothly and monotonically decrease (e.g., linearly change) between the substrate thickness 207 of the second portion 231 and the central thickness 209 of the central portion 281. In aspects, as shown in FIG. 4, the portion of the second transition region 218 extending between the fourth surface area 235 and the second central surface area 243 can be coplanar with one or both surface areas.

As used herein, if a first layer and/or component is described as “disposed over” a second layer and/or component, other layers may or may not be present between the first layer and/or component and the second layer and/or component. Furthermore, as used herein, “disposed over” does not refer to a relative position with reference to gravity. For example, a first layer and/or component can be considered “disposed over” a second layer and/or component, for example, when the first layer and/or component is positioned underneath, above, or to one side of a second layer and/or component. As used herein, a first layer and/or component described as “bonded to” a second layer and/or component means that the layers and/or components are bonded to each other, either by direct contact and/or bonding between the two layers and/or components or via an adhesive layer. As used herein, a first layer and/or component described as “contacting” or “in contact with” a second layer and/or components refers to direct contact and includes the situations where the layers and/or components are bonded to each other.

As shown in FIGS. 2-3, the foldable apparatus 101 and 301 can comprise an adhesive layer 261. As shown, the adhesive layer 261 can comprise a first contact surface 263 and a second contact surface 265 that can be opposite the first contact surface 263. In aspects, as shown in FIGS. 2-3, the second contact surface 265 of the adhesive layer 261 and/or the first contact surface 263 of the adhesive layer 261 can comprise a planar surface. An adhesive thickness 267 of the adhesive layer 261 can be defined as a minimum distance between the first contact surface 263 and the second contact surface 265. In aspects, the adhesive thickness 267 of the adhesive layer 261 can be 1 μm or more, 5 μm or more, 10 μm or more, 100 μm or less, 60 μm or less, 30 μm or less, or 20 μm or less. In aspects, the adhesive thickness 267 of the adhesive layer 261 can range from 1 μm to 100 μm, from 5 μm to 60 μm, from 10 μm to 30 μm, from 10 μm to 20 μm, or any range or subrange therebetween.

In aspects, as shown in FIGS. 2-3, the second contact surface 265 of the adhesive layer 261 can face and/or contact the first major surface 273 of a release liner 271 (described below). In aspects, as shown in FIG. 2, the first contact surface 263 of the adhesive layer 261 can face and/or contact the second surface area 225 of the first portion 221. In aspects, as shown in FIG. 2, the first contact surface 263 of the adhesive layer 261 can face and/or contact the second surface area 225 and/or the fourth surface area 235 (e.g., second major surface 205). In aspects, as shown in FIG. 2, the first contact surface 263 of the adhesive layer 261 can face the second central surface area 243 of the central portion 281. In aspects, as shown in FIG. 3, the first contact surface 263 of the adhesive layer 261 can face and/or contact the first surface area 223 and/or the third surface area 233 (e.g., first major surface 203). In aspects, as shown in FIG. 3, the first contact surface 263 of the adhesive layer 261 can face the first central surface area 213 of the central portion 281. In further aspects, although not shown, the first contact surface 263 of the adhesive layer 261 can contact the first central surface area 213 or the second central surface area 243, for example by filling the region (e.g., first recess 211, second recess 241) indicated as occupied by the adjacent polymer-based portion in FIGS. 2-3, respectively. In aspects, although not shown, the second recess may not be totally filled, for example, to leave room for electronic devices and/or mechanical devices. In aspects, although not shown, the foldable substrate 201 of FIG. 3 can be configured with the adhesive layer 261 contacting the second major surface 205 rather than the first major surface 203 while the (second) polymer-based portion 299 or a coating 251 in place of the (second) polymer-based portion 299 can be positioned at least partially in the first recess 211.

In aspects, the adhesive layer 261 can comprise a polyolefin, a polyamide, a halide-containing polymer (e.g., polyvinylchloride or a fluorine-containing polymer), an elastomer, a urethane, phenolic resin, parylene, polyethylene terephthalate (PET), polyether ether ketone (PEEK), or combinations or copolymers thereof. Example aspects of polyolefins include polyethylenes and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber), and block copolymers (e.g., styrene-butadiene, high-impact polystyrene, poly(dichlorophosphazene). In further aspects, the adhesive layer 261 can comprise an optically clear adhesive. In even further aspects, the optically clear adhesive can comprise one or more optically transparent polymers: an acrylic (e.g., polymethylmethacrylate (PMMA)), an epoxy, silicone, and/or a polyurethane. Examples of epoxies include bisphenol-based epoxy resins, novolac-based epoxies, cycloaliphatic-based epoxies, and glycidylamine-based epoxies. In even further aspects, the optically clear adhesive can comprise, but is not limited to acrylic adhesives, for example, 3M 8212 adhesive, or an optically transparent liquid adhesive, for example, a LOCTITE optically transparent liquid adhesive. Exemplary aspects of optically clear adhesives comprise transparent acrylics, epoxies, silicones, and polyurethanes. For example, the optically transparent liquid adhesive could comprise one or more of LOCTITE AD 8650, LOCTITE AA 3922, LOCTITE EA E-05MR, LOCTITE UK U-09LV, which are all available from Henkel. In aspects, the adhesive layer 261 can comprise an elastic modulus of 0.001 MegaPascals (MPa) or more, 0.01 MPa or more, 0.1 MPa or more, 1 MPa or less, 0.5 MPa or less, 0.1 MPa or less, or 0.05 MPa or less. In aspects, the adhesive layer 261 can comprise an elastic modulus in a range from 0.001 MPa to 1 MPa, from 0.01 MPa to 0.5 MPa, from 0.1 MPa to 0.5 MPa, or any range or subrange therebetween. In aspects, the adhesive layer can comprise an elastic modulus within one or more of the ranges discussed below for the elastic modulus of the polymer-based portions 289 and/or 299.

As shown in FIGS. 2-3, the polymer-based portion 289 and/or 299 of the foldable apparatus 101 can be positioned between the first portion 221 and the second portion 231. In aspects, as shown, the polymer-based portion can comprise a (first) polymer-based portion 289 at least partially positioned in and/or filling the first recess 211. In aspects, as shown in FIG. 2, the polymer-based portion can comprise a (second) polymer-based portion 299 at least partially positioned in and/or filling the second recess 241. In aspects, as shown in FIG. 2, the polymer-based portion can comprise a (second) polymer-based portion 299 at least partially positioned in and/or filling the first recess 211. In aspects, although not shown, the second recess may not be totally filled, for example, to leave room for electronic devices and/or mechanical devices.

As shown in FIG. 2, the (first) polymer-based portion 289 can comprise a fourth contact surface 285 opposite the third contact surface 283. In aspects, as shown, the third contact surface 283 can comprise a planar surface, for example, substantially coplanar (e.g., extend along a common plane, first plane 204a) with the first surface area 223 and the third surface area 233. In aspects, as shown in FIG. 2, the fourth major surface 255 of the coating 251 can face and/or contact the third contact surface 283 of the (first) polymer-based portion 289. In aspects, the fourth contact surface 285 can comprise a planar surface, for example, substantially coplanar (e.g., extend along a common plane, third plane 204b) with the first central surface area 213. In further aspects, the fourth contact surface 285 can contact the first central surface area 213, the first transition surface area 215, and/or the third transition surface area 217.

As shown in FIGS. 2-3, the (second) polymer-based portion 299 can comprise a fourth contact surface 295 opposite the third contact surface 293. In further aspects, as shown in FIG. 2, the third contact surface 293 can contact the second central surface area 243, the second transition surface area 245, and/or the fourth transition surface area 247. In aspects, as shown in FIG. 2, the third contact surface 293 can comprise a planar surface, for example, being substantially coplanar (e.g., extend along a common plane with the fourth plane 206b) with the second central surface area 243. In aspects, as shown in FIG. 2, the fourth contact surface 295 can comprise a planar surface, for example, being substantially coplanar (e.g., extend along a common plane with the second plane 206a) with the second surface area 225 and the fourth surface area 235.

In aspects, as shown in FIG. 3, the third contact surface 293 can contact the first central surface area 213, the first transition surface area 215, and/or the third transition surface area 217. In aspects, as shown in FIG. 3, the third contact surface 293 can comprise a planar surface, for example, being substantially coplanar (e.g., extend along a common plane with the third plane 204b) with the first central surface area 213. In aspects, as shown, the third contact surface 293 can comprise a planar surface, for example, substantially coplanar (e.g., extend along a common plane with the third plane 204b) with the first central surface area 213. In aspects, as shown in FIG. 3, the fourth contact surface 295 can be coplanar (e.g., extend along a common plane with the first plane 204a) with the first surface area 223 and the third surface area 233. In aspects, as shown in FIGS. 2-3, the first contact surface 263 of the adhesive layer 261 can face and/or contact the fourth contact surface 295 of the (second) polymer-based portion 299.

In aspects, the polymer-based portion 289 and/or 299 comprises a polymer (e.g., optically transparent polymer). In further aspects, the polymer-based portion 289 and/or 299 can comprise one or more of an optically transparent: an acrylic (e.g., polymethylmethacrylate (PMMA)), an epoxy, a silicone, and/or a polyurethane. Examples of epoxies include bisphenol-based epoxy resins, novolac-based epoxies, cycloaliphatic-based epoxies, and glycidylamine-based epoxies. In further aspects, the polymer-based portion 289 and/or 299 comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of elastomers include rubbers and block copolymers, for example, comprising one or more of polystyrene, polydichlorophosphazene, and poly(5-ethylidene-2-norbornene). In aspects, the polymer-based portion can comprise a sol-gel material. Example aspects of polyurethanes comprise thermoset polyurethanes, for example, Dispurez 102 available from Incorez and thermoplastic polyurethanes, for example, KrystalFlex PE505 available from Huntsman. In even further aspects, the second portion can comprise an ethylene acid copolymer. An exemplary aspect of an ethylene acid copolymer includes SURLYN available from Dow (e.g., Surlyn PC-2000, Surlyn 8940, Surlyn 8150). An additional exemplary aspect for the second portion comprises Eleglass w802-GL044 available from Axalta with from 1 wt % to 2 wt % cross-linker. In aspects, the polymer-based portion 289 and/or 299 can further comprise nanoparticles, for example, carbon black, carbon nanotubes, silica nanoparticles, or nanoparticles comprising a polymer. In aspects, the polymer-based portion can further comprise fibers to form a polymer-fiber composite.

In aspects, the polymer-based portion 289 and/or 299 can comprise an elastic modulus of 0.001 MegaPascals (MPa) or more, 0.01 MPa or more, 1 MPa or more, 10 MPa or more, 20 MPa or more, 100 MPa or more, 200 MPa or more, 1,000 MPa or more, 5,000 MPa or less, 3,000 MPa or less, 1,000 MPa or less, 500 MPa or less, or 200 MPa or less. In aspects, the polymer-based portion 289 and/or 299 can comprise an elastic modulus in a range from 0.001 MPa to 5,000 MPa, from 0.01 MPa to 3,000 MPa, from 0.01 MPa to 1,000 MPa, from 1 MPa to 200 MPa, from 10 MPa to 200 MPa, from 100 MPa to 200 MPa, or any range or subrange therebetween. In aspects, the adhesive layer 261 comprises an elastic modulus greater than the elastic modulus of the polymer-based portion 289 and/or 299, which arrangement provides improved performance in puncture resistance. In aspects, the elastic modulus of the polymer-based portion 289 and/or 299 can be less than the elastic modulus of the foldable substrate 201. In aspects, the adhesive layer 261 may comprise an elastic modulus within the ranges listed above in this paragraph. In further aspects, the adhesive layer 261 may comprise substantially the same elastic modulus as the elastic modulus of the polymer-based portion 289 and/or 299. In aspects, the elastic modulus of the polymer-based portion 289 and/or 299 can be less than the elastic modulus of the foldable substrate 201.

In aspects, as shown in FIG. 2, a coating 251 can be disposed over the first major surface 203 of the foldable substrate 201. In further aspects, the coating 251 can be disposed over the first portion 221, the second portion 231, and the central portion 281. In aspects, the coating 251 can comprise a third major surface 253 and a fourth major surface 255 opposite the third major surface 253. In further aspects, the coating 251 (e.g., fourth major surface 255) can contact the foldable substrate 201 (e.g., first major surface 203). In further aspects, at least a part of the coating 251 can be positioned in the first recess 211. In even further aspects, the coating 251 can fill the first recess 211. In further aspects, the coating 251 can comprise a coating thickness 257 defined between the third major surface 253 and the fourth major surface 255. In further aspects, the coating thickness 257 can be 0.1 μm or more, 1 μm or more, 5 μm or more, 10 μm or more, 20 μm or more, 25 μm or more, 40 μm or more, 80 μm or more, 200 μm or less, 100 μm or less, or 50 μm or less, 25 μm or less, 20 μm or less, 20 μm or less, 15 μm or less, or 10 μm or less. In aspects, the coating thickness 257 can range from 0.1 μm to 200 μm, from 1 μm to 100 μm, from 10 μm to 50 μm, from 20 μm to 50 μm, or any range or subrange therebetween.

In aspects, the coating 251 can comprise a polymeric hard coating. In further aspects, the polymeric hard coating can comprise one or more of an ethylene-acid copolymer, a polyurethane-based polymer, an acrylate resin, and a mercapto-ester resin. Example aspects of ethylene-acid copolymers include ethylene-acrylic acid copolymers, ethylene-methacrylic acid copolymers, and ethylene-acrylic-methacrylic acid terpolymers (e.g., Nucrel, manufactured by DuPont), ionomers of ethylene acid copolymers (e.g., Surlyn, manufactured by DuPont), and ethylene-acrylic acid copolymer amine dispersions (e.g., Aquacer, manufactured by BYK). Example aspects of polyurethane-based polymers include aqueous modified polyurethane dispersions (e.g., Eleglas®, manufactured by Axalta). Example aspects of acrylate resins that can be UV curable include acrylate resins (e.g., Uvekol® resin, manufactured by Allinex), cyanoacrylate adhesives (e.g., Permabond® UV620, manufactured by Krayden), and UV radical acrylic resins (e.g., Ultrabond windshield repair resin, for example, Ultrabond (45CPS)). Example aspects of mercapto-ester resins include mercapto-ester triallyl isocyanurates (e.g., Norland optical adhesive NOA 61). In further aspects, the polymeric hard coating can comprise ethylene-acrylic acid copolymers and ethylene-methacrylic acid copolymers, which may be ionomerized to form ionomer resins through neutralization of the carboxylic acid residue with typically alkali-metal ions, for example, sodium and potassium, and also zinc. Such ethylene-acrylic acid and ethylene-methacrylic acid ionomers may be dispersed in water and coated onto the substrate to form an ionomer coating. Alternatively, such acid copolymers may be neutralized with ammonia which, after coating and drying liberates the ammonia to reform the acid copolymer as the coating. By providing a coating comprising a polymeric coating, the foldable apparatus can comprise low energy fracture.

In aspects, the coating can comprise a polymeric hard coating comprising an optically transparent polymeric hard-coat layer. Suitable materials for an optically transparent polymeric hard-coat layer include but are not limited to a cured acrylate resin material, an inorganic-organic hybrid polymeric material, an aliphatic or aromatic hexafunctional urethane acrylate, a siloxane-based hybrid material, and a nanocomposite material, for example, an epoxy and urethane material with nanosilicate. In aspects, an optically transparent polymeric hard-coat layer may consist essentially of one or more of these materials. In aspects, an optically transparent polymeric hard-coat layer may consist of one or more of these materials. As used herein, “inorganic-organic hybrid polymeric material” means a polymeric material comprising monomers with inorganic and organic components. An inorganic-organic hybrid polymer is obtained by a polymerization reaction between monomers having an inorganic group and an organic group. An inorganic-organic hybrid polymer is not a nanocomposite material comprising separate inorganic and organic constituents or phases, for example, inorganic particulates dispersed within an organic matrix. More specifically, suitable materials for an optically transparent polymeric (OTP) hard-coat layer include, but are not limited to, a polyimide, a polyethylene terephthalate (PET), a polycarbonate (PC), a poly methyl methacrylate (PMMA), organic polymer materials, inorganic-organic hybrid polymeric materials, and aliphatic or aromatic hexafunctional urethane acrylates. In aspects, an OTP hard-coat layer may consist essentially of an organic polymer material, an inorganic-organic hybrid polymeric material, or aliphatic or aromatic hexafunctional urethane acrylate. In aspects, an OTP hard-coat layer may consist of a polyimide, an organic polymer material, an inorganic-organic hybrid polymeric material, or aliphatic or aromatic hexafunctional urethane acrylate. In aspects, an OTP hard-coat layer may include a nanocomposite material. In aspects, an OTP hard-coat layer may include a nano-silicate at least one of epoxy and urethane materials. Suitable compositions for such an OTP hard-coat layer are described in U.S. Pat. Pub. No. 2015/0110990, which is hereby incorporated by reference in its entirety by reference thereto. As used herein, “organic polymer material” means a polymeric material comprising monomers with only organic components. In aspects, an OTP hard-coat layer may comprise an organic polymer material manufactured by Gunze Limited and having a hardness of 9H, for example Gunze's “Highly Durable Transparent Film.” As used herein, “inorganic-organic hybrid polymeric material” means a polymeric material comprising monomers with inorganic and organic components. An inorganic-organic hybrid polymer is obtained by a polymerization reaction between monomers having an inorganic group and an organic group. An inorganic-organic hybrid polymer is not a nanocomposite material comprising separate inorganic and organic constituents or phases, for example, inorganic particulates dispersed within an organic matrix. In aspects, the inorganic-organic hybrid polymeric material may include polymerized monomers comprising an inorganic silicon-based group, for example, a silsesquioxane polymer. A silsesquioxane polymer may be, for example, an alkyl-silsesquioxane, an aryl-silsesquioxane, or an aryl alkyl-silsesquioxane having the following chemical structure: (RSiO_{1.5})ₙ, where R is an organic group for example, but not limited to, methyl or phenyl. In aspects, an OTP hard-coat layer may comprise a silsesquioxane polymer combined with an organic matrix, for example, SILPLUS manufactured by Nippon Steel Chemical Co., Ltd. In aspects, an OTP hard-coat layer may comprise 90 wt % to 95 wt % aromatic hexafunctional urethane acrylate (e.g., PU662NT (Aromatic hexafunctional urethane acrylate) manufactured by Miwon Specialty Chemical Co.) and 10 wt % to 5 wt % photo-initiator (e.g., Darocur 1173 manufactured by Ciba Specialty Chemicals Corporation) with a hardness of 8H or more. In aspects, an OTP hard-coat layer composed of an aliphatic or aromatic hexafunctional urethane acrylate may be formed as a stand-alone layer by spin-coating the layer on a polyethylene terephthalate (PET) substrate, curing the urethane acrylate, and removing the urethane acrylate layer from the PET substrate. In aspects, an OTP hard-coat layer may be an aliphatic or aromatic hexafunctional urethane acrylate material layer having a thickness within one or more of the thickness ranges discussed above for the coating thickness 257.

In aspects, the coating 251, if provided, may also comprise one or more of an easy-to-clean coating, a low-friction coating, an oleophobic coating, a diamond-like coating, a scratch-resistant coating, or an abrasion-resistant coating. A scratch-resistant coating may comprise an oxynitride, for example, aluminum oxynitride or silicon oxynitride with a thickness of 500 micrometers or more. In such aspects, the abrasion-resistant layer may comprise the same material as the scratch-resistant layer. In aspects, a low friction coating may comprise a highly fluorinated silane coupling agent, for example, an alkyl fluorosilane with oxymethyl groups pendant on the silicon atom. In such aspects, an easy-to-clean coating may comprise the same material as the low friction coating. In other aspects, the easy-to-clean coating may comprise a protonatable group, for example an amine, for example, an alkyl aminosilane with oxymethyl groups pendant on the silicon atom. In such aspects, the oleophobic coating may comprise the same material as the easy-to-clean coating. In aspects, a diamond-like coating comprises carbon and may be created by applying a high voltage potential in the presence of a hydrocarbon plasma.

In aspects, as shown in FIGS. 2-3, the foldable apparatus 101 can comprise the release liner 271 although other substrates (e.g., glass-based substrate and/or ceramic-based substrate discussed throughout the application) may be used in further aspects rather than the illustrated release liner 271. In further aspects, as shown, the release liner 271, or another substrate, can be disposed over the adhesive layer 261. In even further aspects, as shown, the release liner 271, or another substrate, can directly contact the second contact surface 265 of the adhesive layer 261. The release liner 271, or another substrate, can comprise a first major surface 273 and a second major surface 275 opposite the first major surface 273. As shown, the release liner 271, or another substrate, can be disposed on the adhesive layer 261 by attaching the second contact surface 265 of the adhesive layer 261 to the first major surface 273 of the release liner 271, or another substrate. In aspects, as shown, the first major surface 273 of the release liner 271, or another substrate, can comprise a planar surface. In aspects, as shown, the second major surface 275 of the release liner 271, or another substrate, can comprise a planar surface. A substrate comprising the release liner 271 can comprise a paper and/or a polymer, for example polyesters (e.g., polyethylene terephthalate (PET)) and polyolefins.

Aspects of the disclosure can comprise a consumer electronic product. The consumer electronic product can comprise a front surface, a back surface, and side surfaces. The consumer electronic product can further comprise electrical components at least partially within the housing. The electrical components can comprise a controller, a memory, and a display. The display can be at or adjacent to the front surface of the housing. The display can comprise liquid crystal display (LCD), an electrophoretic displays (EPD), an organic light-emitting diode (OLED) display, or a plasma display panel (PDP). The consumer electronic product can comprise a cover substrate disposed over the display. In aspects, at least one of a portion of the housing or the cover substrate comprises the foldable apparatus discussed throughout the disclosure. The consumer electronic product can comprise a portable electronic device, for example, a smartphone, a tablet, a wearable device, or a laptop.

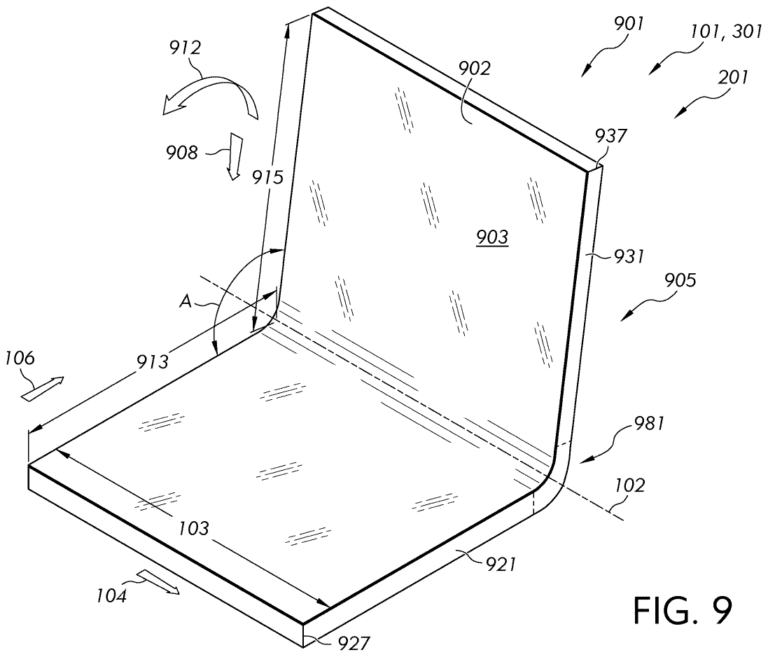

Also, FIG. 9 schematically shows a perspective view of a consumer electronic product 901 that is foldable. The consumer electronic product 901 can include the foldable apparatus 101 and/or 301 and/or the foldable substrate 201 in accordance with aspects of the present disclosure. As shown, the consumer electronic product 901 can include a front surface 903 and a side surface 905. The consumer electronic product 901 can include electronic components, including a display 902 that can be viewed through the front surface 903. In aspects, as shown, the consumer electronic product 901 can be folded in a direction 912 to form a folded configuration that brings a first end 927 and a second end 937 (opposite the first end 927) closer together (than in the unfolded configuration). Additionally, as shown, the consumer electronic product 901 can be folded so that the front surface 903 and/or display 902 faces itself, although the consumer electronic product could be folded opposite the direction 912 so that the front surface 903 is on the outside of the consumer electronic product in the folded configuration. The consumer electronic product 901 shown in FIG. 9 can be folded about the fold axis 102, where a central portion 981 is located between a first portion 921 including the first end 927 and a second portion 931 including the second end 937. A location of the fold axis 102 can determine a first distance 913 between the first end 927 and the fold axis 102 (e.g., in direction 106) relative to a second distance 915 between the second end 937 and the fold axis 102 (e.g., in direction 908). A total length of the consumer electronic product (e.g., length 105 in FIG. 1) can be the sum of the first distance 913 and the second distance 915). Also, as shown, the consumer electronic product is depicted as being in a folded or partially folded configuration with an angle A formed by front surface 903 about the fold axis 102.

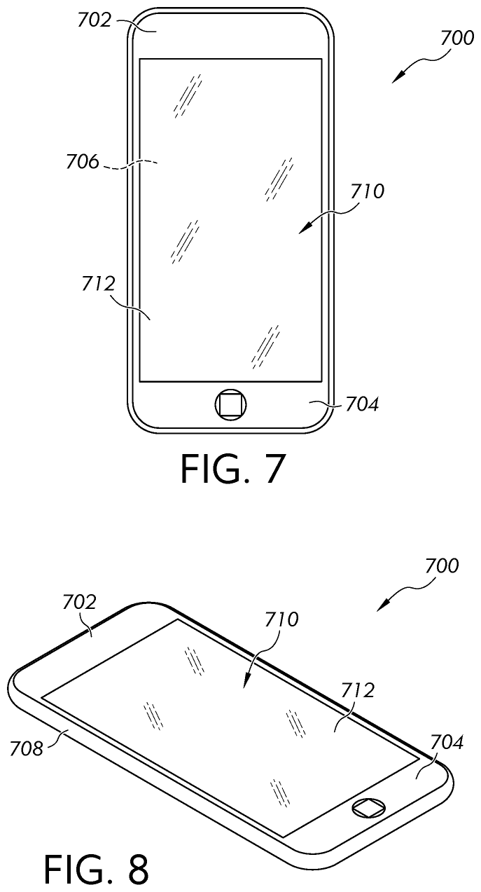

The foldable apparatus disclosed herein may be incorporated into another article, for example, an article with a display (or display articles) (e.g., consumer electronics, including mobile phones, tablets, computers, navigation systems, wearable devices (e.g., watches), and the like), architectural articles, transportation articles (e.g., automotive, trains, aircraft, sea craft, etc.), appliance articles, or any article that may benefit from some transparency, scratch-resistance, abrasion resistance or a combination thereof. An exemplary article incorporating any of the foldable apparatus disclosed herein is shown in FIGS. 7-8. Specifically, FIGS. 7-8 show a consumer electronic device 700 including a housing 702 having front 704, back 706, and side surfaces 708. Although not shown, the consumer electronic device can comprise electrical components that are at least partially inside or entirely within the housing. For example, electrical components include at least a controller, a memory, and a display. As shown in FIGS. 7-8, the display 710 can be at or adjacent to the front surface of the housing 702. The consumer electronic device can comprise a cover substrate 712 at or over the front surface of the housing 702 such that it is over the display 710. In aspects, at least one of the cover substrate 712 or a portion of housing 702 may include any of the foldable apparatus disclosed herein, for example, the foldable substrate.

In aspects, the foldable substrate 201 (e.g., the first portion 221, the second portion 231, and/or the central portion 281) comprising a glass-based substrate and/or a ceramic-based substrate can comprise one or more compressive stress regions. In aspects, a compressive stress region may be created by chemically strengthening. Chemically strengthening may comprise an ion exchange process, where ions in a surface layer are replaced by—or exchanged with—larger ions having the same valence or oxidation state. Methods of chemically strengthening will be discussed later. Without wishing to be bound by theory, chemically strengthening the first portion 221, the second portion 231, and/or the central portion 281 can enable good impact and/or puncture resistance (e.g., resists failure for a pen drop height of 15 centimeters (cm) or more, 20 cm or more, 50 cm or more). Without wishing to be bound by theory, chemically strengthening the first portion 221, the second portion 231, and/or the central portion 281 can enable small (e.g., smaller than 10 mm or less) parallel plate distance because the compressive stress from the chemical strengthening can counteract the bend-induced tensile stress on the outermost surface of the substrate. A compressive stress region may extend into a portion of the first portion and/or the second portion for a depth called the depth of compression (DOC). As used herein, depth of compression means the depth at which the stress in the chemically strengthened substrates and/or portions described herein changes from compressive stress to tensile stress. Depth of compression may be measured by a surface stress meter or a scattered light polariscope (SCALP, wherein values reported herein were made using SCALP-5 made by Glasstress Co., Estonia) depending on the ion exchange treatment and the thickness of the article being measured. Where the stress in the substrate and/or portion is generated by exchanging potassium ions into the substrate, a surface stress meter, for example, the FSM-6000 (Orihara Industrial Co., Ltd. (Japan)), is used to measure depth of compression. Unless specified otherwise, compressive stress (including surface CS) is measured by surface stress meter (FSM) using commercially available instruments, for example the FSM-6000, manufactured by Orihara. Surface stress measurements rely upon the accurate measurement of the stress optical coefficient (SOC), which is related to the birefringence of the glass. Unless specified otherwise, SOC is measured according to Procedure C (Glass Disc Method) described in ASTM standard C770-16, entitled “Standard Test Method for Measurement of Glass Stress-Optical Coefficient,” the contents of which are incorporated herein by reference in their entirety. Where the stress is generated by exchanging sodium ions into the substrate, and the article being measured is thicker than 400 μm, SCALP is used to measure the depth of compression and central tension (CT). Where the stress in the substrate and/or portion is generated by exchanging both potassium and sodium ions into the substrate and/or portion, and the article being measured is thicker than 400 μm, the depth of compression and CT are measured by SCALP. Without wishing to be bound by theory, the exchange depth of sodium may indicate the depth of compression while the exchange depth of potassium ions may indicate a change in the magnitude of the compressive stress (but not the change in stress from compressive to tensile). The refracted near-field (RNF; the RNF method is described in U.S. Pat. No. 8,854,623, entitled “Systems and methods for measuring a profile characteristic of a glass sample”, which is incorporated herein by reference in its entirety) method also may be used to derive a graphical representation of the stress profile. When the RNF method is utilized to derive a graphical representation of the stress profile, the maximum central tension value provided by SCALP is utilized in the RNF method. The graphical representation of the stress profile derived by RNF is force balanced and calibrated to the maximum central tension value provided by a SCALP measurement. As used herein, “depth of layer” (DOL) means the depth that the ions have exchanged into the substrate and/or portion (e.g., sodium, potassium). Throughout the disclosure, DOL is measured in accordance with ASTM C-1422. Without wishing to be bound by theory, a DOL is usually greater than or equal to the corresponding DOC. Through the disclosure, when the maximum central tension cannot be measured directly by SCALP (as when the article being measured is thinner than 400 μm) the maximum central tension can be approximated by a product of a maximum compressive stress and a depth of compression divided by the difference between the thickness of the substrate and twice the depth of compression, wherein the compressive stress and depth of compression are measured by FSM.

In aspects, the first portion 221 may comprise a first compressive stress region at the first surface area 223 extending to a first depth of compression from the first surface area 223 and/or a second compressive stress region at the second surface area 225 extending to a second depth of compression from the second surface area 225. In aspects, the first depth of compression and/or the second depth of compression, as a percentage of the substrate thickness 207, can be 5% or more, 10% or more, 12% or more, 15% or more, 17% or more, 20% or more, 30% or less, 25% or less, 22% or less, 20% or less, 17% or less, or 15% or less. In aspects, the first depth of compression and/or the second depth of compression, as a percentage of the substrate thickness 207, be from greater than or equal to 5% to less than or equal to 30%, from greater than or equal to 10% to less than or equal to 25%, from greater than or equal to 12% to less than or equal to 22%, from greater than or equal to 15% to less than or equal to 20%, from greater than or equal to 17% to less than or equal to 20%, or any range or subrange therebetween. In preferred aspects, the first depth of compression and/or the second depth of compression, as a percentage of the substrate thickness 207, can be from greater than or equal to 5% to less than or equal to 30%, from greater than or equal to 10% to less than or equal to 25%, or from greater than or equal to 15% to less than or equal to 20%. In aspects, the first depth of compression and/or the second depth of compression can be 5 μm or more, 10 μm or more, 15 μm or more, 20 μm or more, 25 μm or more, 30 μm or more, 200 μm or less, 150 μm or less, 100 μm or less, 60 μm or less, 40 μm or less, 40 μm or less, 30 μm or less, or 20 μm or less. In aspects, the first depth of compression and/or the second depth of compression can range from greater than or equal to 5 μm to less than or equal to 200 μm, from greater than or equal to 10 μm to less than or equal to 150 μm, from greater than or equal to 15 μm to less than or equal to 100 μm, from greater than or equal to 20 μm to less than or equal to 60 μm, from greater than or equal to 25 μm to less than or equal to 50 μm, from greater than or equal to 30 μm to less than or equal to 50 μm, or any range or subrange therebetween. By providing a first portion comprising a first glass-based and/or ceramic-based portion comprising a first depth of compression and/or a second depth of compression in a range from 1% to 30% of the first thickness, good impact and/or puncture resistance can be enabled.

In aspects, the first compressive stress region can comprise a first maximum compressive stress, and/or the second compressive stress region can comprise a second maximum compressive stress. In further aspects, the first maximum compressive stress and/or the second maximum compressive stress can be 600 MegaPascals (MPa) or more, 650 MPa or more, 700 MPa or more, 750 MPa or more, 800 MPa or more, 850 MPa or more, 900 MPa or more, 950 MPa or more, 1000 MPa or more, 1500 MPa or less, 1300 MPa or less, 1200 MPa or less, 1100 MPa or less, 1,000 MPa or less, 900 MPa or less, 850 MPa or less, 800 MPa or less, 750 MPa or less, or 700 MPa or less. In further aspects, the first maximum compressive stress and/or the second maximum compressive stress can be from greater than or equal to 600 MPa to less than or equal to 1500 MPa, from greater than or equal to 650 MPa to less than or equal to 1300 MPa, from greater than or equal to 700 MPa to 1200 MPa, from greater than or equal to 750 MPa to less than or equal to 1100 MPa, from greater than or equal to 800 MPa to less than or equal to 1000 MPa, from greater than or equal to 850 MPa to less than or equal to 900 MPa, or any range or subrange therebetween. In preferred aspects, the first maximum compressive stress can be from greater than or equal to 600 MPa to less than or equal to 1500 MPa, from greater than or equal to 1300 MPa, from greater than or equal to 650 MPa to less than or equal to 1300 MPa, from greater than or equal to 700 MPa to less than or equal to 1000 MPa, or any range or subrange therebetween. By providing a first maximum compressive stress and/or a second maximum compressive stress in a range from 600 MPa to 1,500 MPa, good impact and/or puncture resistance can be enabled.

The first portion 221 may comprise a first tensile stress region positioned between the first compressive stress region and the second compressive stress region. In aspects, the first tensile stress region can comprise a first maximum tensile stress of 10 MPa or more, 20 MPa or more, 40 MPa or more, 60 MPa or more, 80 MPa or more, 100 MPa or more, 120 MPa or more, 150 MPa or more, 250 MPa or less, 200 MPa or less, 150 MPa or less, 120 MPa or less, 100 MPa or less, 80 MPa or less, or 60 MPa or less. In further aspects, the first maximum tensile stress can be from greater than or equal to 10 MPa to less than or equal to 250 MPa, from greater than or equal to 20 MPa to less than or equal to 200 MPa, from greater than or equal to 40 MPa to less than or equal to 150 MPa, from greater than or equal to 60 MPa to less than or equal to 120 MPa, from greater than or equal to 80 MPa to less than or equal to 100 MPa, or any range or subrange therebetween. Providing a first maximum tensile stress in a range from 10 MPa to 250 MPa can enable good impact and/or puncture resistance while providing low energy fractures without being frangible.

In aspects, the second portion 231 may comprise a third compressive stress region at the third surface area 233 extending to a third depth of compression from the third surface area 233, and/or the second portion 231 may comprise a fourth compressive stress region at the fourth surface area 235 extending to a fourth depth of compression from the fourth surface area 235. In aspects, the third depth of compression and/or the fourth depth of compression, as a percentage of the substrate thickness 207, can be within one or more of the ranges discussed above for the first depth of compression and/or the second depth of compression. In further aspects, the third depth of compression can be substantially equal to the fourth depth of compression. The third compressive stress region can comprise a third maximum compressive stress, and/or the fourth compressive stress region can comprise a fourth maximum compressive stress. In aspects, the third maximum compressive stress and/or the fourth maximum compressive stress can be within one or more of the ranges discussed above for the first maximum compressive stress and/or the second maximum compressive stress. The second portion 231 may comprise a second tensile stress region positioned between the third compressive stress region and the fourth compressive stress region. In aspects, the second tensile stress region can comprise a second maximum tensile stress that can be within one or more of the ranges discussed above for the first maximum tensile stress. In further aspects, the first maximum tensile stress can be substantially equal to the second maximum tensile stress.

In aspects, the first depth of compression can be substantially equal to the third depth of compression. In aspects, the second depth of compression can be substantially equal to the fourth depth of compression. In aspects, the first maximum compressive stress can be substantially equal to the third maximum compressive stress. In aspects, the second maximum compressive stress can be substantially equal to the fourth maximum compressive stress. In aspects, the first depth of layer of one or more alkali-metal ions can be substantially equal to the third depth of layer of one or more alkali-metal ions. In aspects, the second depth of layer of one or more alkali-metal ions can be substantially equal to the fourth depth of layer of one or more alkali-metal ions.

In aspects, the central portion 281 can comprise a first central compressive stress region at the first central surface area 213 extending to a first central depth of compression from the first central surface area 213, and/or the central portion 281 can comprise a second central compressive stress region at the second central surface area 243 extending to a second central depth of compression from the second central surface area 243. In further aspects, the first central depth of compression and/or the second central depth of compression, as a percentage of the central thickness 209, can be within one or more of the ranges discussed above for the first depth of compression and/or the second depth of compression, as a percentage of the substrate thickness 207. For example, the first central depth of compression and/or the second central depth of compression as a percentage of the central thickness 209 can be from greater than or equal to 5% to 30%, from greater than or equal to 15% to less than or equal to 25%, from greater than or equal to 17% to less than or equal to 20%, or any range or subrange therebetween. In further aspects, the first central depth of compression can be substantially equal to the second central depth of compression. In further aspects, the first central depth of compression and/or the second central depth of compression can be within one or more of the ranges discussed above for the first depth of compression and/or the second depth of compression. In further aspects, the first central depth of compression and/or the second central depth of compression can be 3 μm or more, 4 μm or more, 5 μm or more, 6 μm or more, 8 μm or more, 10 μm or more, 30 μm or less, 25 μm or less, 20 μm or less, 15 μm or less, 10 μm or less, or 8 μm or less. For example, the first central depth of compression and/or the second central depth of compression can be from greater than or equal to 3 μm to less than or equal to 30 μm, from greater than or equal to 4 μm to less than or equal to 25 μm, from greater than or equal to 5 μm to less than or equal to 20 μm, from greater than or equal to 6 μm to less than or equal to 15 μm, from greater than or equal to 8 μm to less than or equal to 10 μm, or any range or subrange therebetween. By providing a central portion comprising a glass-based and/or ceramic-based portion comprising a first central depth of compression and/or a second central depth of compression in a range from 5% to 30% of the central thickness, good impact and/or puncture resistance can be enabled.

The first central compressive stress region can comprise a first central maximum compressive stress, and/or the second central compressive stress region can comprise a second central maximum compressive stress. In aspects, the first central maximum compressive stress and/or the second central maximum compressive stress can be within one or more of the ranges discussed above for the first maximum compressive stress and/or the second maximum compressive stress. For example, the first central maximum compressive stress can be from greater than or equal to 600 MPa to less than or equal to 1500 MPa, from greater than or equal to 1300 MPa, from greater than or equal to 650 MPa to less than or equal to 1300 MPa, from greater than or equal to 700 MPa to less than or equal to 1000 MPa, or any range or subrange therebetween. By providing a first central maximum compressive stress and/or a second central maximum compressive stress in a range from 600 MPa to 1,500 MPa, good impact and/or puncture resistance can be enabled. In aspects, an absolute difference of the first maximum compressive stress and the first central maximum compressive stress can be less than or equal to 100 MPa, less than or equal to 75 MPa, less than or equal to 50 MPa, or less than or equal to 30 MPa (e.g., from greater than or equal to 0 MPa to less than or equal to 100 MPa, from greater than or equal to 5 MPa to less than or equal to 75 MPa, from greater than or equal to 10 MPa to less than or equal to 50 MPa, from greater than or equal to 20 MPa to less than or equal to 30 MPa, or any range or subrange therebetween). In further aspects, the first maximum compressive stress can be equal to the first central maximum compressive stress. In aspects, an absolute difference of the second maximum compressive stress and the second central maximum compressive stress can be within the corresponding range discussed above in this paragraph. In further aspects, the second maximum compressive stress can be equal to the second central maximum compressive stress. In aspects, an absolute difference of the first central maximum compressive stress and the second central maximum compressive stress can be within the corresponding range discussed above in this paragraph. In further aspects, the first central maximum compressive stress can be equal to the second central maximum compressive stress.

The central portion 281 may comprise a central tensile stress region positioned between the first central compressive stress region and the second central compressive stress region. In aspects, the central tensile stress region can comprise a central maximum tensile stress of 100 MPa or more, 125 MPa or more, 150 MPa or more, 175 MPa or more, 200 MPa or more, 225 MPa or more, 250 MPa or more, 300 MPa or more, 450 MPa or less, 400 MPa or less, 350 MPa or less, 300 MPa or less, or 250 MPa or less. In further aspects, the central maximum tensile stress can be from greater than or equal to 100 MPa to less than or equal to 450 MPa, from greater than or equal to 125 MPa to less than or equal to 400 MPa, from greater than or equal to 150 MPa to less than or equal to 350 MPa, from greater than or equal to 175 MPa to less than or equal to 325 MPa, from greater than or equal to 200 MPa to less than or equal to less than or equal to 300 MPa, from greater than or equal to 225 MPa to less than or equal to 250 MPa, or any range or subrange therebetween. Providing a central maximum tensile stress in a range from 100 MPa to 450 MPa can enable low minimum parallel plate distance.

As used herein, a larger alkali metal oxide refers to one or more of potassium oxide (K₂O), rubidium oxide (Rb₂O), cesium oxide (Cs₂O), and francium oxide (Fr₂O). It is to be understood that the “larger alkali metal” of the larger alkali metal oxide has a larger ionic radius than sodium, where a concentration of the larger alkali metal oxide is increased during chemical strengthening in methods of making the foldable substrate and/or foldable apparatus. In aspects, the larger alkali metal oxide can be potassium oxide. The larger alkali metal oxide can be associated with a corresponding compressive stress region, where the extent that larger alkali metal oxide is elevated within the corresponding compressive stress region can be characterized by a depth of layer of the larger alkali metal oxide. As such, the first depth of layer refers to the depth of layer of the larger alkali metal oxide associated with the first compressive stress region in the first region from the first major surface (e.g., first surface area). Likewise, the second, third, and fourth depths of layer refers to the depth of layer of the larger alkali metal oxide associated with the second, third, and fourth compressive stress regions (in the second region, first region, and second region, respectively) from the corresponding surface (e.g., second surface area and/or first major surface in the second portion for the second depth of layer, the third surface area and/or second major surface in the first portion for the third depth of layer, and the fourth surface area and/or second major surface in the second portion for the fourth depth of layer). In aspects, the first depth of layer of the larger alkali metal oxide can be 4 μm or more, 4.5 μm or more, 5.0 μm or more, 5.5 μm or more, 6.0 μm or more, 6.5 μm or more, 7 μm or more, 8 μm or more, 9 μm or more, 10 μm or less, 9 μm or less, 8 μm or less, 7 μm or less, 6 μm or less, or 5 μm or less. In aspects, the first depth of layer of the larger alkali metal oxide can be from greater than or equal to 4.0 μm to less than or equal to 10 μm, from greater than or equal to 4.5 μm to less than or equal to 9 μm, from greater than or equal to 5.0 μm to less than or equal to 8 μm, from greater than or equal to 5.5 μm to less than or equal to 7 μm, from greater than or equal to 5.5 μm to less than or equal to 6.0 μm, or any range or subrange therebetween. In preferred aspects, the first depth of layer of the larger alkali metal oxide can be from greater than or equal to 4 μm to less than or equal to 10 μm, from greater than or equal to 4.5 μm to less than or equal to 8 μm, from greater than or equal to 5.0 μm to less than or equal to 6 μm or any range or subrange therebetween. In aspects, the second depth of layer, third depth of layer, and/or fourth depth of layer of the larger alkali metal oxide (associated with the corresponding compressive stress region) can be within one or more of the ranges discussed above in this paragraph and/or equal to the first depth of layer. In aspects, a first central depth of layer of the larger alkali metal oxide associated with the first central compressive stress region and/or the second central depth of layer of the larger alkali metal oxide associated with the second central compressive stress region in the central portion can be within one or more of the range discussed above in this paragraph. In aspects, a ratio of the first depth of layer to the first central depth of layer (i.e., the first depth of layer divided by the first central depth of layer) can be 0.7 or more, 0.8 or more, 0.9 or more, 1.0 or more, 1.1 or more, 1.5 or less, 1.4 or less, 1.3 or less, 1.2 or less 1.1 or less, 1.0 or less, or 0.9 or less. In aspects, a ratio of the first depth of layer to the first central depth of layer can be from greater than or equal to 0.7 to less than or equal to 1.5, from greater than or equal to 0.8 to less than or equal to 1.4, from greater than or equal to 0.9 to less than or equal to 1.3, from greater than or equal to 1.0 to less than or equal to 1.2, from greater than or equal to 1.0 to less than or equal to 1.1, or any range or subrange therebetween. In further aspects, the first depth of layer can be equal to the first central depth of layer. Providing a first depth of layer that is equal to the first central depth of layer can be consistent with the first portion and the central portion being subjected to similar and/or simultaneous chemical strengthening treatment(s).

In aspects, the foldable apparatus 101, 301, 401, and/or 601 and/or the foldable substrate 201 can be free from buckling in the central portion 281 and/or the central region 248. A foldable apparatus and/or a foldable substrate can be buckled when a surface profile of the first central surface area 213 taken along a midline of the central portion (e.g., at an intersection of the fold plane 109 and the first central surface area 213 shown in FIGS. 2-3 when the fold plane 109 is centered with the first central surface area 213, such that the surface profile is taken along a line at the intersection) equally spaced from the first portion 221 and the second portion 231 using a deflectometer comprises non-parabolic shape. As used herein, the deflectometer profile is measured using a SpecGAGE3D available from Irsa Vision using the default settings. The raw deflectometry measurements correspond to an array of gradients over the measured area. The measured gradients are integrated by the software provided with the SpecGAGE3D to produce a 3D surface. A zero-point of the 3D surface is set so that the average height of the entire 3D surface is 0. A line profile corresponding to the midline of the central portion (i.e., midway between the first portion and the second portion) is extracted from this 3D surface is used as the surface profile (i.e., deflectometer profile). In aspects, the central portion 281 (e.g., first central surface area 213, second central surface area 243) can be free of buckling. In aspects, the central portion 281 (e.g., first central surface area 213, second central surface area 243) can comprise a substantially planar and/or substantially parabolic shape.

However, the general shape of the surface profile may not be precise enough to define whether a sample is buckled or non-buckled. It has been found that an average of an absolute value of the gradient of the surface profile (i.e., “average gradient”) can distinguish between buckled and non-buckled sample with buckled samples having a larger average gradient than non-buckled samples. As used herein, the average gradient is calculated by averaging all gradient measurements, where each gradient measurement is calculated between adjacent extrema (e.g., a local maximum and adjacent local minimum). In aspects, the surface profile of the first central surface area 213 taken along a midline of the central region 248 can comprise an average gradient of 0.018 mm/mm or less, 0.017 mm/mm or less, 0.016 mm/mm or less, 0.015 mm/mm or less, 0.013 mm/mm or less, 0.12 mm/mm or less, 0.011 mm/mm or less, or 0.010 mm/mm or less. In aspects, the surface profile of the first central surface area 213 taken along a midline of the central region 248 can comprise an average gradient from 0.001 mm/mm to 0.018 mm/mm, from 0.002 mm/mm to 0.017 mm/mm, from 0.003 mm/mm to 0.016 mm/mm, from 0.005 to 0.015 mm/mm, from 0.008 mm/mm to 0.013 mm/mm, from 0.010 mm/mm to 0.012 mm/mm, or any range or subrange therebetween. For samples that are not buckled, the central portion and/or the central region can exhibit a warp that can be tolerated for most applications.

As used herein, “warp” is taken as the largest difference in height (vertical axis) of the surface profile along the midline excluding the measurements within 1 mm of the edge of the foldable substrate in the surface profile, where the most extreme 1% on either side of the distribution is removed to avoid using spurious readings. As such, for a distribution of heights along the midline (excluding measurements within 1 mm of the edge), the warp is the height value at the 99% percentile minus the height value at the 1% percentile (since 1% of the most extreme values are removed changing 100%-0% to 99%-1%). In aspects, the surface profile of the first central surface area 213 taken along a midline of the central region 248 can comprise a tolerable warp of 1,000 μm (1 mm) or less, 700 μm or less, 600 μm or less, 500 μm or less, 400 μm or less, 350 μm or less, 320 μm or less, 300 μm or less, 280 μm or less, 250 μm or less, or 200 μm or less. In aspects, a warp of the surface profile per length of the midline (μm/mm) can be 10 μm/mm or less, 9 μm/mm or less, 8 μm/mm or less, 7 μm/mm or less, 6 μm or less, or 5 μm/mm or less.

As used herein, “local curvature” is taken as the curvature calculated between 3 points adjacent one another in a direction along the measured 3D surface excluding points within 1 mm of the edge of the foldable substrate in the measured 3D surface. Specifically, curvature (K) at point “i” in the Y-direction is calculated as: K(i)=−[(Yᵢ₊₁−2*Yᵢ+Yᵢ₋₁)/(Δy)²]/(1+(m(i))²)^{1.5}, where Yᵢ is the position in the y-direction at point “i”, Δy is the spacing between adjacent points (i to i+1 and i to i−1—such that the 3 points are at i+1, i, and i−1), and m (i) is the slope (m) at point “i” defined as: m(i)=(Yᵢ₊₁−Yᵢ₋₁)/(2*Δy). The “maximum local curvature” at a location is the greater absolute value of the two curvatures (e.g., in the x-direction and in the y-direction) at the location, and the “maximum curvature” refers to the largest value of the maximum local curvature. Unless otherwise indicated, curvature is reported in Diopters (D). Throughout the disclosure, a maximum local curvature of the first central surface area (e.g., surface profile thereof) can characterized in terms of optical power (in units of diopters (D)). As described above, curvature is calculated using measurements within 1 mm (exclusive) of one another with the measurements taken from the surface profile described above. In aspects, the maximum local curvature of the first central surface area (e.g., surface profile thereof) can be 5 D or less, 4 D or less, 3 D or less, 2 D or less, 1 D or less, 0.1 D or more, 0.5 D or more, 1 D or more, 1.5 D or more, 2 D or more, 2.5 D or more, 3 D or more, 4 D or more, or 5 D or more. In aspects, the maximum local curvature of the first central surface area (e.g., surface profile thereof) can be from greater than or equal to 0.1 D to less than or equal to 5 D, from greater than or equal to 0.5 D to less than or equal to 4 D, from greater than or equal to 1.0 D to less than or equal to 3 D, from greater than or equal to 1.5 D to less than or equal to 2 D, or any range or subrange therebetween.

Buckling is a type of mechanical instability. Without wishing to be bound by theory, buckling can occur when a portion of a foldable substrate is subjected to greater than a critical buckling strain for that portion. Critical buckling strain increases with thickness; so, the central portion may be the most susceptible to buckling. When the central portion is subjected to increasing strain less than the critical buckling strain, the central portion can exhibit increasing saddle warp. One source of strain on the central portion is chemical strengthening induced expansion strain caused by expansion when larger ions replace existing, smaller ions in the foldable substrate. Specifically, a mismatch between a chemical strengthening induced expansion strain of the central portion and the first portion and the second portion can arise due to the different thicknesses (e.g., volume) of these portions (central portion, first portion, and second portion) and potentially different amounts of chemical strengthening that these portions are subjected to.

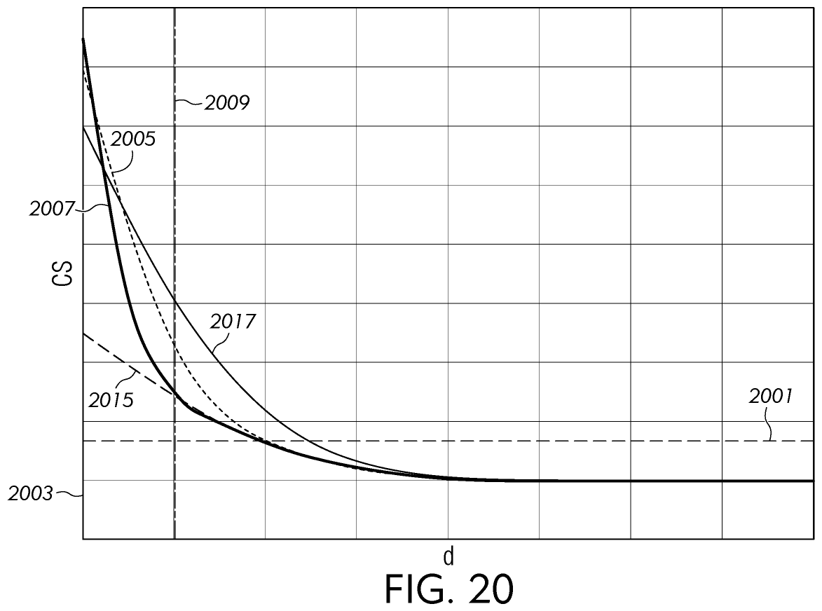

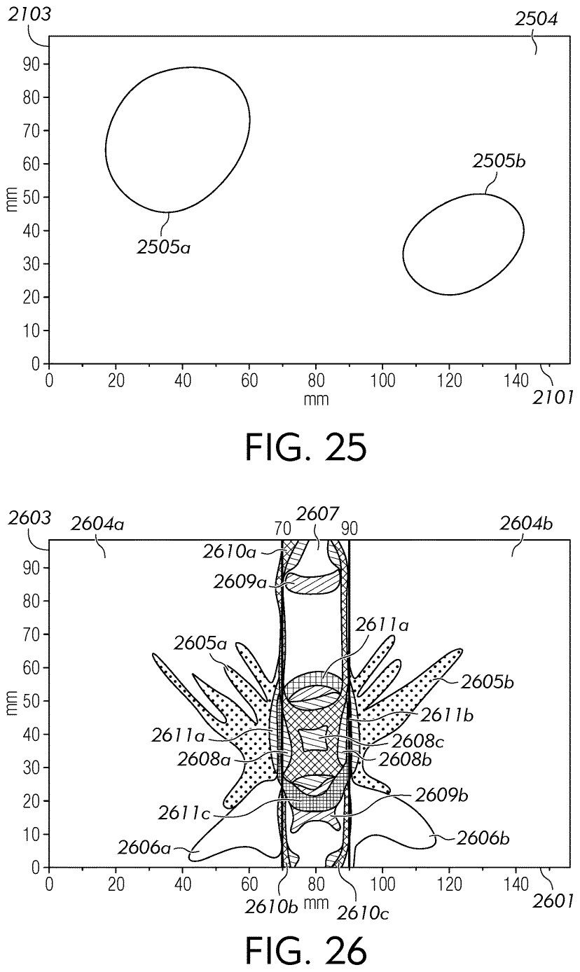

The present disclosure demonstrates that buckling-free and low warp foldable substrates can be obtained. As discussed below, it has unexpectedly been demonstrated that a foldable substrate can be formed from a precursor (e.g., strengthened substrate) with a buckled central portion that is etched to become free of buckling. Previously, it was thought to be beneficial to avoid buckling throughout the entire process of making a foldable substrate because it was believed that buckling could not be undone once induced due to the non-linear behavior that occurs when the critical buckling strain is exceeded. However, allowing the presence of buckling during methods of the present disclosure enables higher compressive stress to be achieved for foldable substrates (and through methods of present disclosure), for example, as discussed below with reference to FIG. 20. Additionally, as demonstrated herein (see FIGS. 25, 30, and 31), foldable substrates that are free of buckling and have low warp can be achieved through a series of chemical strengthening steps without using a mask or other material between any part of the corresponding substrate and the corresponding molten salt solution(s).

Throughout the disclosure, surface concentrations of alkali metal oxides (e.g., lithium oxide (Li₂O), sodium oxide (Na₂O), and potassium oxide (K₂O)) are measured using secondary-ion mass spectroscopy (SIMS). Unless otherwise indicated, concentration profiles are measured using dynamic SIMS. While surface concentrations can be measured using SIMS and/or dynamic SIMS (as specified above), some surface concentrations discussed herein will use measurements from glow discharge optical emission spectroscopy (GDOES) with the understanding that the measured concentrations are applicable to the corresponding measurements from SIMS and/or dynamic SIMS. When using GDOES, however, the “surface concentration” or “concentration at the surface” from GDOES measurements is taken as the concentration at a depth of 1 μm from the surface to avoid any spurious readings or surface contamination during the start of the GDOES measurement. As used herein, concentrations in mol % reported in the concentration profiles from SIMS or GDOES refer to the amount of the given compound at a certain depth from the surface relative to other compounds detected at that same, certain depth from the surface. Additionally or alternatively, it is to be understood that concentrations of the first midpoint can correspond to the bulk composition of the foldable substrate, for example, when alkali metal oxides from chemically strengthening treatments, where concentrations of alkali metals can be determined using flame emission spectroscopy, as described above for the bulk composition.

As mentioned, surface concentrations and central concentrations can be determined using secondary-ion mass spectroscopy (SIMS). Unless otherwise indicated, samples were cleaned with a low-energy Ar gas cluster ion beam (GCIB) source before analysis with SIMS. Concentrations at the surface can be measured using SIMS for the foldable substrate as—is, whereas concentrations at the central midpoint and/or the first midpoint can be determined by removing material from the foldable substrate until a surface corresponding to the corresponding midpoint is revealed, which can then be analyzed using SIMS. As used herein, SIMS was conducted using a time-of-flight secondary ion mass spectrometer (ToF-SIMS) with a dual beam configuration. Unless otherwise indicated, the TOF-SIMS used for the results reported herein was a TOF-SIMS M6 instrument (available from IONTOF GmbH) equipped with a Nanoprobe50 bismuth source. For dynamic SIMS, the TOF-SIMS M6 instrument was operated with a dual-beam configuration, where the analysis beam was a 30 kilo-electron Volts (keV) Bi₃⁺ beam with a current of about 0.1 pA and the sputter beam was 2 keV Cs⁺ with a current of about 120 nA; the sputter beam was configured form a 300 μm by 300 μm sputter “crater”; and the analysis beam was configured to impinge a 75 μm by 75 μm area centered in the sputter “crater.” Charge compensation was achieved using an electron flood gun operating with 20 nA beam current, 20 eV electron energy, and a 1.5 mm spot size focused on the location impinged by the analysis beam. The chamber was evacuated to a pressure of 5×10⁻⁷ Pascals (5×10⁻⁹ millibar) before being brought to and maintained at a pressure of 5×10⁻⁵ Pascals (5×10⁻⁷ millibar) using argon (e.g., 99.99999% purity). Data was collected in positive ion mode with the analyzer in the “all purpose” mode, an analyzer energy of 3000 V and a cycle time of 100 microseconds. Data was processed using Surface Lab software (version 7.3.125519 available from IONTOF GmbH).

In aspects, the first compressive stress region and/or the third compressive stress region extending from the first major surface 203 can have a non-zero concentration profile of Li₂O therein. In aspects, the second compressive stress region and/or the fourth compressive stress region extending from the second major surface 205 can have a non-zero concentration profile of Li₂O therein. For example, the non-zero concentration profile of Li₂O in the compressive stress region(s) extending from (one or more) portion(s) of the first major surface and/or the second major surface can range from greater than or equal to 0.1 mol % to less than or equal to 5.0 mol %, from greater than or equal to 0.2 mol % to less than or equal to 4.5 mol %, from greater than or equal to 0.3 mol % to less than or equal to 4.0 mol %, from greater than or equal to 0.4 mol % to less than or equal to 3.0 mol %, from greater than or equal to 0.5 mol % to less than or equal to 2.5 mol %, from greater than or equal to 0.6 mol % to less than or equal to 2.0 mol %, from greater than or equal to 0.7 mol % to less than or equal to 1.8 mol %, from greater than or equal to 0.8 mol % to less than or equal to 1.5 mol %, or any range or subrange therebetween. In aspects, the first central compressive stress region and/or the second central compressive stress region (e.g., extending from the first central surface area 213 and/or the second central surface area 243) have a non-zero concentration profile of Li₂O therein. In further aspects, the lithium concentration profile of Li₂O can be within one or more of the ranges discussed above in this paragraph.

As used herein, a midpoint of the foldable substrate 201 (e.g., first portion 221, second portion 231) is defined as a location midway between the first major surface 203 and the second major surface 205 corresponding to a particular location on the first major surface 203 and extending perpendicular to the first major surface 203 from that location. For example, if the substrate thickness 207 is 100 μm (e.g., when the first plane 204a is parallel to the second plane 206a), then the midpoint (e.g., in the first portion) is located 50 μm from the first major surface 203 and 50 μm from the second major surface 205. Unless otherwise indicated, the “first midpoint” refers to the midpoint in the first portion (having the substrate thickness). Likewise, as used herein, a “central midpoint” refers to midpoint of the central portion 281 (e.g., central region 248) that is defined as a location midway between the first central surface area 213 and the second central surface area 243 (e.g., at the fold plane 109 shown in FIGS. 2-3. For example, if the central thickness 209 is 30 μm, then the central midpoint (e.g., in the central region) is located 15 μm from the first central surface area 213 and 15 μm from the second central surface area 243. In aspects, when the first distance 219 is equal to the second distance 249, the midpoint of the foldable substrate 201 in the first portion 221 and in the second portion 231 can be coplanar with the central midpoint. Throughout the disclosure, a first concentration of an alkali metal oxide refers to a concentration of the corresponding alkali metal oxide at or otherwise corresponding to the region around the first midpoint. Throughout the disclosure, a central concentration of an alkali metal oxide refers to a concentration of the corresponding alkali metal oxide at or otherwise corresponding to the region around the central midpoint in the central portion.

In aspects, a concentration profile of Li₂O can be non-zero in the central portion 281 throughout the entire central thickness 209. For example, the non-zero concentration profile of Li₂O in the central portion can range from greater than or equal to 0.1 mol % to less than or equal to 5.0 mol %, from greater than or equal to 0.2 mol % to less than or equal to 3.0 mol %, from greater than or equal to 0.3 mol % to less than or equal to 2.0 mol %, from greater than or equal to 0.4 mol % to less than or equal to 1.5 mol % from greater than or equal to 0.5 mol % to less than or equal to 1.2 mol %, from greater than or equal to 0.6 mol % to less than or equal to 1.0 mol %, any range or subrange therebetween. In aspects, a concentration profile of Li₂O in the first portion and/or the second portion (i.e., having the substrate thickness 207) can be zero for at least a portion (e.g., near the midpoint-defined below, or the tensile region between the compressive stress regions) therein. Alternatively or additionally, in aspects, the first concentration of Li₂O at the first midpoint can be non-zero, for example, within one or more of the ranges discussed above for the Li₂O concentration in one or more of the compressive stress regions.

As used herein, a “midpoint lithium difference” (ΔLi₂O(MP)) is defined as a difference between the central concentration of Li₂O (Li₂O(CC)) (i.e., the concentration of Li₂O at or otherwise corresponding to the region around the central midpoint of the central portion) and the first concentration of Li₂O (Li₂O(1C)) (i.e., the concentration of Li₂O at or otherwise corresponding to the region around the first midpoint of the first portion)—i.e., ΔLi₂O(MP)=Li₂O(CC)−Li₂O(1C). Without wishing to be bound by theory, a positive midpoint lithium difference can correspond to or otherwise be consistent with lithium from a molten salt bath diffusing to the central midpoint (i.e., throughout the central portion) without reaching the first midpoint, for example, due to the difference between the central thickness and substrate thickness and the duration of the contact with the corresponding molten salt bath. In aspects, the midpoint lithium difference can be greater than or equal to 0.2 mol %, greater than or equal to 0.5 mol %, greater than or equal to 0.6 mol %, greater than or equal to 0.7 mol %, greater than or equal to 0.8 mol %, greater than or equal to 0.9 mol %, greater than or equal to 1.0 mol %, greater than or equal to 1.2 mol %, greater than or equal to 1.5 mol %, less than or equal to 2.0 mol %, less than or equal to 1.7 mol %, less than or equal to 1.5 mol %, less than or equal to 1.2 mol %, less than or equal to 1.2 mol %, less than or equal to 1.0 mol %, less than or equal to 0.9 mol %, less than or equal to 0.8 mol %, less than or equal to 0.7 mol %, less than or equal to 0.6 mol %, or less than or equal to 0.5 mol %. In aspects, the midpoint lithium difference can be from greater than or equal to 0.2 mol % to less than or equal to 2.0 mol %, from greater than or equal to 0.5 mol % to less than or equal to 1.7 mol %, from greater than or equal to 0.6 mol % to less than or equal to 1.5 mol, from greater than or equal to 0.7 mol % to less than or equal to 1.2 mol %, from greater than or equal to 0.8 mol % to less than or equal to 1.0 mol %, from greater than or equal to 0.8 mol % to less than or equal to 0.9 mol %, or any range or subrange therebetween. In preferred aspects, the midpoint lithium difference can be from greater than or equal to 0.2 mol % to less than or equal to 2.0 mol %, from greater than or equal to 0.5 mol % to less than or equal to 1.2 mol %, from greater than or equal to 0.6 mol % to less than or equal to 0.9 mol %, or any range or subrange therebetween. Providing a positive midpoint lithium difference (i.e., a higher concentration of Li₂O in the central portion than the surrounding first portion and second portion) (e.g., from 0.2 mol % to 2 mol %) can reduce (e.g., mitigate, counteract) a chemical strengthening induced expansion and resulting strain in the foldable substrate.

As used herein, a “central surface lithium difference” (ΔLi₂O(CS)) is defined as a difference between the first central surface concentration of Li₂O (Li₂O(1CSC)) (i.e., the concentration of Li₂O at a center of the first central surface area) and the central concentration of Li₂O (Li₂O(CC)) (i.e., the concentration of Li₂O at or otherwise corresponding to the region around the central midpoint of the central portion)—i.e., ΔLi₂O(CS)=Li₂O(1CSC)−Li₂O(CC). Without wishing to be bound by theory, the central surface lithium difference can reflect the final chemical strengthening treatment performed since the alkali metal ions (including lithium) exchanged between the substrate and the corresponding molten salt solution are located near the surface, especially when the duration of the corresponding chemical strengthening treatment is short. Consequently, a negative central surface lithium difference can correspond to a final (e.g., second) chemical strengthening treatment having less (compared to an earlier chemical strengthening treatment) or even being substantially free of lithium. Further, a negative central surface lithium difference in combination with a positive midpoint lithium difference can correspond to or otherwise be consistent with the methods of the present disclosure since (1) an earlier (e.g., first) chemical strengthening treatment added lithium through the central portion (including the central midpoint) but that earlier chemical strengthening treatment did not add lithium throughout the entire first portion (including the first midpoint) and (2) the molten salt solution for the final (e.g., second, later) chemical strengthening treatment had lower lithium concentration than the earlier chemical strengthening treatments (and/or the molten salt bath for the later chemical strengthening treatment was substantially free of lithium) and/or high amounts of a larger alkali metal ion (e.g., the alkali metal described by the depth of compression associated with the corresponding compressive stress regions). In aspects, the central surface lithium difference can be less than or equal to 0.5 mol %, less than or equal to 0.4 mol %, less than or equal to 0.3 mol %, less than or equal to 0.2 mol %, less than or equal to 0.1 mol %, less than or equal to 0.0 mol %, less than or equal to −0.1 mol %, less than or equal to −0.2 mol %, less than or equal to −0.3 mol %, or less than or equal to −0.5 mol %, greater than or equal to −0.7 mol %, greater than or equal to −0.5 mol %, greater than or equal to −0.4 mol %, greater than or equal to −0.3 mol %, greater than or equal to −0.2 mol %, greater than or equal to −0.1 mol %, greater than or equal to −0.0 mol %, or greater than or equal to 0.1 mol %. In aspects, the central surface lithium difference can be from greater than or equal to −0.7 mol % to less than or equal to 0.5 mol %, from greater than or equal to −0.5 mol % to less than or equal to 0.4 mol %, from greater than or equal to −0.4 mol % to less than or equal to 0.3 mol %, from greater than or equal to −0.3 mol % to less than or equal to 0.2 mol %, from greater than or equal to −0.2 mol % to less than or equal to 0.1 mol %, from greater than or equal to −0.1 to less than or equal to 0.0 mol %, or any range or subrange therebetween. In preferred aspects, the central surface lithium difference can be from greater than or equal to −0.5 mol % to less than or equal to 0.5 mol %, from greater than or equal to −0.3 mol % to less than or equal to 0.3 mol %, from greater than or equal to 0.0 mol % to less than or equal to 0.2 mol %, or any range or subrange therebetween. In aspects, at least a portion of the Li₂O concentration in the central portion can be substantially flat. In further aspects, an absolute value of a change in Li₂O concentration over a range spanning at least 5 μm (e.g., 5 μm or more, 7 μm or more, 10 μm or more, 12 μm, 30% of the central thickness or more, 33% of the central thickness or more, or 40% of the central thickness or more) in the direction of the central thickness—where the range starts within 5 μm of the first central surface area—can be 0.2 mol % or less, 0.15 mol % or less, or 0.10 mol % or less.

As discussed above, a larger alkali metal oxide refers to one or more of potassium oxide (K₂O), rubidium oxide (Rb₂O), cesium oxide (Cs₂O), and francium oxide (Fr₂O). In aspects, the larger alkali metal oxide can be potassium oxide (K₂O). In aspects, the first compressive stress region and/or the third compressive stress region can comprise a non-zero concentration profile a larger alkali metal oxide extending from the first major surface to a corresponding depth of layer (excluding the depth of layer itself) of the larger alkali metal oxide; and/or the second compressive stress region and/or the fourth compressive stress region can comprise a non-zero concentration profile a larger alkali metal oxide extending from the second major surface to a corresponding depth of layer (excluding the depth of layer itself) of the larger alkali metal oxide. In further aspects, the concentration of the larger alkali metal oxide at the corresponding major surface can be greater than the concentration of the larger alkali metal oxide at the corresponding depth of layer. In further aspects, the non-zero concentration profile of the larger alkali metal oxide extending from the corresponding major surface to the corresponding depth of layer can range from greater than or equal to 0.01 mol % to less than or equal to 14.0 mol %, from greater than or equal to 0.02 mol % to less than or equal to 12.0 mol %, from greater than or equal to 0.05 mol % to less than or equal to 10.0 mol %, from greater than or equal to 0.1 mol % to less than or equal to 8.0 mol % from greater than or equal to 0.2 mol % to less than or equal to 7.0 mol %, or any range or subrange therebetween.

In aspects, a concentration of the larger alkali metal oxide at the first major surface 203 (e.g., first surface area 223, third surface area 233) and/or the second major surface 205 (e.g., second surface area 225, fourth surface area 235) can be 4.0 mol % or more, 4.5 mol % or more, 5.0 mol % or more, 5.5 mol % or more, 6.0 mol % or more, 6.5 mol % or more, 7.0 mol % or more, 7.5 mol % or more, 8.0 mol % or more, 9 mol % or more, 10.0 mol % or more, 14 mol % or less, 13.0 mol % or less, 12.0 mol % or less, 11.0 mol % or less, 10.0 mol % or less, 9.0 mol % or less, 8.5 mol % or less, 8.0 mol % or less, 7.5 mol % or less, 7.0 mol % or less, or 6.5 mol % or less. In aspects, a concentration of the larger alkali metal oxide at the first major surface 203 (e.g., first surface area 223, third surface area 233) and/or the second major surface 205 (e.g., second surface area 225, fourth surface area 235) can range from greater than or equal to 4.0 mol % to less than or equal to 14 mol %, from greater than or equal to 4.5 mol % to less than or equal to 13.0 mol %, from greater than or equal to 5.0 mol % to less than or equal to 12.0 mol %, from greater than or equal to 5.5 mol % to less than or equal to 11.0 mol %, from greater than or equal to 6.0 mol % to less than or equal to 10.0 mol %, from greater than or equal to 6.5 mol % to less than or equal to 9.0 mol %, from greater than or equal to 7.0 mol % to less than or equal to 8.5 mol %, from greater than or equal to 7.5 mol % to less than or equal to 8.0 mol %, or any range or subrange therebetween. In preferred aspects, a concentration of the larger alkali metal oxide at the first major surface 203 (e.g., first surface area 223, third surface area 233) and/or the second major surface 205 (e.g., second surface area 225, fourth surface area 235) can be from greater than or equal to 4.0 mol % to less than or equal to 14 mol %, from greater than or equal to 5.0 mol % to less than or equal to 10.0 mol %, from greater than or equal to 5.5 mol % to less than or equal to 9.0 mol %, or any range subrange therebetween. In aspects, a concentration of the larger alkali metal oxide at the second major surface 205 can be equal to the concentration of the larger alkali metal oxide at the first major surface 203. Providing a high (e.g., 4 mol % or more) concentration of K₂O (e.g., as an absolute mol % and/or an amount that the surface concentration is elevated relative to a concentration at the midpoint) can provide a large (e.g., 500 MPa) surface compressive stress that can enable increased fracture resistance.

As used herein, a “central surface larger alkali difference” (ΔLA(CS)) is defined as a difference between the first central surface concentration of the larger alkali metal oxide (LA(1CSC)) (i.e., the concentration of larger alkali metal oxide at a center of the first central surface area) and the central concentration of the larger alkali metal oxide (LA(CC)) (i.e., the concentration of larger alkali metal oxide at or otherwise corresponding to the region around the central midpoint of the central portion)—i.e., ΔLA(CS)=LA(1CSC)−LA(CC). In aspects, the central surface larger alkali difference can be 4 mol % or more, 5 mol % or more, 5.5 mol % or more, 6 mol % or more, 6.5 mol % or more, 7 mol % or more, 7.5 mol % or more, 8 mol % or more, 9 mol % or more, 14 mol % or less, 12 mol % or less, 10 mol % or less, 9 mol % or less, 8.5 mol % or less, 8 mol % or less, 7.5 mol % or less, 7 mol % or less, 6.5 mol % or less, 6.0 mol % or less, 5.5 mol % or less, or 5.0 mol % or less. In aspects, the central surface larger alkali difference can be from greater than or equal to 4 mol % to less than or equal to 14 mol %, from greater than or equal to 5 mol % to less than or equal to 12 mol %, from greater than or equal to 5.5 mol % to less than or equal to 10 mol %, from greater than or equal to 6 mol % to less than or equal to 9 mol %, from greater than or equal to 6.5 mol % to less than or equal to 8.5 mol %, from greater than or equal to 7 mol % to less than or equal to 8 mol %, or any range or subrange therebetween.

In aspects, a ratio of the midpoint lithium difference (ΔLi₂O(MP)) to the central surface larger alkali difference (ΔLA(CS)) (i.e., ΔLi₂O(MP)/ΔLA(CS)) can be 0.01 or more, 0.02 or more, 0.05 or more, 0.07 or more, 0.10 or more, 0.12 or more, 0.15 or more, 0.20 or more, 0.25 or more, 0.30 or more, 0.33 or more, 0.35 or more, 0.40 or less, 0.35 or less, 0.33 or less, 0.30 or less, 0.25 or less, 0.20 or less, 0.17 or less, 0.15 or less, 0.10 or less, 0.08 or less, or 0.05 or less. In aspects, a ratio of the midpoint lithium difference (ΔLi₂O(MP)) to the central surface larger alkali difference (ΔLA(CS)) can be from greater than or equal to 0.01 to less than or equal to 0.40, from greater than or equal to 0.02 to less than or equal to 0.35, from greater than or equal to 0.05 to less than or equal to 0.33, from greater than or equal to 0.07 to less than or equal to 0.30, from greater than or equal to 0.10 to less than or equal to 0.25, from greater than or equal to 0.12 to less than or equal to 0.20, from greater than or equal to 0.15 to less than or equal to 0.17, or any range or subrange therebetween. In preferred aspects, a ratio of the midpoint lithium difference (ΔLi₂O(MP)) to the central surface larger alkali difference (ΔLA(CS)) can be from greater than or equal to 0.01 to less than or equal to 0.40, from greater than or equal to 0.02 to less than or equal to 0.20, from greater than or equal to 0.05 to less than or equal to 0.15, or any range or subrange therebetween.

In aspects, a ratio of the central surface lithium difference (ΔLi₂O(CS)) to the central surface larger alkali difference (ΔLA(CS)) (i.e., ΔLi₂O(CS)/ΔLA(CS)) can be −0.13 or more, −0.12 or more, −0.11 or more, −0.10 or more, −0.08 or more, −0.06 or less, −0.05 or more, −0.04 or more, −0.03 or more, −0.02 or less, −0.01 or more, 0.00 or more, 0.01 or more, 0.02 or more, 0.03 or more, 0.04 or more, 0.05 or more, 0.07 or more, 0.09 or more, 0.13 or less, 0.12 or less, 0.11 or less, 0.10 or less, 0.08 or less, 0.06 or less, 0.05 or less, 0.04 or less, 0.03 or less, 0.02 or less, 0.01 or less, 0.00 or less, −0.01 or less, −0.02 or less, −0.03 or less, −0.04 or less, −0.05 or less, −0.07 or less, or −0.09 or less. In aspects, a ratio of the midpoint lithium difference (ΔLi₂O(MP)) to the central surface larger alkali difference (ΔLA(CS)) can be from greater than or equal to −0.13 to less than or equal to 0.13, from greater than or equal to −0.12 to less than or equal to 0.12, from greater than or equal to −0.11 to less than or equal to 0.11, from greater than or equal to −0.10 to less than or equal to 0.10, from greater than or equal to −0.08 to less than or equal to 0.08, from greater than or equal to −0.06 to less than or equal to −0.06, from greater than or equal to −0.05 to less than or equal to 0.05, from greater than or equal to −0.04 to less than or equal to 0.04, from greater than or equal to −0.03 to less than or equal to 0.03, from greater than or equal to −0.02 to less than or equal to 0.02, from greater than or equal to −0.01 to less than or equal to 0.01, from greater than or equal to 0.00 to less than or equal to 0.01, or any range or subrange therebetween. In preferred aspects, the ratio of the midpoint lithium difference (ΔLi₂O (MP)) to the central surface larger alkali difference (ΔLA(CS)) can be from greater than or equal to −0.15 to less than or equal to 0.15, from greater than or equal to −0.05 to less than or equal to 0.10, from greater than or equal to −0.03 to less than or equal to 0.06, or any range or subrange therebetween.

As used herein, “mixed alkali” metal oxide refers to a combination of (i.e., total amount or total concentration) of sodium oxide and the larger alkali metal oxide. For example, when the larger alkali metal oxide is potassium oxide, a mixed alkali concentration refers to a total concentration of sodium oxide and potassium oxide. As used herein, a “central surface mixed alkali difference” (ΔMA(CS)) is defined as a difference between the first central surface concentration of the mixed alkali metal oxides (MA(1CSC)) (i.e., the concentration of sodium oxide and the larger alkali metal oxide at a center of the first central surface area) and the central concentration of the mixed alkali metal oxides (MA(CC)) (i.e., the concentration of sodium oxide and the larger alkali metal oxide at or otherwise corresponding to the region around the central midpoint of the central portion)—i.e., ΔMA(CS)=MA(1CSC)−MA(CC). In aspects, the central surface mixed alkali difference can be within one or more of the ranges discussed above for the central surface larger alkali difference. In aspects, the central surface mixed alkali difference can be less than or equal to 0.5 mol %, less than or equal to 0.4 mol %, less than or equal to 0.3 mol %, less than or equal to 0.2 mol %, less than or equal to 0.1 mol %, less than or equal to 0.0 mol %, less than or equal to −0.1 mol %, less than or equal to −0.2 mol %, less than or equal to −0.3 mol %, or less than or equal to −0.5 mol %, greater than or equal to −0.7 mol %, greater than or equal to −0.5 mol %, greater than or equal to −0.4 mol %, greater than or equal to −0.3 mol %, greater than or equal to −0.2 mol %, greater than or equal to −0.1 mol %, greater than or equal to −0.0 mol %, or greater than or equal to 0.1 mol %. In aspects, the central surface larger alkali difference can be from greater than or equal to −0.7 mol % to less than or equal to 0.5 mol %, from greater than or equal to −0.5 mol % to less than or equal to 0.4 mol %, from greater than or equal to −0.4 mol % to less than or equal to 0.3 mol %, from greater than or equal to −0.3 mol % to less than or equal to 0.2 mol %, from greater than or equal to −0.2 mol % to less than or equal to 0.1 mol %, from greater than or equal to −0.1 to less than or equal to 0.0 mol %, or any range or subrange therebetween. In preferred aspects, the central surface mixed alkali difference can be from greater than or equal to −0.5 mol % to less than or equal to 0.5 mol %, from greater than or equal to −0.3 mol % to less than or equal to 0.2 mol %, from greater than or equal to −0.2 mol % to less than or equal to 0.0 mol %, or any range or subrange therebetween. In aspects, an absolute value of a ratio of the midpoint lithium difference (ΔLi₂O(MP)) to the central surface mixed alkali difference (ΔMA(CS)) (i.e., ΔLi₂O(MP)/ΔMA(CS)) can be greater than or equal to 0.4, greater than or equal to 0.6, greater than or equal to 0.8, greater than or equal 1.0, greater than or equal 1.5, greater than or equal 2, greater than or equal 3, greater than or equal 4, greater than or equal 5, greater than or equal 7, greater than or equal to 10, greater than or equal to 15, greater than or equal 20, greater than or equal 25, greater than or equal to 33, greater than or equal to 40, less than or equal to 50, less than or equal to 40, less than or equal to 33, less than or equal to 25, less than or equal to 20, less than or equal to 15, less than or equal to 10, less than or equal to 7, less than or equal to 5, less than or equal to 4, less than or equal to 3, less than or equal to 2.5, less than or equal 2.0, less than or equal to 1.5, less than or equal 1.2, less than or equal to 1.0, less than or equal to 0.9, less than or equal to 0.8, less than or equal to 0.7, or less than or equal to 0.6. In aspects, an absolute value of a ratio of the midpoint lithium difference (ΔLi₂O (MP)) to the central surface mixed alkali difference (ΔMA(CS)) (i.e., ΔLi₂O(MP)/ΔMA(CS)) can be from greater than or equal to 0.4 to less than or equal to 50, from greater than or equal to 0.6 to less than or equal to 40, from greater than or equal to 0.8 to less than or equal to 33, less than or equal to 1.0 to less than or equal to 25, from greater than or equal to 1.5 to less than or equal to 20, from greater than or equal to 2 to less than or equal to 15, from greater than or equal to 3 to less than or equal to 10, from greater than or equal to 4 to less than or equal to 7, or any range or subrange therebetween. In preferred aspects, an absolute value of a ratio of the midpoint lithium difference (ΔLi₂O(MP)) to the central surface mixed alkali difference (ΔMA(CS)) (i.e., ΔLi₂O(MP)/ΔMA(CS)) can be from greater than or equal to 0.4 to less than or equal to 50, from greater than or equal to 0.8 to less than or equal to 25, from greater than or equal to 1.0 to less than or equal to 10, or any range or subrange therebetween. In aspects, a ratio of the central surface lithium difference (ΔLi₂O(CS)) to the central surface mixed alkali difference (ΔMA(CS)) (i.e., ΔLi₂O(MP)/ΔMA(CS)) can be 0.7 or more, 0.8 or more, 0.9 or more, 1.0 or more, 1.1 or more, 1.5 or less, 1.4 or less, 1.3 or less, 1.2 or less 1.1 or less, 1.0 or less, or 0.9 or less. In aspects, a ratio of the central surface lithium difference (ΔLi₂O(CS)) to the central surface mixed alkali difference (ΔMA(CS)) (i.e., ΔLi₂O(MP)/AMA (CS)) can be from greater than or equal to 0.7 to less than or equal to 1.5, from greater than or equal to 0.8 to less than or equal to 1.4, from greater than or equal to 0.9 to less than or equal to 1.3, from greater than or equal to 1.0 to less than or equal to 1.2, from greater than or equal to 1.0 to less than or equal to 1.1, or any range or subrange therebetween. In further aspects, the central surface lithium difference (ΔLi₂O(CS)) can be equal to the central surface mixed alkali difference (ΔMA(CS)).

In aspects, a concentration of Na₂O at the first central surface area 213 and/or the second central surface area 243 can be 1.0 mol % or more, 2.0 mol % or more, 3.0 mol % or more, 4.0 mol % or more, 5.0 mol % or more, 5.5 mol % or more, 6.0 mol % or more, 6.5 mol % or more, 7.0 mol % or more, 7.5 mol % or more, 8.0 mol % or more, 8.5 mol % or more, 9.0 mol % or more, 9.5 mol % or more, 10 mol % or more, 15 mol % or less, 14 mol % or less, 13 mol % or less, 12 mol % or less, 11 mol % or less, 10 mol % or less, 9.5 mol % or less, 9.0 mol % or less, 8.5 mol % or less, 8.0 mol % or less, 7.5 mol % or less, 7.0 mol % or less, 6.0 mol % or less, 5.0 mol % or less, 4.0 mol % or less. In aspects, a concentration of Na₂O at the first central surface area 213 and/or the second central surface area 243 can range from greater than or equal to 1.0 mol % to less than or equal to 15 mol %, from greater than or equal to 2.0 mol % to less than or equal to 14 mol %, from greater than or equal to 3.0 mol % to less than or equal to 13 mol %, from greater than or equal to 4.0 mol % to less than or equal to 12 mol %, from greater than or equal to 5.0 mol % to less than or equal to 11 mol %, from greater than or equal to 5.5 mol % to less than or equal to 10 mol %, from greater than or equal to 6.0 mol % to less than or equal to 9.5 mol %, from greater than or equal to 6.5 mol % to less than or equal to 9.0 mol %, from greater than or equal to 7.0 mol % to less than or equal to 8.5 mol %, from greater than or equal to 7.5 mol % to less than or equal to 8.0 mol %, or any range or subrange therebetween. In preferred aspects, concentration of Na₂O at the first central surface area 213 and/or the second central surface area 243 can be from greater than or equal to 1.0 mol % to less than or equal to 15 mol %, from greater than or equal to 5.0 mol % to less than or equal to 13 mol %, from greater than or equal to 6.0 mol % to less than or equal to 10 mol %, or any range or subrange therebetween.

As used herein, a “total thickness variation” (TTV) of the central portion refers to the absolute value of the difference between the minimum thickness of the central portion 281 (e.g., central region 248) and the maximum thickness of the central portion 281 (e.g., central region 248). The maximum thickness and minimum thickness are measured by combining the 3D surfaces measured for each surface of the region (e.g., central portion 281, central region 248) using SpecGAGE3D, as described above. In aspects, the central portion 281 and/or the central region 248 can comprise a TTV of 6 μm or less, 5 μm or less, 4 μm or less, 3.8 μm or less, 3.6 μm or less, or 3.4 μm or less. In aspects, the central portion 281 and/or the central region 248 can comprise a TTV in a range from 0.5 μm to 6 μm, from 1 μm to 5 μm, from 1.5 μm to 4 μm, from 2 μm to 3.8 μm, from 2.5 μm to 3.6 μm, from 3 μm to 3.4 μm, or any range or subrange therebetween. Providing a low TTV (e.g., 6 μm or less) can further decrease an incidence of buckling by reducing variation in chemically-strengthening induced strain associated with the expansion or contraction due to ion-exchange.

As used herein, refractive index is measured in accordance with ASTM E1967-19 at a wavelength of 589 nm. In aspects, the polymer-based portion 289 and/or 299 can be optically clear and/or comprise a first index of refraction. In aspects, the first refractive index of the polymer-based portion 289 and/or 299 may be 1.3 or more, 1.4 or more, 1.45 or more, 1.49 or more, 2 or less, 1.7 or less, 1.6 or less, or 1.55 or less. In aspects, the first refractive index of the polymer-based portion 289 and/or 299 can range from 1 to 2, from 1.3 to 1.7, from 1.4 to 1.6, from 1.45 to 1.55, from 1.49 to 1.55, or any range or subrange therebetween. In aspects, a differential equal to the absolute value of the difference between a second index of refraction of the foldable substrate 201 and the first index of refraction of the polymer-based portion 289 and/or 299 can be 0.1 or less, 0.07 or less, 0.05 or less, 0.001 or more, 0.01 or more, or 0.02 or more. In aspects, the differential is in a range from 0.001 to 0.1, from 0.01 to 0.07, from 0.02 to 0.05, or any range or subrange therebetween. In aspects, the second index of refraction of the foldable substrate 201 may be greater than the first index of refraction of the polymer-based portion 289 and/or 299. In aspects, the second index of refraction of the foldable substrate 201 may be less than the first index of refraction of the polymer-based portion 289 and/or 299.

In aspects, the adhesive layer 261 can comprise a third index of refraction. In aspects, the third index of refraction of the adhesive layer 261 can be within one or more of the ranges discussed above with regards to the first index of refraction of the polymer-based portion 289 and/or 299. In aspects, a differential equal to the absolute value of the difference between the third index of refraction of the adhesive layer 261 and the first index of refraction of the polymer-based portion 289 and/or 299 can be within one or more of the ranges discussed above for the differential between the second index of refraction and the first index of refraction. In aspects, the third index of refraction of the adhesive layer 261 may be greater than the first index of refraction of the polymer-based portion 289 and/or 299. In aspects, the third index of refraction of the adhesive layer 261 may be less than the first index of refraction of the polymer-based portion 289 and/or 299. In aspects, a differential equal to the absolute value of the difference between the third index of refraction of the adhesive layer 261 and the second index of refraction of the foldable substrate 201 can be within one or more of the ranges discussed above for the differential between the second index of refraction and the first index of refraction. In aspects, the third index of refraction of the adhesive layer 261 may be greater than the second index of refraction of the foldable substrate 201. In aspects, the third index of refraction of the adhesive layer 261 may be less than the second index of refraction of the foldable substrate 201.

In aspects, the coating 251 can comprise a fourth index of refraction. In aspects, the fourth index of refraction of the coating 251 can be within one or more of the ranges discussed above with regards to the first index of refraction of the polymer-based portion 289 and/or 299. In aspects, a differential equal to the absolute value of the difference between the fourth index of refraction of the coating 251 and the first index of refraction of the polymer-based portion 289 and/or 299 can be within one or more of the ranges discussed above for the differential between the second index of refraction and the first index of refraction. In aspects, the fourth index of refraction of the coating 251 may be greater than the first index of refraction of the polymer-based portion 289 and/or 299. In aspects, the fourth index of refraction of the coating 251 may be less than the first index of refraction of the polymer-based portion 289 and/or 299. In aspects, a differential equal to the absolute value of the difference between the fourth index of refraction of the coating 251 and the second index of refraction of the foldable substrate 201 can be within one or more of the ranges discussed above for the differential between the second index of refraction and the first index of refraction. In aspects, the fourth index of refraction of the coating 251 may be greater than the second index of refraction of the foldable substrate 201. In aspects, the fourth index of refraction of the coating 251 may be less than the second index of refraction of the foldable substrate 201. In aspects, a differential equal to the absolute value of the difference between the fourth index of refraction of the coating 251 and the third index of refraction of the adhesive layer 261 can be within one or more of the ranges discussed above for the differential between the second index of refraction and the first index of refraction. In aspects, the fourth index of refraction of the coating 251 may be greater than the third index of refraction of the adhesive layer 261. In aspects, the fourth index of refraction of the coating 251 may be less than the third index of refraction of the adhesive layer 261.

FIGS. 4-6 schematically illustrate aspects of a foldable apparatus 401 and/or 601 in accordance with aspects of the disclosure in a folded configuration. As shown in FIG. 5, the foldable apparatus 401 is folded such that the second major surface 205 of the foldable substrate 201 is on the inside of the folded foldable apparatus 401, for example, foldable apparatus 301 can be folded to form foldable apparatus 401. For example, a display could be located on the side of the second major surface 205, and a viewer would view the display from the side of the first major surface 203. Alternatively, a display could be located on the side of the first major surface 203, and a viewer would view the display from the side of the second major surface 205. As shown in FIG. 6, the foldable apparatus 601 is folded such that the first major surface 203 of the foldable substrate 201 is on the inside of the folded foldable apparatus 601, for example, foldable apparatus 101 can be folded to form foldable apparatus 601.

As shown in FIG. 6, the foldable apparatus 101 shown in FIG. 1 (modified as described in the Parallel Plate Test below) is folded to form folded foldable apparatus 601 such that the first major surface 203 of the foldable substrate 201 is on the inside of the folded foldable apparatus 601. In FIG. 6, a user would view a display device in place of the PET sheet 507 through the foldable substrate 201 and, thus, would be positioned on the side of the second major surface 205. In aspects, as shown in FIG. 6, the foldable apparatus 601 can comprise a coating 251 disposed over the foldable substrate 201 (e.g., first major surface 203). In further aspects, a user would view a display device in place of the PET sheet 507 through the coating 251. In aspects, as shown in FIG. 6, the polymer-based portion 289 and/or 299 can be disposed over the foldable substrate 201. In further aspects, although not shown, an additional substrate (e.g., glass-based substrate and/or ceramic-based substrate in place of release liner 271 or PET sheet 507), and the additional substrate can be disposed over a display device. As shown in FIG. 5, the foldable apparatus 401 is folded such that the second major surface 205 of the foldable substrate 201 is on the inside of the folded foldable apparatus. In FIG. 5, a user would view a display device in place of the PET sheet 507 through the foldable substrate 201 and, thus, would be positioned on the side of the second major surface 205. It is to be understood that the foldable apparatus can be designed to fold such that the display device is on the inside of the bend, on the outside of the bend, or such that the foldable apparatus can be folded in either direction.

As used herein, “foldable” includes complete folding, partial folding, bending, flexing, or multiple capabilities. As used herein, the terms “fail,” “failure” and the like refer to breakage, destruction, delamination, or crack propagation. Likewise, a foldable apparatus achieves a parallel plate distance of “X,” or has a parallel plate distance of “X,” or comprises a parallel plate distance of “X” if it resists failure when the foldable apparatus is held at a parallel plate distance of “X” for 24 hours at 85 °C and 85% relative humidity.

As used herein, the “parallel plate distance” of a foldable apparatus and/or foldable substrate is measured with the following test configuration and process using a parallel plate apparatus 501 (see FIGS. 5-6) that comprises a pair of parallel rigid stainless-steel plates 503, 505 comprising a first rigid stainless-steel plate 503 and a second rigid stainless-steel plate 505. When measuring the “parallel plate distance” for the foldable substrate 201, as shown in FIG. 5, the foldable substrate 201 is placed between the pair of rigid stainless-steel plates 503 and 505 such that the second major surface 205 is on the inside of the bent configuration, where test adhesive layer 509 comprising a thickness of 50 μm and a 100 μm thick polyethylene terephthalate (PET) sheet 507 are disposed over the first major surface 203 with the PET sheet 507 contacting the rigid stainless-steel plates 503, 505. When measuring the “parallel plate distance” for a foldable apparatus resembling the foldable apparatus 101 and 601 shown in FIGS. 2 and 6, respectively, the adhesive layer 261 is removed and is replaced by a test adhesive layer 509 comprises a thickness of 50 μm. Further, the test is conducted with a 100 μm thick polyethylene terephthalate (PET) sheet 507 rather than with the release liner 271 of FIG. 2. Thus, during the test to determine the “parallel plate distance” of a configuration of a foldable apparatus, the foldable apparatus 601 is produced by using the 100 μm thick PET sheet 507 rather than with the release liner 271 of FIG. 2.

When preparing the foldable apparatus 601, the 100 μm thick PET sheet 507 is attached to the test adhesive layer 509 in an identical manner that the release liner 271 is attached to the second contact surface 265 of the adhesive layer 261 as shown in FIG. 2. To test the foldable apparatus 601 of FIG. 6, the test adhesive layer 509 and the PET sheet 507 can likewise be installed as shown in the configuration of FIG. 6 to conduct the test on the foldable apparatus 601. The foldable apparatus 601 is placed between the pair of parallel rigid stainless-steel plates 503 and 505 such that the foldable substrate 201 will be on the inside of the bend, similar to the configuration shown in FIG. 6. For determining a “parallel plate distance”, the distance between the parallel plates is reduced at a rate of 50 μm/second until the parallel plate distance 511 is equal to the “parallel plate distance” to be tested. Then, the parallel plates are held at the “parallel plate distance” to be tested for 24 hours at 85 °C and 85% relative humidity. As used herein, the “minimum parallel plate distance” is the smallest parallel plate distance that the foldable apparatus can withstand without failure under the conditions and configuration described above.

In aspects, the foldable apparatus 101, 301, 401, and/or 601 and/or foldable substrate 201 can achieve a parallel plate distance of 100 mm or less, 50 mm or less, 20 mm or less, 10 mm or less, 5 mm or less, or 3 mm or less. In further aspects, the foldable apparatus and/or foldable substrate can achieve a parallel plate distance of 50 millimeters (mm), or 20 mm, or 10 mm, of 5 mm, or 3 mm. In aspects, the foldable apparatus and/or foldable substrate can comprise a minimum parallel plate distance of 40 mm or less, 20 mm or less, 10 mm or less, 5 mm or less, 3 mm or less, 1 mm or less, 1 mm or more, 3 mm or more, 5 mm or more, or 10 mm or more. In aspects, the foldable apparatus and/or foldable substrate can comprise a minimum parallel plate distance in a range from 1 mm to 40 mm, from 1 mm to 20 mm, from 1 mm to 10 mm, from 1 mm to 5 mm, from 1 mm to 3 mm. In aspects, the foldable apparatus and/or foldable substrate can achieve a minimum parallel plate distance in a range from 2 mm to 40 mm, from 2 mm to 20 mm, from 3 mm to 10 mm, from 3 mm to 5 mm, or any range or subrange therebetween.

A central width 287 of the central portion 281 of the foldable substrate 201 is defined between the first portion 221 and the second portion 231 in the direction 106 of the length 105. In aspects, the central width 287 of the central portion 281 of the foldable substrate 201 can extend from the first portion 221 to the second portion 231. A width 210 of the first central surface area 213 and the second central surface area 243 of the foldable substrate 201 is defined between the first transition region 212 and the second transition region 218, for example, as the portion comprising the central thickness 209, in the direction 106 of the length 105. In aspects, the central width 287 of the central portion 281 of the foldable substrate 201 and/or the width 210 of the first central surface area 213 of the foldable substrate 201 can be 1.4 times or more, 1.6 times or more, 2 times or more, 2.2 times or more, 3 times or less, or 2.5 times or less the minimum parallel plate distance. In aspects, the central width 287 of the central portion 281 of the foldable substrate 201 and/or the width 210 of the first central surface area 213 of the foldable substrate 201 as a multiple of the minimum parallel plate distance can range from 1.4 times to 3 times, from 1.6 times to 2.5 times, from 2 times to 2.5 times, from 2.2 times to 2.5 times, or any range or subrange therebetween. Without wishing to be bound by theory, the length of a bent portion in a circular configuration between parallel plates can be 1.6 times the parallel plate distance. Without wishing to be bound by theory, the length of a bend portion in an elliptical configuration between parallel plates can be 2.2 times the parallel plate distance. In aspects, the central width 287 of the central portion 281 of the foldable substrate 201 and/or the width 210 of the first central surface area 213 of the foldable substrate 201 can be 1 mm or more, 3 mm or more, 5 mm or more, 8 mm or more, 10 mm or more, 15 mm or more, 20 mm or more, 60 mm or less, 50 mm or less, 40 mm or less, 35 mm or less, 30 mm or less, or 25 mm or less. In aspects, the central width 287 of the central portion 281 of the foldable substrate 201 and/or the width 210 of the first central surface area 213 of the foldable substrate 201 can range from 1 mm to 100 mm, from 3 mm to 60 mm, from 5 mm to 50 mm, from 8 mm to 40 mm, from 10 mm to 40 mm, from 15 mm to 35 mm, from 20 mm to 30 mm, or any range of subrange therebetween. In aspects, the central width 287 of the central portion 281 of the foldable substrate 201 and/or the width 210 of the first central surface area 213 of the foldable substrate 201 can be 2.8 mm or more, 6 mm or more, 9 mm or more, 60 mm or less, 40 mm, or less, or 24 mm or less. In aspects, the central width 287 of the central portion 281 of the foldable substrate 201 and/or the width 210 of the first central surface area 213 of the foldable substrate 201 can range from 2.8 mm to 40 mm, from 6 mm to 24 mm, or any range of subrange therebetween. In aspects, the first central surface area 213, the central portion 281 (e.g., centerline of the central portion 281), and/or the fold plane 109 can correspond to a midpoint between opposing ends of the foldable substrate and/or the foldable apparatus in the direction 106 of the length 105. By providing a width within the above-noted ranges for the central portion, folding of the foldable apparatus without failure can be facilitated.

In aspects, the foldable substrate and/or the foldable apparatus can be rollable. As used herein, a foldable substrate or a foldable apparatus is “rollable” if it can achieve a threshold parallel plate distance over a length of the corresponding foldable substrate and/or foldable apparatus that is the greater of 10 mm or 10% of the length of the corresponding foldable substrate and/or foldable apparatus. For example, as shown in FIGS. 2-3, the foldable substrate 201 is considered “rollable” when the central width 287 of the central portion 281 is greater than 10% of the length 105 (see FIG. 1) extending in the direction 106 of the length 105.

Additionally or alternatively, the central width 287 can be greater than a first width of the first portion and/or a second width of the second portion. In aspects, the central width 287, as a percentage of the length of the foldable substrate 201 and/or the foldable apparatus 101 and/or 301, can be 15% or more, 20% or more, 25% or more, 30% or more, 35% or more, 40% or more, 42% or more, 44% or more, 45% or more, 50% or less, 49% or less, 48% or less, 47% or less, 46% or less, 45% or less, 38% or less, or 32% or less. In aspects, the central width 287, as a percentage of the length of the foldable substrate 201 and/or the foldable apparatus 101 and/or 301, can range from 15% to 50%, from 20% to 50%, from 25% to 49%, from 30% to 49%, from 35% to 48%, from 40% to 48%, from 42% to 47%, from 43% to 46%, from 44% to 45%, or any range or subrange therebetween. In further aspects, the second width can be less than the central width 287. Providing a central width within one or more of the ranges mentioned above in this paragraph can enable a display portion of the foldable apparatus to be adjusted as a portion of the rollable substrate is moved into and/or out of view of a user without unnecessarily expanding a size of the corresponding apparatus when in a fully rolled configuration.

The foldable apparatus 101, 301, 401, and/or 601 may have an impact resistance defined by the capability of a region of the foldable apparatus (e.g., a region comprising the first portion 221, a region comprising the second portion 231, a region comprising the polymer-based portion 289 and/or 299 and/or central portion 281) to avoid failure at a pen drop height (e.g., 5 centimeters (cm) or more, 10 centimeters or more, 20 cm or more), when measured according to the “Pen Drop Test.” As used herein, the “Pen Drop Test” is conducted such that samples of foldable apparatus are tested with the load (i.e., from a pen dropped from a certain height) imparted to an outer major surface (e.g., first major surface 203 of the foldable substrate 201 for foldable apparatus 101 or 301 shown in FIGS. 2-3, second major surface 205 of the foldable substrate 201 for foldable apparatus 301 or 401 shown in FIGS. 3-4) with the foldable apparatus configured as in the parallel plate test with 100 μm thick PET sheet 507 attached to the test adhesive layer 509 having a thickness of 50 μm (as shown in FIGS. 5-6) instead of the release liner 271 shown in FIG. 2. As such, the PET layer in the Pen Drop Test is meant to simulate a foldable electronic display device (e.g., an OLED device). During testing, the foldable apparatus bonded to the PET layer is placed on an aluminum plate (6063 aluminum alloy, as polished to a surface roughness with 400 grit paper) with the PET layer in contact with the aluminum plate. No tape is used on the side of the sample resting on the aluminum plate.

A tube is used for the Pen Drop Test to guide a pen to an outer surface of the foldable apparatus. For the foldable apparatus 101, 301, 401, and/or 601 in FIGS. 2-3 and 5-6, the pen is guided to the outer major surface (e.g., third major surface 253 of the coating 251 or first major surface 203 of the foldable substrate 201 for foldable apparatus 101 shown in FIG. 2, second major surface 205 of the foldable substrate 201 for foldable apparatus 301 shown in FIG. 3), and the tube is placed in contact with the outer major surface of the foldable substrate 201 and/or foldable apparatus so that the longitudinal axis of the tube is substantially perpendicular to the outer major surface with the longitudinal axis of the tube extending in the direction of gravity. The tube has an outside diameter of 1 inch (2.54 cm), an inside diameter of nine-sixteenths of an inch (1.4 cm), and a length of 90 cm. An acrylonitrile butadiene (ABS) shim is employed to hold the pen at a predetermined height for each test. After each drop, the tube is relocated relative to the sample to guide the pen to a different impact location on the sample. The pen employed in Pen Drop Test is a BIC Easy Glide Pen, Fine, having a tungsten carbide ballpoint tip of 0.7 mm (0.68 mm) diameter, and a weight of 5.73 grams (g) including the cap.

For the Pen Drop Test, the pen is dropped with the cap attached to the top end (i.e., the end opposite the tip) so that the ballpoint can interact with the test sample. In a drop sequence according to the Pen Drop Test, one pen drop is conducted at an initial height of 1 cm, followed by successive drops in 0.5 cm increments up to 20 cm, and then after 20 cm, 2 cm increments until failure of the test sample. After each drop is conducted, the presence of any observable fracture, failure, or other evidence of damage to the sample is recorded along with the particular pen drop height. Using the Pen Drop Test, multiple samples can be tested according to the same drop sequence to generate a population with improved statistical accuracy. For the Pen Drop Test, the pen is to be changed to a new pen after every 5 drops, and for each new sample tested. In addition, all pen drops are conducted at random locations on the sample at or near the center of the sample, with no pen drops near or on the edge of the samples.

For purposes of the Pen Drop Test, “failure” means the formation of a visible mechanical defect in a laminate. The mechanical defect may be a crack or plastic deformation (e.g., surface indentation). The crack may be a surface crack or a through crack. The crack may be formed on an interior or exterior surface of a laminate. The crack may extend through all or a portion of the foldable substrate 201 and/or coating. A visible mechanical defect has a minimum dimension of 0.2 mm or more.

In aspects, the foldable apparatus can resist failure for a pen drop in a region comprising the first portion 221 or the second portion 231 at a pen drop height of 10 centimeters (cm), 12 cm, 14 cm, 16 cm, or 20 cm. In aspects, a maximum pen drop height that the foldable apparatus can withstand without failure over a region comprising the first portion 221 or the second portion 231 may be 10 cm or more, 12 cm or more, 14 cm or more, 16 cm or more, 40 cm or less, 30 cm or less, 20 cm or less, or 18 cm or less. In aspects, a maximum pen drop height that the foldable apparatus can withstand without failure over a region comprising the first portion 221 or the second portion 231 can range from 10 cm to 40 cm, from 12 cm to 30 cm, from 14 cm to 20 cm, from 16 cm to 20 cm, from 18 cm to 20 cm, or any range or subrange therebetween.

In aspects, the foldable apparatus can resist failure for a pen drop in a region (e.g., central portion 281) comprising the polymer-based portion 289 and/or 299 between the first portion 221 and the second portion 231 at a pen drop height of 1 cm, 2 cm, 3 cm, 4 cm, 5 cm, or more. In aspects, a maximum pen drop height that the foldable apparatus can withstand without failure over a region comprising the polymer-based portion 289 and/or 299 between the first portion 221 and the second portion 231 may be 1 cm or more, 2 cm or more, 3 cm or more, 4 cm or more, 20 cm or less, 10 cm or less, 8 cm or less, or 6 cm or less. In aspects, a maximum pen drop height that the foldable apparatus can withstand without failure over a region comprising the polymer-based portion 289 and/or 299 between the first portion 221 and the second portion 231 can range from 1 cm to 20 cm, from 2 cm to 10 cm, from 3 cm to 8 cm, from 4 cm to 8 cm, from 4 cm to 6 cm, or any range or subrange therebetween. In aspects, a maximum pen drop height that the foldable apparatus can withstand without failure of a region comprising the polymer-based portion 289 and/or 299 between the first portion 221 and the second portion 231 can range from 1 cm to 10 cm, from 1 cm to 8 cm, from 2 cm to 5 cm, from 3 cm to 5 cm, from 4 cm to 5 cm, or any range or subrange therebetween.

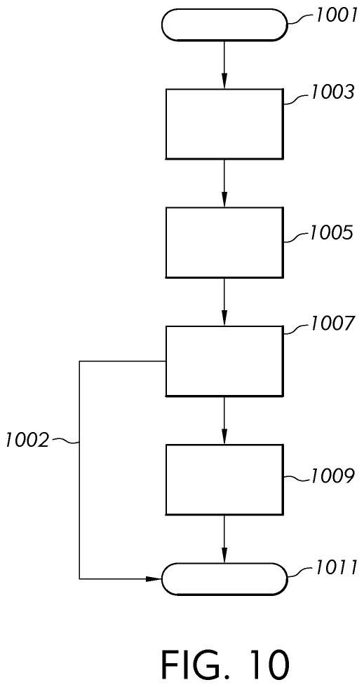

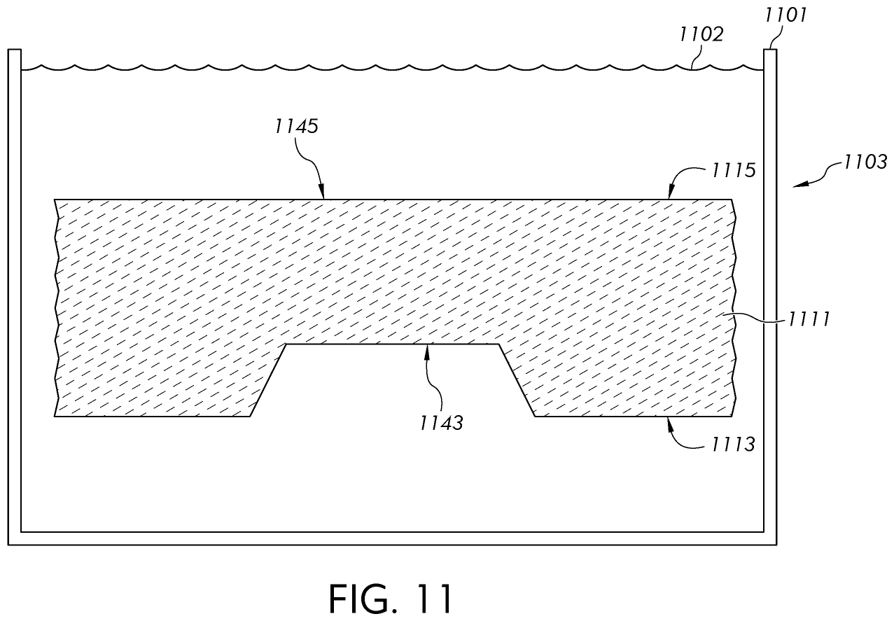

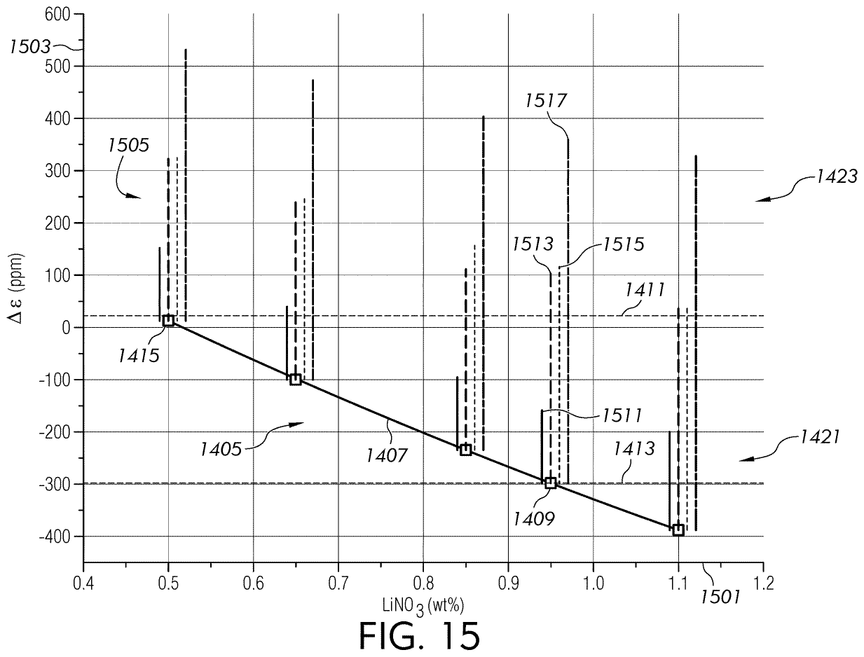

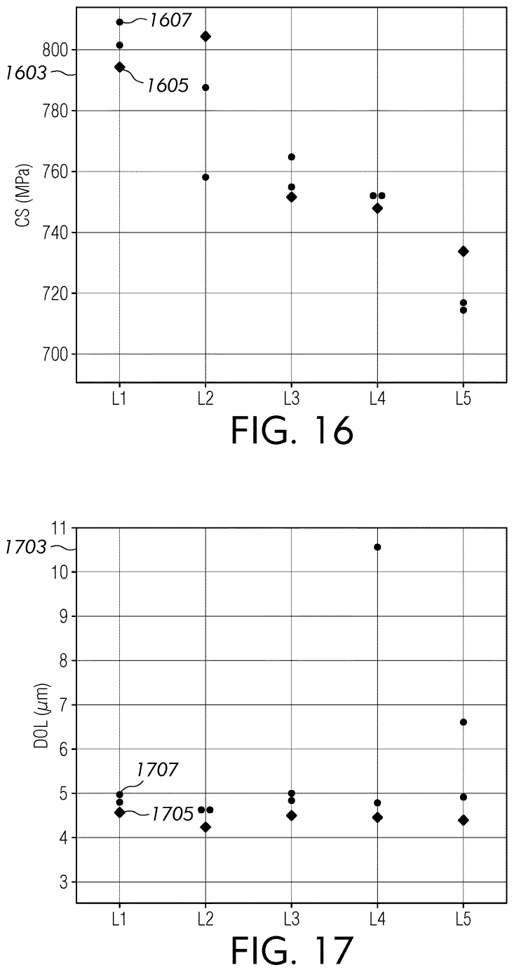

Aspects of methods of making the foldable apparatus 101, 301, 401, and/or 601 and/or foldable substrate 201 illustrated in FIGS. 2-3 and 5-6 in accordance with aspects of the disclosure will be discussed with reference to the flow chart in FIG. 10 and example method steps illustrated in FIGS. 11-14, schematic development of expansion induced strain in FIGS. 15-16, and the schematical stress profiles illustrated in FIG. 20.

In a first step 1001 of methods of the disclosure, methods can start with obtaining an initial substrate 1111 (see FIG. 11—corresponding to the general shape and/or dimensions of the resulting foldable substrate 201). In aspects, the initial substrate 1111 may be provided by purchase or otherwise obtaining a substrate or by forming the foldable substrate. In aspects, the initial substrate 1111 can comprise a glass-based substrate and/or a ceramic-based substrate. In further aspects, glass-based substrates and/or ceramic-based substrates can be provided by forming them with a variety of ribbon forming processes, for example, slot draw, down-draw, fusion down-draw, up-draw, press roll, redraw, or float. In further aspects, ceramic-based substrates can be provided by heating a glass-based substrate to crystallize one or more ceramic crystals. In aspects, the initial substrate 1111 can be unstrengthened at the end of step 1001, although the initial substrate may comprise one or more compressive stress regions at the end of step 1001 in other aspects. As used herein, unstrengthened refers to a substrate comprising either no depth of layer, no depth of compression, a depth of layer in a range from 0% to 5% of the substrate thickness, or a depth of compression in a range from 0% to 5% of the substrate thickness. In aspects, the initial substrate 1111 can correspond to an initial foldable substrate 1103 when the initial substrate is provided with at least one recess (e.g., the existing first central surface area 1143 recessed from the existing first major surface 1113), although the at least one recess can be formed by etching and/or mechanically removing material before the end of step 1001 to form the initial foldable substrate 1103. In aspects, as shown in FIG. 11, in step 1001, the initial substrate 1111 can comprise an existing first central surface area 1143 recessed from an existing first major surface 1113. As shown, the initial substrate 1111 has an existing second major surface 1115 opposite the existing first major surface, where an initial substrate thickness defined therebetween that can be within one or more of the ranges discussed above for the substrate thickness and/or the initial substrate thickness can be greater than the resulting substrate thickness by an amount (e.g., less than or equal to 20 μm, less than or equal to 10 μm, less than or equal to 4 μm) corresponding to a total thickness removed (including outer layer removed from both major surfaces) in a subsequent etching step (see step 1007 discussed below). As shown, the initial substrate 1111 has an existing second central surface area 1145 opposite the existing first central surface area 1143, where an initial central thickness defined therebetween that can be within one or more of the ranges discussed above for the central thickness and/or the initial central thickness can be greater than the resulting central thickness by the same amount that the initial substrate thickness is greater than the resulting substrate thickness. Additionally, in aspects, corresponding to the foldable substrate shown in FIG. 2, the initial substrate can additionally comprise the existing second central surface area recessed from the existing second major surface, although the second central surface area can be flush and/or coplanar with second major surface (see FIGS. 3 and 11).

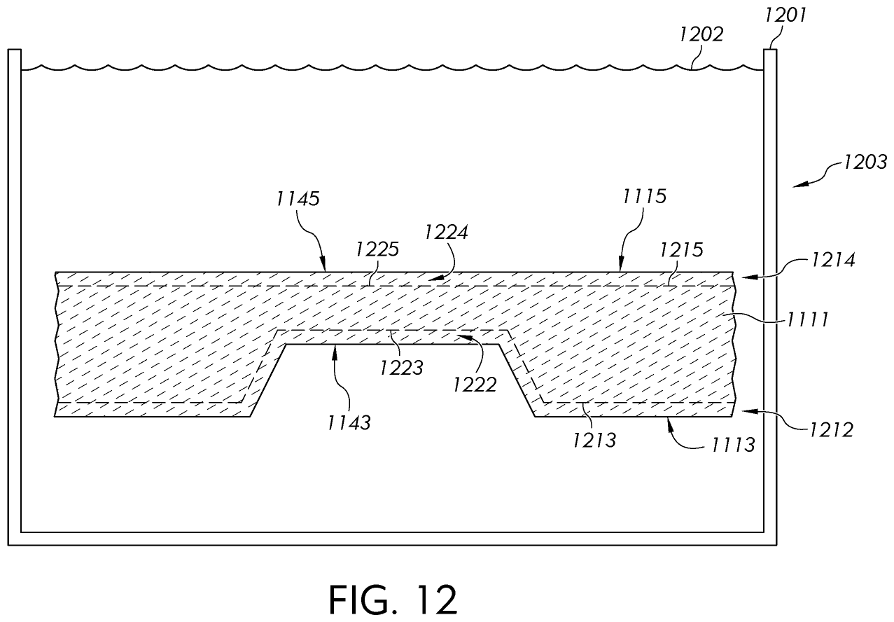

After step 1001, as shown in FIG. 11, methods can proceed to step 1003 comprising chemically strengthening the initial substrate 1111 (e.g., the initial foldable substrate 1103) to form an initially strengthened substrate 1203 (see FIG. 12). In aspects, as shown, chemically strengthening the initial substrate 1111 (e.g., initial foldable substrate 1103) can comprise contacting at least a portion of the initial substrate 1111 a first molten salt solution 1102 (e.g., contained in a first molten salt bath 1101). Chemically strengthening a substrate (e.g., glass-based substrate, ceramic-based substrate) by ion exchange can occur when a first cation within a depth of a surface of the substrate is exchanged with a second cation within a molten salt solution that has a larger radius than the first cation. For example, a lithium cation or a sodium cation within the depth of the surface of the initial foldable substrate 1103 can be exchanged with a potassium cation within a first molten salt solution 1102. Consequently, the surface of the initial foldable substrate 1103 can placed in compression and thereby chemically strengthened by the ion exchange process since the lithium cation has a smaller radius than the radius of the exchanged sodium cation or potassium cation within the first molten salt solution 1102. Additionally or alternatively, as discussed below, the first molten salt solution can comprise a lithium salt that can cause reverse ion-exchange (i.e., exchanging an alkali metal from the initial substrate having a larger ionic radius than lithium with the lithium in the molten salt solution) to occur between the first molten salt solution and the initial substrate, which can occur simultaneously with the ion-exchange discussed above in this paragraph. In further aspects, as shown, the existing first major surface 1113 and the existing first central surface area 1143 can be in direct contact with and simultaneously ion-exchanged with the first molten salt solution 1102, for example, by immersing (e.g., completely immersing) the initial foldable substrate 1103 in the first molten salt solution 1102 contained in the first molten salt bath 1101 (e.g., with the existing second major surface 1115 and the existing second central surface area 1145 also in direct contact with and simultaneously ion-exchanged with the first molten salt solution 1102).

In aspects, the chemical strengthening in step 1003 can occur for a first period of time while the first molten salt solution 1102 is maintained at a first temperature. In further aspects, the first temperature can be 350 °C or more, 370 °C or more, 380 °C or more, 390 °C or more, 400 °C or more, 410 °C or more, 420 °C or more, 430 °C or more, 500 °C or less, 480 °C or less, 450 °C or less, 430 °C or less, 420 °C or less, 410 °C or less, 400 °C or less, or 390 °C or less. In aspects, the first temperature of can range from greater than or equal to 350 °C to less than or equal to 500 °C, from greater than or equal to 370 °C to less than or equal to 480 °C, from greater than or equal to 380 °C to less than or equal to 450 °C, from greater than or equal to 390 °C to less than or equal to 430 °C, from greater than or equal to 400 °C to less than or equal to 420 °C, or any range or subrange therebetween. In aspects, the first period of time can be 1 minute or more, 2 minutes or more, 3 minutes or more, 4 minutes or more, 5 minutes or more, 7 minutes or more, 10 minutes or more, 30 minutes or less, 15 minutes or less, 10 minutes or less, 7 minutes or less, 5 minutes or less, or 3 minutes or less. In aspects, the first period of time can be from greater than or equal to 1 minute to less than or equal to 30 minutes, from greater than or equal to 2 minutes to less than or equal to 15 minutes, from greater than or equal to 3 minutes to less than or equal to 10 minutes, from greater than 4 minutes to less than or equal to 7 minutes, or any range or subrange therebetween. Without wishing to be bound by theory, lithium diffuses through glass-based materials faster than larger alkali metals; consequently, in combination with the relatively low central thickness, the relatively short first period of time can be sufficient to develop the midpoint lithium difference discussed above and/or for lithium from the first molten salt solution to be present throughout the entire central portion.

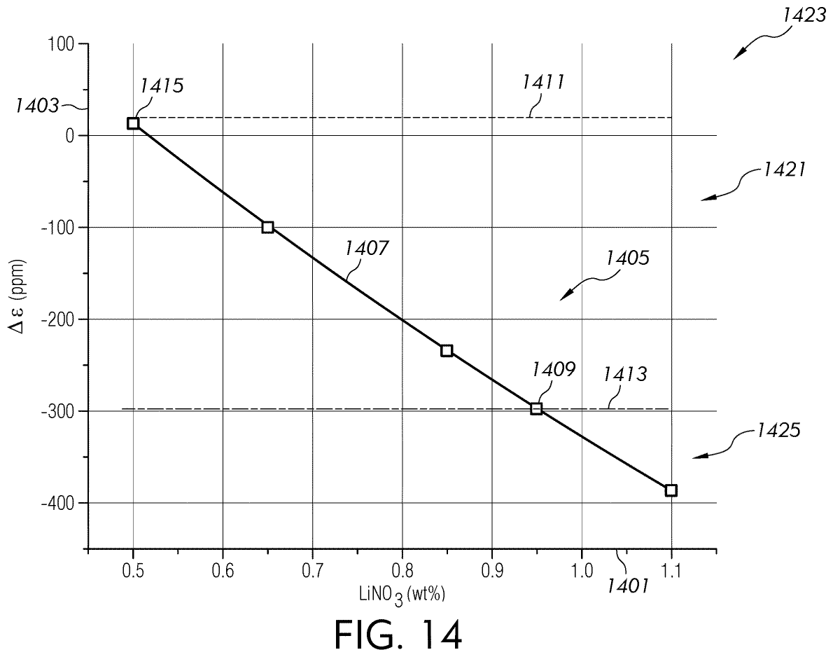

In aspects, the first molten salt solution 1102 comprise a lithium salt. In further aspects, an amount of the lithium salt in the first molten salt solution, based on 100 wt % of the first molten salt solution, can be greater than or equal to 0.1 wt %, greater than or equal to 0.20 wt %, from greater than or equal to 0.25 wt %, greater than or equal to 0.30 wt %, greater than or equal to 0.35 wt %, greater than or equal to 0.40 wt %, greater than or equal to 0.45 wt %, greater than or equal to 0.50 wt %, greater than or equal to 0.55 wt %, greater than or equal to 0.60 wt %, greater than or equal to 0.65 wt %, greater than or equal to 0.70 wt %, greater than or equal to 0.75 wt %, greater than or equal to 0.80 wt %, less than or equal to 2.00 wt %, less than or equal to 1.75 wt %, less than or equal to 1.50 wt %, less than or equal to 1.25 wt %, less than or equal to 1.0 wt %, less than or equal to 0.95 wt %, less than or equal to 0.90 wt %, less than or equal to 0.85 wt %, less than or equal to 0.80 wt %, less than or equal to 0.75 wt %, less than or equal to 0.70 wt %, less than or equal to 0.65 wt %, less than or equal to 0.60 wt %, less than or equal to 0.55 wt %, less than or equal to 0.50 wt %, less than or equal to 0.45 wt %, less than or equal to 0.40 wt %, less than or equal to 0.35 wt %, less than or equal to 0.30 wt %, or less than or equal to 0.25 wt %. In aspects, an amount of the lithium salt in the first molten salt solution, based on 100 wt % of the first molten salt solution, can be from greater than or equal to 0.1 wt % to less than or equal to 2.0 wt %, from greater than or equal to 0.20 wt % to less than or equal to 1.75 wt %, from greater than or equal to 0.25 wt % to less than or equal to 1.50 wt %, from greater than or equal to 0.25 wt % to less than or equal to 1.25 wt %, from greater than or equal to 0.30 wt % to less than or equal to 1.00 wt %, from greater than or equal to 0.30 wt % to less than or equal to 0.95 wt %, from greater than or equal to 0.35 wt % to less than or equal to 0.90 wt %, from greater than or equal to 0.35 wt % to less than or equal to 0.85 wt %, from greater than or equal to 0.40 wt % to less than or equal to 0.80 wt %, from greater than or equal to 0.40 wt % to less than or equal to 0.75 wt %, from greater than or equal to 0.45 wt % to less than or equal to 0.70 wt %, from greater than or equal to 0.50 wt % to less than or equal to 0.65 wt %, from greater than or equal to 0.55 wt % to less than or equal to 0.60 wt %, or any range or subrange therebetween. In preferred aspects, an amount of the lithium salt in the first molten salt solution, based on 100 wt % of the first molten salt solution, can be from greater than or equal to 0.1 wt % to less than or equal to 2.0 wt %, from greater than or equal to 0.25 wt % to less than or equal to 1.0 wt %, or from greater than or equal to 0.45 wt % to less than or equal to 0.85 wt %, or any range or subrange therebetween. Providing from 0.1 wt % to 2.0 wt % (e.g., from 0.25 wt % to 1.0 wt %, from 0.45 wt % to 0.85 wt %) of a lithium salt in the first molten salt solution can generate an expansion-induced strain difference between the first portion and the second portion that is opposite of that normally encountered when chemically strengthening a foldable substrate having a central portion thinner than an adjacent first portion since lithium has the opposite effect of the larger alkali metal. This can be the case, as demonstrated in FIGS. 14-15, even when the first molten salt solution comprises both the lithium salt and a larger alkali metal salt (e.g., potassium salt). It is believed that without the lithium salt in the first molten salt bath it would not be possible to achieve the compressive stress and mechanical performance of the resulting foldable substrate without buckling or severe warping of the central portion and/or making the central portion frangible, especially when no masks or other barriers are placed between any portion of the foldable substrate and the corresponding molten salt solution throughout the chemical strengthening steps herein.

In aspects, the first molten salt solution 1102 in step 1003 can comprise a salt of the larger alkali metal (e.g., potassium) and optionally a sodium salt. In further aspects, the sodium salt, if present, can comprise sodium nitrate, although the sodium salt can be sodium carbonate, sodium sulfate, sodium chloride, etc. in other aspects—in addition to combinations of any of these salts. Likewise, in further aspects, the anion of the salt of the larger alkali metal can be nitrate (e.g., potassium nitrate), although the anion can be carbonate, sulfate, chloride, etc. in other aspects—in addition to combinations of any of these salts. In further aspects, an amount of the larger alkali metal salt (e.g., potassium salt) in the first molten salt solution 1102, based on 100 wt % of the first molten salt solution, can be 20 wt % or more, 25 wt % or more, 33 wt % or more, 40 wt % or more, 50 wt % or more, 60 wt % or more, 66 wt % or more, 75 wt % or more, 80 wt % or more, 85 wt % or more, 90 wt % or more, 92 wt % or more, 95 wt % or more, 95.5 wt % or more, 96 wt % or more, 96.5 wt % or more, 97 wt % or more, 97.5 wt % or more, 98 wt % or more, 98.5 wt % or more, 99 wt % or more, 99.15 wt % or more, 99.25 wt % or more, 99.4 wt % or more, 99.5 wt % or more, 99.9 wt % or less, 99.75 wt % or less, 99.5 wt % or less, 99.25 wt % or less, 99.0 wt % or less, 98.75 wt % or less, 98.5 wt % or less, 98.25 wt % or less, 98.0 wt % or less, 97.75 wt % or less, 97.5 wt % or less, 97.25 wt % or less, 97.0 wt % or less, 96.75 wt % or less, 96.5 wt % or less, 96.25 wt % or less, 96.0 wt % or less, 95.75 wt % or less, 95.5 wt % or less, 95.25 wt % or less, 95.0 wt % or less, 94 wt % or less, 93 wt % or less, 92 wt % or less, 91 wt % or less, 90 wt % or less, 88 wt % or less, 85 wt % or less, 80 wt % or less, 75 wt % or less, 66 wt % or less, or 50 wt % or less. In further aspects, an amount of the larger alkali metal salt (e.g., potassium salt) in the first molten salt solution 1102, based on 100 wt % of the first molten salt solution, can be greater than or equal to 95 wt %, for example, from greater than or equal to 95 wt % to less than or equal to 99.9 wt %, from greater than or equal to 95.5 wt % to less than or equal to 99.75 wt %, from greater than or equal to 96 wt % to less than or equal to 99.5 wt %, from greater than or equal to 96.5 wt % to less than or equal to 96.5 wt % to less than or equal to 99.25 wt %, from greater than or equal to 97 wt % to less than or equal to 99 wt %, from greater than or equal to 97.5 wt % to less than or equal to 98.75 wt %, from greater than or equal to 97.5 wt % to less than or equal to 98.5 wt %, from greater than or equal to 98 wt % to less than or equal to 98.25 wt %, or any range or subrange therebetween. In further aspects, an amount of the larger alkali metal salt (e.g., potassium salt) in the first molten salt solution 1102, based on 100 wt % of the first molten salt solution, can be greater than or equal to 99 wt % (e.g., when the first molten salt solution is substantially free of sodium), for example, from greater than or equal to 99.0 wt % to less than or equal to 99.9 wt %, from greater than or equal to 99.15 wt % to less than or equal to 99.75 wt %, from greater than or equal to 99.25 wt % to less than or equal to 99.55 wt %, from greater than or equal to 99.4 wt % to less than or equal to 99.5 wt %, or any range or subrange therebetween. In aspects, the first molten salt solution can consist of a lithium salt, a salt of the larger alkali metal, and optionally silicic acid and optionally a sodium salt. In further aspects, an amount of sodium, if any, present in the first molten salt solution can be the balance of the concentrations of the lithium salt and the larger alkali metal salt (e.g., potassium salt) in the first molten salt solution. In further aspects, the first molten salt solution 1102 can optionally comprise silicic acid in an amount, by superaddition to the first molten salt solution, in a range from greater than 0 wt % to 1 wt %, from 0.1 wt % to 0.9 wt %, from 0.2 wt % to 0.8 wt %, from 0.3 wt % to 0.7 wt %, from 0.4 wt % to 0.6 wt %, or any range or subrange therebetween.

In aspects, step 1003 can further comprise heating the initial substrate to an initial temperature before the initial substrate is contacted with the first molten salt solution. In further aspects, the initial substrate can be heated in an environment (e.g., air, in an oven) maintained at the initial temperature for an initial period of time. In aspects, the initial temperature can be 200 °C or more, 220 °C or more, 240 °C or more, 260 °C or more, 280 °C or more, 300 °C or less, 280 °C or less, 260 °C or less, 240 °C or less, or 220 °C or less. In aspects, the initial temperature can be from greater than or equal to 200 °C to less than or equal to 300 °C, from greater than or equal to 220 °C to less than or equal to 280 °C, from greater than or equal to 240 °C to less than or equal to 260 °C, or any range or subrange therebetween. In aspects, the initial period of time can be 10 minutes or more, 15 minutes or more, 30 minutes or more, 45 minutes or more, 1 hour or more, 2 hours or more, 4 hours or more, 24 hours or less, 12 hours or less, 8 hours or less, 6 hour or less, 4 hours or less, 2 hours or less, 1 hour or less, or 45 minutes or less. In aspects, the initial period of time can be from greater than or equal to 10 minutes to less than or equal to 24 hours, from greater than or equal to 15 minutes to less than or equal to 12 hours, from greater than or equal to 30 minutes to less than or equal to 8 hours, from greater than or equal to 45 minutes to less than or equal to 6 hours, from greater than or equal to 1 hour to less than or equal to 4 hours, from greater than or equal to 1 hour to less than or equal to 2 hours, or any range or subrange therebetween. Heating the initial substrate before contacting the first molten salt solution can reduce thermal shock to the glass-based article that can increase yield of the method and/or increase a uniformity of the resulting compressive stress region from step 1003.

In further aspects, after the chemically strengthening in step 1003 to from the initially strengthened substrate, step 1003 can further comprise rinsing the initially strengthened substrate in deionized water or an alkaline detergent solution. An exemplary aspect of an alkaline detergent solution includes SemiClean KG (Yokohama Oils & Fats Industry Co.).

At the end of step 1003, as shown in FIG. 12, the initially strengthened substrate 1203 can have one or more initial compressive stress regions. In aspects, the initially strengthened substrate 1203 can have at least an initial first compressive stress region 1212 extending from the existing first major surface 1113 to an initial first depth of compression (indicated by dashed line 1213) and an initial first central compressive stress region 1222 extending from the existing first central surface area 1143 to an initial first central depth of compression (indicated by dashed line 1223). In further aspects, as shown, the initially strengthened substrate 1203 can further comprise at least an initial second compressive stress region 1214 extending from the existing second major surface 1115 to an initial second depth of compression (indicated by dashed line 1215) and an initial second central compressive stress region 1224 extending from the existing second central surface area 1145 to an initial second central depth of compression (indicated by dashed line 1225). When the dimensions are closely monitored before and after step 1003 to experimentally determine how much expansion-induced strain the central portion is subjected to. Providing from 0.1 wt % to 2.0 wt % (e.g., from 0.25 wt % to 1.0 wt %, from 0.45 wt % to 0.85 wt %) of a lithium salt in the first molten salt solution can generate an expansion-induced strain difference between the first portion and the second portion that is opposite of that normally encountered when chemically strengthening a foldable substrate having a central portion thinner than an adjacent first portion since lithium has the opposite effect of the larger alkali metal. This can be the case, as demonstrated in FIGS. 14-15, even when the first molten salt solution comprises both the lithium salt and a larger alkali metal salt (e.g., potassium salt).

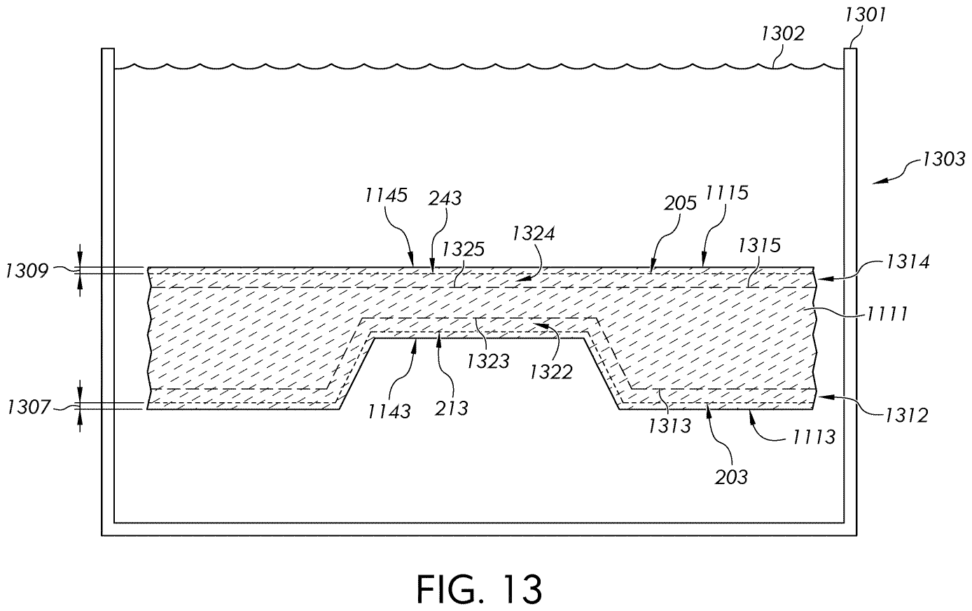

After step 1003, as shown in FIG. 12, methods can proceed to step 1005 comprising chemically strengthening the initially strengthened substrate 1203 to form the strengthened substrate 1303 (see FIG. 13). In aspects, as shown, chemically strengthening the initially strengthened substrate 1203 can comprise contacting at least a portion of initially strengthened substrate 1203 with a second molten salt solution 1202 (e.g., contained in a second molten salt bath 1201). In aspects, as shown, chemically strengthening the initially strengthened substrate 1203 in step 1005 can comprise immersing the initially strengthened substrate 1203 in the second molten salt solution 1202 contained in the second molten salt bath 1201. In aspects, as shown, in step 1005, the existing first major surface 1113 and the existing first central surface area 1143 can be in direct contact with and simultaneously ion-exchanged with the first molten salt solution 1102, for example, by immersing (e.g., completely immersing) the initially strengthened substrate 1203 in the second molten salt solution 1202 contained in the second molten salt bath 1201 (e.g., with the existing second major surface 1115 and the existing second central surface area 1145 also in direct contact with and simultaneously ion-exchanged with the second molten salt solution 1202).

In aspects, the chemical strengthening in step 1005 can occur for a second period of time while the second molten salt solution 1202 is maintained at a second temperature. In further aspects, the second temperature can be within one or more of the temperature ranges discussed above for the first temperature. In further aspects, the second period of time can be within one or more of the ranges discussed above for the first period of time. In further aspects, the second period of time can be from greater than or equal to 1 minute to less than or equal to 15 minutes, from greater than or equal to 1 minute to less than or equal to 10 minutes, from greater than or equal to 1 minute to less than or equal to 7 minutes, from greater than or equal to 2 minutes to less than or equal to 5 minutes, from greater than or equal to 3 minutes to less than or equal to 4 minutes, or any range or subrange therebetween. In aspects, after further chemically strengthening in step 1005 to from the strengthened substrate, step 1005 can further comprise rinsing the chemically strengthened substrate in deionized water or an alkaline detergent solution.

In aspects, the second molten salt solution can be substantially free of lithium and/or lithium salts. As used here, “substantially free” of an alkali metal and/or an alkali metal salt in a molten salt solution means that a concentration of the alkali metal and/or an alkali metal salt is less than 0.1 wt %, which may be as close to 0 as is practicably possible due to the introduction of such materials into the molten salt solution from the substrates being chemically strengthened therein. In particular, step 1003 adds lithium to the initial foldable substrate 1103 to form the initially strengthened substrate 1203 that is contacted with the second molten salt solution 1202 in step 1005, where it is expected that some of the lithium (added in step 1003) will be ion-exchanged out the initially strengthened substrate 1203. Consequently, the term “substantially free” covers the situation where lithium and/or lithium salts are not intentionally added to the second molten salt solution apart from the contact with the initial foldable substrate 1103, but lithium and/or lithium salt may be present when the second molten salt solution is used for multiple batches of initially strengthened substrate(s).

In aspects, the second molten salt solution 1202 in step 1005 can comprise a salt of the larger alkali metal (e.g., potassium). In further aspects, the anion of the salt of the larger alkali metal can be nitrate (e.g., potassium nitrate), although the anion can be carbonate, sulfate, chloride, etc. in other aspects—in addition to combinations of any of these salts. In further aspects, an amount of the salt of the larger alkali metal, based on 100 wt % of the second molten salt solution, can be 20 wt % or more, 22 wt % or more, 25 wt % or more, 27 wt % or more, 30 wt % or more, 33 wt % or more, 35 wt % or more, 40 wt % or more, 45 wt % or more, 50 wt % or more, 55 wt % or more, 60 wt % or more, 66 wt % or more, 70 wt % or more, 73 wt % or more, 75 wt % or more, 78 wt % or more, 100 wt % or less, 95 wt % or less, 90 wt % or less, 85 wt % or less, 80 wt % or less, 78 wt % or less, 75 wt % or less, 73 wt % or less, 70 wt % or less, 66 wt % or less, 60 wt % or less, 55 wt % or less, 50 wt % or less, 45 wt % or less, 40 wt % or less, 35 wt % or less, 33 wt % or less, 30 wt % or less, 27 wt % or less, 25 wt % or less, or 22 wt % or less. In further aspects, an amount of the salt of the larger alkali metal, based on 100 wt % of the second molten salt solution, can from be greater than or equal to 20 wt % to less than or equal to 80 wt %, from greater than or equal to 22 wt % to less than or equal to 78 wt %, from greater than or equal to 25 wt % to less than or equal to 75 wt %, from greater than or equal to 27 wt % to less than or equal to 73 wt %, from greater than or equal to 30 wt % to less than or equal to 70 wt %, from greater than or equal to 33 wt % to less than or equal to 66 wt %, from greater than or equal to 35 wt % to less than or equal to 60 wt %, from greater than or equal to 40 wt % to less than or equal to 55 wt %, from greater than or equal to 45 wt % to less than or equal to 50 wt %, or any range or subrange therebetween. In further aspects, an amount of the salt of the larger alkali metal, based on 100 wt % of the second molten salt solution, can be 50 wt % or more, for example, from greater than or equal to 50 wt % to less than or equal to 100 wt %, from greater than or equal to 55 wt % to less than or equal to 95 wt %, from greater than or equal to 60 wt % to less than or equal to 90 wt %, from greater than or equal to 66 wt % to less than or equal to 85 wt %, from greater than or equal to 70 wt % to less than or equal to 80 wt %, from greater than or equal to 75 wt % to less than or equal to 80 wt %, or any range or subrange therebetween.

In further aspects, the second molten salt solution can comprise greater than 95 wt % of the larger alkali metal salt (e.g., from greater than or equal to 95 wt % to less than or equal to 100 wt %), for example, with the amount of the larger alkali metal salt in the second molten salt solution being within one or more of the ranges discussed above for the amount of the larger alkali metal salt in the first molten salt solution. Alternatively, further aspects, the second molten salt solution can comprise greater than or equal to 5 wt % of a sodium salt. In even further aspects, an amount of the sodium salt in the second molten salt solution can be greater than or equal to 20 wt % to less than or equal to 80 wt %, from greater than or equal to 22 wt % to less than or equal to 78 wt %, from greater than or equal to 25 wt % to less than or equal to 75 wt %, from greater than or equal to 27 wt % to less than or equal to 73 wt %, from greater than or equal to 30 wt % to less than or equal to 70 wt %, from greater than or equal to 33 wt % to less than or equal to 66 wt %, from greater than or equal to 35 wt % to less than or equal to 60 wt %, from greater than or equal to 40 wt % to less than or equal to 55 wt %, from greater than or equal to 45 wt % to less than or equal to 50 wt %, or any range or subrange therebetween. Alternatively, the second molten salt solution can optionally comprise 4 wt % or less of a sodium salt (e.g., sodium nitrate), for example, from greater than or equal to 0 wt % to less than or equal to 4 wt %, from greater than or equal to 0.5 wt % to less than or equal to 3.5 wt %, from greater than or equal to 1.0 wt % to less than or equal to 3.0 wt %, from greater than or equal to 1.5 wt % to less than or equal to 2.5 wt %, from greater than or equal to 1.5 wt % to less than or equal to 2.0 wt %, or any range or subrange therebetween.

In aspects, the strengthened substrate 1303 (formed as a result of the contact with the second molten salt solution 1202 in step 1005) can have buckling in the central portion (e.g., existing first central surface area 1143, existing second central surface area 1145). Without wishing to be bound by theory, the expansion-induced strain from step 1005 can exceed the critical buckling strain for the central portion-even taking into account the oppositely signed expansion-induced strain from step 1003. As discussed herein, buckling of any kind at any point during the process was previously avoided. Without wishing to be bound by theory, it was believed that buckling could not be undone once induced due to the non-linear behavior that occurs when the critical buckling strain is exceeded. However, as demonstrated by the Examples herein, it has unexpectedly been demonstrated that a foldable substrate can be formed from a precursor (e.g., strengthened substrate) with a buckled central portion that is etched to become free of buckling. Consequently, the resulting foldable substrate herein can be closer to the critical buckling strain than previously thought possible that have a low warp and are free of buckling.

At the end of step 1005, as shown in FIG. 13, the strengthened substrate 1303 can have one or more compressive stress regions. As discussed above, step 1005 can increase compressive stress, depth of layer, and/or other properties associated with the initial compressive stress regions formed in step 1003. Consequently, as shown, the strengthened substrate 1303 can have an intermediate first compressive stress region 1312 extending from the existing first major surface 1113 to an intermediate first depth of compression (indicated by dashed line 1313) and an intermediate first central compressive stress region 1322 extending from the existing first central surface area 1143 to an intermediate first central depth of compression (indicated by dashed line 1323). In further aspects, a maximum compressive stress and/or depth of layer associated with the intermediate first compressive stress region 1312 can be greater than or equal to the corresponding property of the initial first compressive stress region 1212, and/or a maximum compressive stress and/or depth of layer associated with the intermediate first central compressive stress region 1322 can be greater than or equal to the corresponding property of the initial first central compressive stress region 1222. In further aspects, as shown, the strengthened substrate 1303 can further comprise an intermediate second compressive stress region 1314 extending from the existing second major surface 1115 to an intermediate second depth of compression (indicated by dashed line 1315) and an intermediate second central compressive stress region 1324 extending from the existing second central surface area 1145 to an intermediate second central depth of compression (indicated by dashed line 1325).

After step 1005, in aspects, methods can proceed to step 1007 comprising etching the strengthened substrate 1303 with an etchant solution 1302, as shown in FIG. 13, to form the foldable substrate 201. In aspects, as shown in FIG. 13, step 1007 can comprise immersing the strengthened substrate 1303 in the etchant solution 1302 contained in an etchant bath 1301. In aspects, as shown, the etching can remove at least: a first outer layer having a first outer thickness 1307 from the existing first major surface 1113 to form the first major surface 203; and a first central outer layer from the existing first central surface area 1143 to form the first central surface area 213. In further aspects, as shown, the etching can remove: a second outer layer having a second outer thickness 1309 from the existing second major surface 1115 to form the second major surface 205 and a second central outer layer from the existing second central surface area 1145 to form the second central surface area 243. In further aspects, the etchant can simultaneously contact the entire surface area of the strengthened substrate 1303. In further aspects, the first outer thickness can be equal to the second outer thickness. In even further aspects, step 1007 can remove a uniform outer thickness from the existing first major surface, the existing second major surface, the existing first central surface area, and the existing second central surface area. In aspects, the first outer thickness 1307 and/or the second outer thickness 1309 can be 10 nanometers (nm) or more, 50 nm or more, 100 nm or more, 250 nm or more, 500 nm or more, 600 nm or more, 700 nm or more, 800 nm or more, 900 nm or more, 1 μm or more, 1.5 μm or more, 2 μm or more, 10 μm or less, 8 μm or less, 5 μm or less, 3 μm or less, 2 μm or less, 1.5 μm or less, 1.2 μm or less, 1.0 μm or less, or 0.9 μm or less. In aspects, the first outer thickness 1307 and/or the second outer thickness 1309 can be from greater than or equal to 10 nm to less than or equal to 10 μm, from greater than or equal to 50 nm to less than or equal to 8 μm, from greater than or equal to 100 nm to less than or equal to 5 μm, from greater than or equal to 250 nm to less than or equal to 3 μm, form greater than or equal to 500 nm to less than or equal to 2 μm, from greater than or equal to 600 nm to less than or equal to 1.5 μm, from greater than or equal to 700 nm to less than or equal to 1.2 μm, from greater than or equal to 800 nm to less than or equal to 1.0 μm, from greater than or equal to 800 nm to less than or equal to 0.9 μm, or any range or subrange therebetween. In preferred aspects, the first outer thickness 1307 and/or the second outer thickness 1309 can be from greater than or equal to 10 nm to less than or equal to 10 μm, from greater than or equal to 250 nm to less than or equal to 3 μm, from greater than or equal to 500 nm to less than or equal to 2 μm, or any range or subrange therebetween.

As shown in FIG. 13, the etching in step 1007 can remove a portion of the intermediate compressive stress regions 1312, 1314, 1322, and/or 1324 by removing an outer layer of the strengthened substrate. As demonstrated by the Examples herein, the etching can remove enough of the corresponding compressive stress region(s) (including the near-surface portions potentially having the highest concentration of the larger alkali metal oxide) to reduce the expansion-induced strain experience by the central portion below the critical buckling strain, which is evidenced by the absence of buckling in the resulting foldable substrate.

After step 1007, methods can proceed to step 1009. In aspects, step 1009 can comprise assembling a display device (e.g., the consumer electronic device in FIGS. 7-8 and/or 9) comprising the foldable substrate, for example, as part of the housing and/or the cover substrate 712 in the consumer electronic device 700 shown in FIGS. 7-8 and/or a corresponding portion in the consumer electronic product 901 shown in FIG. 9. Additionally or alternatively, step 1009 can comprise further treating the foldable substrate, which can comprise rinsing the foldable substrate (e.g., in deionized water or an alkaline detergent solution), disposing a coating on the foldable substrate, and/or disposing a polymer-based material (e.g., adhesive) on the foldable substrate.

After step 1007 or 1009, in aspects, methods can proceed to step 1011, where methods of making the foldable substrate and/or the foldable apparatus can be complete. In aspects, methods of making a foldable substrate and/or a foldable apparatus in accordance with aspects of the disclosure can proceed along steps 1001, 1003, 1005, 1007, 1009, and 1011 of the flow chart in FIG. 10 sequentially, as discussed above. In aspects, methods can follow arrow 1002 from step 1007 to step 1011, for example, if methods are complete at the end of step 1007. Upon reaching step 1011, in aspects, the foldable substrate can be free of buckling (e.g., the central portion can be free of buckling), the first central surface area of the central portion can be substantially parabolic and/or substantially planar, and/or a maximum local curvature of a surface profile along a midline of the first central surface area can be less than or equal to 5 Diopters. In aspects, the foldable substrate can exhibit the midpoint lithium difference and the central surface larger alkali difference (or central surface mixed alkali difference) within one or more of the corresponding ranges discussed above, including ratios thereof. Additionally or alternatively, the foldable substrate can exhibit the central surface lithium difference and the central surface mixed alkali difference (or the central surface larger alkali difference) within one or more of the corresponding ranges discussed above, including ratios thereof.

Additionally, in aspects, foldable substrates and/or foldable articles in accordance with the present disclosure can exhibit good mechanical properties (e.g., failure strength, puncture resistance, flaw depth tolerance).

As used herein, “failure strength” of a sample is measured in accordance with the Ball-on-Ring Test as described in Section 2.4.3 (pages 56-58) of “The Mechanical Reliability of Thin, Flexible Glass” by G. Scott Glaesemann in Flexible Glass (2017, Scrivner Publishing LLC) edited by Sean M. Garner. For flexible substrates and flexible apparatus having a central portion, the ring is centered on the central portion. The ring had a diameter of 1 inch (25.4 mm) and the ball had a diameter of 0.5 inches (12.7 mm). The radial strain at failure was recorded and converted to failure stress (referred to as “failure strength” herein) using the following equation:

$$σ = \frac{E ε}{1 - v} ,$$

where σ is the “failure strength”, E is the Young's modulus of the sample (e.g., glass substrate), ¿ is radial strain at failure, and v is the Poisson's ratio of the sample (e.g., glass substrate). The strain (i.e., radial strain) measured at the apex of the tension side using a strain gage. As understood by a person having ordinary skill in the art, the side of the sample bowing outward is in tension (i.e., “tension side”), and the apex is the location with the greatest outward bowing (corresponding to a location opposite the side where the ball is applied). Failure strength was measured at 23±2 °C and a relative humidity of 40±10%. Although not used here, it is to be understood that a finite element model could also be used to evaluate the failure strength from the failure load. The reported failure strength is the median of at least five measurements.

In aspects, a failure strength of the foldable substrate and/or foldable apparatus can be 1965 MPa or more, 1975 MPa or more, 1990 MPa or more, 2000 MPa or more, 2020 MPa or more, 2050 MPa or more, 2060 MPa or more, or 2080 MPa or more. In aspects, a failure strength of the foldable substrate and/or foldable apparatus can be in a range from greater than or equal to 1965 MPa to less than or equal to 2500 MPa, from greater than or equal to 1990 MPa to less than or equal to 2300 MPa, from greater than or equal to 2050 MPa to less than or equal to 2100 MPa, or any range or subrange therebetween.

As used herein, the “Quasi-Static Puncture Test” uses a multilayer apparatus constructed using the foldable substrate to be tested. An example multilayer apparatus (e.g., foldable apparatus 301 in FIG. 3) would be modified similar to the foldable apparatus 401 show in FIG. 5. As shown in FIG. 3, a test adhesive layer 509 filling the central portion (see central portion 211 in FIG. 3 with the test adhesive layer taking the place of the polymer-based portion 299 and the adhesive layer 261 in FIG. 3) and further comprising a test adhesive thickness of 250 μm (beyond the corresponding major surface-see adhesive thickness 267 in FIG. 3) that is, in turn, contacting a polymer sheet comprising a thickness of 50 μm (e.g., where the polymer sheet is in the location shown by the PET sheet 507 in FIG. 5 and in place of the release liner shown 271 in FIG. 3). The polymer sheet for the Quasi-Static Puncture Test is low density polyethylene (LDPE) with a thickness of 50 μm (in place of the PET sheet shown in FIG. 5). The test adhesive layer comprised an acrylic adhesive having an elastic modulus of 0.8 MPa with a tensile strength of about 0.58 MPa and an elongation at failure of about 220%. As understood to a person having ordinary skill in the art “elongation at failure” of a polymer-based portion corresponds to the “ultimate elongation” defined in ASTM D412, which is the elongation at rupture of the sample. In the Quasi-Static Puncture Test, a tungsten carbide ball with a predetermined diameter is placed on the outer surface (e.g., second major surface 205) and pressed into the outer surface at a rate of 0.5 mm/min until failure. The multilayer apparatus to be tested is configured such that the polymer sheet is placed on an aluminum plate (6063 aluminum alloy, as polished to a surface roughness with 400 grit paper) with the polymer sheet contacting the aluminum plate. No tape is used on the side of the sample resting on the aluminum plate. Unless otherwise indicated, the predetermined diameter of the tungsten carbide ball is 0.5 mm. Also, the Quasi-Static Puncture Test was performed at 23±2 °C and a relative humidity of 40±10%. The reported puncture resistance is the median of at least five measurements. In aspects, the foldable substrate and/or foldable apparatus can exhibit a puncture resistance as measured in a Quasi-Static Puncture Test (e.g., using a tungsten carbide ball with a diameter of 0.5 mm) of 0.61 kgf or more, 0.64 kgf or more, 0.66 kgf or more, 0.68 kgf or more, or 0.70 kgf or more.

As used herein, a “flaw depth” is calculated based on the measurement for failure strength (described above) using the expression of −σⱼ−σ_{cs}=K_{IC}/(Y*√a), where K_{IC} is the fracture toughness of the corresponding composition (in MPa √m), Y* is a constant related to the flaw geometry, σ_{f} is the failure stress (corresponding to the failure strength mentioned above with reference to the Ball-on-Ring Test), σ_{cs} is the surface compressive stress (CS), and a is the flaw depth. Lower calculated flaw depths are associated with higher strength and higher quality of the sample. As used herein, “fracture toughness” refers to the K_{IC} value as measured by the chevron-notched short bar (CNSB) method. The CNSB method is disclosed in Reddy, K. P. R. et al., “Fracture Toughness Measurement of Glass and Ceramic Materials Using Chevron-Notched Specimens,” J. Am. Ceram. Soc., 71 [6], C-310-C-313 (1988) except that Y*m is calculated using equation 5 of Bubsey, R. T. et al., “Closed-Form Expressions for Crack-Mouth Displacement and Stress Intensity Factors for Chevron-Notched Short Bar and Short Rod Specimens Based on Experimental Compliance Measurements,” NASA Technical Memorandum 83796, pp. 1-30 (October 1992). Unless otherwise indicated, Y* was 1.35 here. In aspects, the foldable substrate and/or foldable apparatus can exhibit a flaw depth can be 0.30 μm or less, 0.28 μm or less, 0.26 μm or less, 0.25 μm or less, 0.24 μm or less, 0.23 μm or less, 0.22 μm or less, 0.21 μm or less, 0.20 μm or less, 0.19 μm or less, 0.18 μm or less, or 0.17 μm or less. In aspects, the foldable substrate and/or foldable apparatus can exhibit flaw depth in a range from greater than or equal to 0.05 μm to less than or equal to 0.3 μm, from greater than or equal to 0.1 μm to less than or equal to 0.25 μm, from greater than or equal to 0.15 μm to less than or equal to 0.20 μm, or any range or subrange therebetween.

### EXAMPLES

Various aspects will be further clarified by the following examples. Unless otherwise indicated, all samples comprise a glass-based substrate of Composition 1 having a nominal composition in mol % of: 65.1 SiO₂, 14.0 Al₂O₃, 16.4 Na₂O, 3.4 MgO, 1.0 CaO, and 0.1 SnO₂; the dimensions of the samples are 100 mm by 60 mm in a direction perpendicular to the substrate thickness. Unless otherwise specified, the examples have a substrate thickness of 100 μm with central thickness of 30 μm formed by etching a recess in the first major surface with a width of 20 mm.

Table 1 presents the conditions for chemically strengthening Example A-K and M and the Properties of and properties of the central portion of Examples A-K and M. As shown, Examples A-F were chemically strengthened in a molten salt solution having from 0.12 wt % to 0.85 wt % LiNO₃ with the balance being a larger alkali metal salt (i.e., KNO₃ here) maintained at a temperature (Temp) of 410 °C for 1 minute (min) or 2 minutes. For the examples treated for 1 minute (Examples A, C, E, H, J, and M), the depth of layer (DOL) of the larger alkali metal (i.e., potassium here) was largely unchanged (likely within confidence intervals of 4.6 μm) but the compressive stress (CS) decreased as the LiNO₃ concentration increased. The substantially unchanged DOL is expected since lithium does not directly affect the diffusion of potassium ion-exchanged into the sample (although lithium does compete with potassium to be ion-exchanged into the sample, but this is not a significant impact on DOL for this short time period). Likewise, the decrease in CS for increasing LiNO₃ concentration is also expected since (1) lithium directly competes with potassium to be ion-exchanged into the sample and (2) lithium has a smaller ionic radius than sodium while potassium has a larger ionic radius such that the effect on stress for ion-exchanging lithium is in the opposite direction of that for potassium. For the examples treated for 2 minutes (Examples B, D, F, G, I, and K), the DOL is about 5 μm for all of these examples, but the CS decreases as the LiNO₃ concentration increased. These trends for the 2 minute treatment time are consistent with that observed for the 1 minute treatment time. To the extent that there may be a statistically significant difference in DOL between the examples with less than 0.5 wt % LiNO₃ (5.1 μm) versus greater than or equal to 0.5 wt % LiNO₃ (4.9 μm), this is likely due to the higher LiNO₃ concentration decreasing the amount of potassium ion-exchanged into the sample rather than effecting diffusion within the sample itself.

TABLE 1
Conditions and Properties of Central
Portion of Examples A-K and M

| Example | LiNO₃ | Temp | Time | DOL | CS | |
|---|---|---|---|---|---|---|
| (Condition) | (wt %) | (°C) | (min) | (μm) | (MPa) | Appearance |
| A | 0.12 | 410 | 1 | 4.5 | 875 | Wavy |
| B | 0.20 | 410 | 2 | 5.1 | 815 | Wavy |
| C | 0.25 | 410 | 1 | 4.7 | 870 | Wavy |
| D | 0.30 | 410 | 2 | 5.1 | 800 | Wavy |
| E | 0.40 | 410 | 1 | 4.6 | 855 | Wavy |
| F | 0.40 | 410 | 2 | 5.1 | 815 | Wavy |
| G (L1) | 0.50 | 410 | 2 | 4.8 | 760 | OK |
| H | 0.55 | 410 | 1 | 4.6 | 795 | OK |
| I | 0.60 | 410 | 2 | 4.9 | 750 | OK |
| J | 0.70 | 410 | 1 | 4.5 | 790 | OK |
| K | 0.70 | 410 | 2 | 4.9 | 735 | OK |
| M | 0.85 | 410 | 1 | 4.3 | 770 | OK |

Also, the appearance of the central portion in Examples A-K and M is noted in Table 1. Examples A-F with less than 0.45 wt % LiNO₃ had a wavy appearance, which could correspond to buckling. In contrast, Examples G-K and M with greater than 0.45 wt % LiNO₃ (e.g., greater than or equal to 0.5 wt % LiNO₃) did not have a distorted appearance (OK). As discussed below with reference to FIG. 14, it is believed that with less than 0.4 wt % LiNO₃, the expansion-induced strain on the central portion (due to the ion-exchange) is greater than a critical buckling strain for this thinner central portion (relative to the thicker first portion and second portion). Without wishing to be bound by theory, the potassium ion-exchanged into the sample generates compressive stress and expands the glass network; this effect leads to a larger net expansion for thicker portions than thinner portions (although the relative amount-strain-would be the same); and this difference in net expansion imposes an expansion-induced strain on the central portion. At the same time, lithium has an effect with opposite sign on the compressive stress and the glass network. Based on the results in Table 1 with less than 0.45 wt % LiNO₃, the expansion-induced strain is predominated by the expansion from potassium even when considering the oppositely signed effect on expansion from lithium. In contrast, based on the results in Table 1 with greater than 0.45 wt % LiNO₃, the expansion from potassium is balanced or outweighed by the oppositely signed effect on expansion from lithium, which is why these examples do not have a wavy appearance. This is consistent for both the 1 minute and 2 minute treatment times.

Table 2 presents the conditions for Conditions L1-L5. As shown, Conditions L1-L5 have a sample in contact with a molten salt solution (having from 0.50 wt % to 1.10 wt % LiNO₃ with the balance being KNO₃) maintained at 410 °C for 2 minutes. Based on the results discussed above with reference to Table 1, it is expected that samples treated by Conditions L1-L5 would not have a wavy appearance (since these conditions have greater than 0.45 wt % LiNO₃). This is further explained with reference to the modeling results presented in FIG. 14.

TABLE 2
Conditions L1-L5 (balance KNO₃)

| | LiNO₃ | Temp | Time |
|---|---|---|---|
| Condition | (wt %) | (°C) | (min) |
| L1 | 0.50 | 410 | 2 |
| L2 | 0.65 | 410 | 2 |
| L3 | 0.85 | 410 | 2 |
| L4 | 0.95 | 410 | 2 |
| L5 | 1.10 | 410 | 2 |

FIG. 14 schematically illustrates strain difference (Δε) in parts-per-million (ppm) on the vertical axis 1403 (i.e., y-axis) as a function of lithium nitrate (LiNO₃) concentration in weight percent (wt %) of the first molten salt solution on the horizontal axis 1401 (i.e., x-axis). The strain difference (between the first portion and the central portion based on the ion-exchange) was modeled for the sample dimensions (100 μm substrate thickness and 30 μm central thickness) with the conditions of Conditions L1-L5 and some of the conditions described in Table 1. In FIG. 14, dashed line 1411 corresponds to the critical buckling strain beyond which (i.e., above) the central portion is expected to buckle. Based on the results discussed above in Table 1, it is believed that using a molten salt solution with less than 0.45 wt % LiNO₃ produces a strain difference above the critical buckling strain (i.e., buckled region 1423 above dashed line 1411) while point 1415 (corresponding to Condition L1) with 0.5 wt % LiNO₃ (i.e., greater than 0.45 wt % LiNO₃) has an expansion strain less than the critical buckling strain (i.e., point 1415 is in a non-buckled region 1421 below dashed line 1411), where the central portion is free of waviness or other indications of buckling. Without wishing to be bound by theory, glass performs better in compression than in tension, which explains why the critical buckling strain—the dashed line 1411—for positive expansion strain (corresponding to putting the central portion in tension) is much closer to 0 expansion strain than corresponding thresholds for the oppositely signed expansion strain (e.g., dashed line 1413, discussed below). Also, as discussed above, the thinner central portion is more susceptible to buckling than the thicker first and second portions.

Although not encountered for the samples in Table 1, dashed line 1413 corresponds to a threshold where noticeable warpage is observed for the central portion (i.e., a warpage region 1425 is below dashed line 1413). Based on the experimental samples (not shown) for L3-L5, warpage was not seen for 0.85 wt % LiNO₃ (Condition L3) but was seen for greater than 0.85 wt % (Conditions L4 and L5). Consequently, dashed line 1413 is aligned with point 1409 (Condition L4) with the understanding that the dashed line may be slightly higher than point 1409. Line 1407 shows the trend between the modeled condition (points 1405 in FIG. 14), where there appears to be a linear relationship between lithium concentration and expansion strain—at least in the non-buckled region 1421 (e.g., between points 1415 and 1409).

FIG. 16 illustrates compressive stress (CS) in MegaPascals (MPa) on the vertical axis 1603 (i.e., y-axis) in the first portion (points 1607) and the central portion (points 1605), respectively, for examples treated with Conditions L1-L5. As shown, the compressive stress for both the first portion and the central portion decreases going from Condition L1 to Condition L5, which is consistent with the trend seen in Table 1 due to the increase in lithium concentration in the molten salt solution. Also, the compressive stress for the first portion (points 1607) and the central portion (points 1605) are generally closely grouped (e.g., all points within 100 MPa or even about 50 MPa for each condition shown). This similarity (i.e., small difference) between the compressive stress of the first portion and the central portion is consistent with and reflects that the entire sample was chemically strengthened simultaneously without the use of any masks or other barriers.

FIG. 17 illustrates depth of layer (DOL) of potassium in micrometers (μm) on the vertical axis 1703 (i.e., y-axis) in the first portion (points 1707) and the central portion (points 1705), respectively, for examples treated with conditions L1-L5. Consistent with the trend see in Table 1, the depth of layer is largely the same across the Conditions L1-L5 since the time and temperature are the same for these conditions. It is likely that the higher DOL seen for the point for Condition L5 (and the point for Condition L4 omitted as an outlier) are spurious.

Table 3 presents the conditions for Conditions S1-S4. As shown, Conditions S1-S4 have a sample in contact with a molten salt solution (free—or at least substantially free of −LiNO₃; 100 wt % KNO₃) maintained at either 380 °C or 410 °C for either 1 minute or 2 minutes. As used in this section, samples using one Conditions S1-S4 were treated as follows: one of conditions L1-L5 followed by Conditions S1-S4. For compactness, the resulting samples (and/or examples) will be referred to by the series of conditions. For example, treating a sample with Condition S1 followed by Condition L1 will be referred to as Example S1-L1. In certain examples, described below, the resulting sample is further treated with an HF-containing etchant solution to remove an outer layer thickness of 0.75 μm from all surfaces of the sample (i.e., a thickness reduction of 1.5 μm to the substrate thickness and the central thickness).

TABLE 3
Conditions S1-S4 (100 wt % KNO₃)

| | LiNO₃ | Temp | Time |
|---|---|---|---|
| Condition | (wt %) | (°C) | (min) |
| S1 | 0 | 380 | 1 |
| S2 | 0 | 380 | 2 |
| S3 | 0 | 410 | 1 |
| S4 | 0 | 410 | 2 |

FIG. 15 schematically illustrates the effect on strain difference (Δε) in parts-per-million (ppm) on the vertical axis 1503 (i.e., y-axis) based on substrates treated with (a) a first molten salt solution having a lithium nitrate (LiNO₃) concentration in weight percent (wt %) indicated on the horizontal axis 1501 (i.e., x-axis) as shown in FIG. 14 and (b) a subsequent chemical strengthening treatment with a second molten salt solution (Conditions S1-S4). The effect of Conditions S1-S4 were modeled for the sample dimensions (100 μm substrate thickness and 30 μm central thickness), as above, following the treatments modeled and shown in FIG. 14. Segments 1511 correspond to applying Condition S1, segments 1513 correspond to applying Condition S2, segments 1515 correspond to applying Condition S3, and segments 1517 correspond to applying Condition S1 to the already treated conditions (points 1405 from FIG. 14). The resulting modeled strain increases for all of segments 1505 (segments 1511, 1513, 1515, and 1517) as a result of Conditions S1-S4, respectively, where the resulting modeled strain is at the end of the corresponding segment-opposite points 1405. As explained herein, a lithium free (or substantially lithium free) molten salt solution imposes an expansion-induced strain (i.e., positive strain difference) on the central portion from the ion-exchange of the larger alkali metal (i.e., potassium here). Further, as shown, the only points for the resulting expansion strain that are not beyond the critical buckling strain (dashed line 1411—in non-buckled region 1421) are for Condition S1 on the segments (e.g., segments extending from point 1409) with 0.95 wt % or 1.1 wt % LiNO₃ in the earlier ion-exchange treatment. Otherwise, all of the points following Conditions S1-S2 are above the critical buckling strain (dashed line 1411—in non-buckled region 1421) and therefore are expected to have a buckled central portion. This was confirmed by the appearance of experimental samples combining Conditions L1-L5 with Conditions S1-S4 (with only Examples L4-S1 and L5-S1 having a non-buckled central portion).

As discussed herein, the buckled examples represented by segments 1505 (i.e., segments 1511, 1513, 1515, and/or 1517 above dashed line 1411) would have been considered unacceptable prior to the realization described in the present disclosure. However, as demonstrated herein (e.g., see FIGS. 25, 30, and 32 discussed below for Example L3-S4), it has unexpectedly been demonstrated that a foldable substrate can be formed from a precursor (e.g., strengthened substrate) with a buckled central portion that is etched to become free of buckling. That being said, it is believed that there is a certain point (e.g., expansion strain) beyond which a non-buckled final product cannot be obtained (e.g., such as would be obtained without the initial treatment-corresponding to Conditions L1-L5), although this is much higher than the critical buckling strain that was previously thought to be such a limit. For the examples discussed herein, the buckled samples were etched (i.e., with an HF-containing etchant solution to remove an outer layer thickness of 0.75 μm from all surfaces of the sample) to produce a non-buckled resulting foldable substrate.

The schematic stress profiles shown in FIG. 20 will be used to explain how increased compressive stress in the resulting foldable substrate can be obtained in accordance with methods of the present disclosure. FIG. 20 schematically illustrates stress profiles of the central portion before an etching treatment, where compressive stress (CS) in MegaPascals (MPa) is illustrated on the vertical axis 2003 (i.e., y-axis) as a function of depth (d) from the first central surface area on the horizontal axis 2001 (i.e., x-axis). Dashed line 2009 represents a depth to which the sample could be etched to, where the corresponding portion of the stress profile to the left of the dashed line 2009 would be removed. Curve 2007 corresponds to the stress profile generated from a pure potassium salt molten salt solution (i.e., no lithium and no earlier chemical strengthening treatment with a lithium-containing molten salt solution). Curve 2007 has the highest surface compressive stress (of the curves shown in FIG. 20), but at dashed line 2009, curve 2007 a low compressive stress (compared to the other curves shown in FIG. 20) since the near-surface spike producing the high surface compressive stress (or at least a portion thereof) is removed by the etching. Curve 2015 corresponds to the stress profile generated using a lithium-containing molten salt solution (e.g., in accordance with aspects of the present disclosure). As shown, the maximum compressive stress of curve 2015 is much lower than that for curve 2007 due to the lithium ion-exchanged into the sample for curve 2015; however, the stress profiles (curves 2007 and 2015) are essentially the same starting at dashed line 2009 (e.g., due to the lithium concentration have low to no slope at these depths). Consequently, the stress profile after etching to dashed line 2009 would be the same for curves 2007 and 2015. The difference is that the lithium added for the sample corresponding to curve 2015 means that there is less expansion-induced strain for the central portion corresponding to curve 2015 than curve 2007. The realization to be seen here is that surface compressive stress of the intermediate (e.g., following chemical strengthening) is as important as the compressive stress at the depth that the sample will be etched to since the etching will remove the maximum compressive stress seen at the surface of the intermediate. Consequently, methods of the present disclosure can produce articles with high (or higher) compressive stress in the resulting article by adjusting the compressive stress at a predetermined depth rather than focusing on the compressive stress at the surface of the intermediate.

Curve 2005 corresponds to another stress profile that can be achieved using multiple ion-exchange steps, where the last ion-exchange step used a pure potassium molten salt solution. The maximum compressive stress (at depth=0) for curve 2005 is lower than that for curve 2007, but the stress at the dashed line 2009 is higher than that curve 2007. Applying the relationship noted between curves 2007 and 2015, it is to be understood that the same (elevated) compressive stress at the dashed line 2009 can be achieved as curve 2005 with an article having a lower surface compressive stress (e.g., due to lithium being present in the molten salt solution of an earlier ion-exchange process). Further, curve 2017 corresponds to a stress profile produced using multiple ion-exchange steps (like curve 2005) but where the last ion-exchange step had a mixed molten salt solution (e.g., having significant amounts of both potassium and sodium). The mixed molten salt solution in the last ion-exchange step allows the potassium to diffuse deeper into the molten salt solution before generating the sort of surface compressive stress seen in curve 2005. Consequently, the stress profile at the dashed line 2009 (and generally deeper than the spike see for curves 2005 or 2007) for curve 2017 is greater than that seen for curves 2005 and 2007. Applying the above realizations to this situation, it is now believed that an even higher stress at a predetermined depth from the surface of the intermediate (e.g., dashed line 2009 corresponding to a depth to which the intermediate is to be etched) can be obtained using a combination of a lithium-containing molten salt solution (also containing a larger alkali metal salt—e.g., potassium—associated with curve 2015) for an earlier ion-exchange step and a mixed molten salt solution (i.e., containing a sodium salt and a larger alkali metal salt-associated with curve 2017) for the later ion-exchange step.

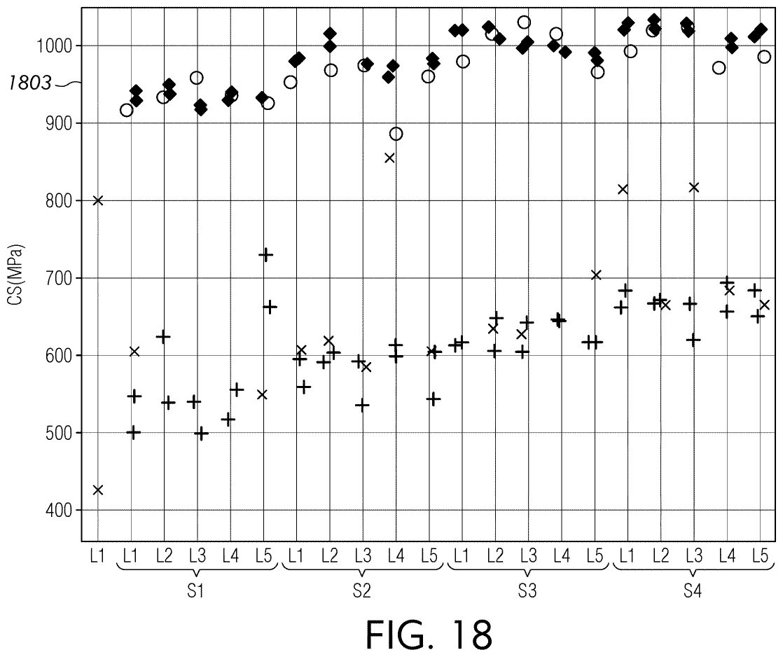

Now, the compressive stress and depth of layer experimentally measured for the Examples combining Conditions L1-L5 with Conditions S1-S4 (e.g., Examples L1-S1 through L5-S4) before and after the subsequent etching will be discussed with reference to FIGS. 17-19 (where the compressive stress following Conditions L1-L5 was discussed above with reference to FIG. 16). FIG. 18 illustrates compressive stress (CS) in MegaPascals (MPa) on the vertical axis 1803 (i.e., y-axis) in the first portion (open circles) and the central portion (solid diamonds), respectively, for examples treated with one of conditions L1-L5 followed by one of conditions S1-S4 before and after a subsequent etching treatment (as compared against treatment with L1 alone with and without a subsequent etching treatment), as indicated. As shown, all of the examples shown in FIG. 18 following the second ion-exchange step (e.g., Conditions S1-S4) but before the etching had compressive stresses greater than or equal to 900 MPa for both the first portion and the second portion. Again, as observed for FIG. 16, the difference between the compressive stress in the first portion and the central portion is low (e.g., less than or equal to 100 MPa and even less than or equal to 50 MPa). Additionally, the compressive stress for Condition L1 only (alone—before etching) is 800 MPa, which demonstrates that the compressive stress of the intermediate articles for the two ion-exchange conditions (L1-L5+S1-S4) is higher than that obtained from a single ion-exchange treatment. Again, these improvements would not have been considered previously because most of the two ion-exchange conditions produced samples that are buckled before etching (see the discussion above with reference to FIG. 15).

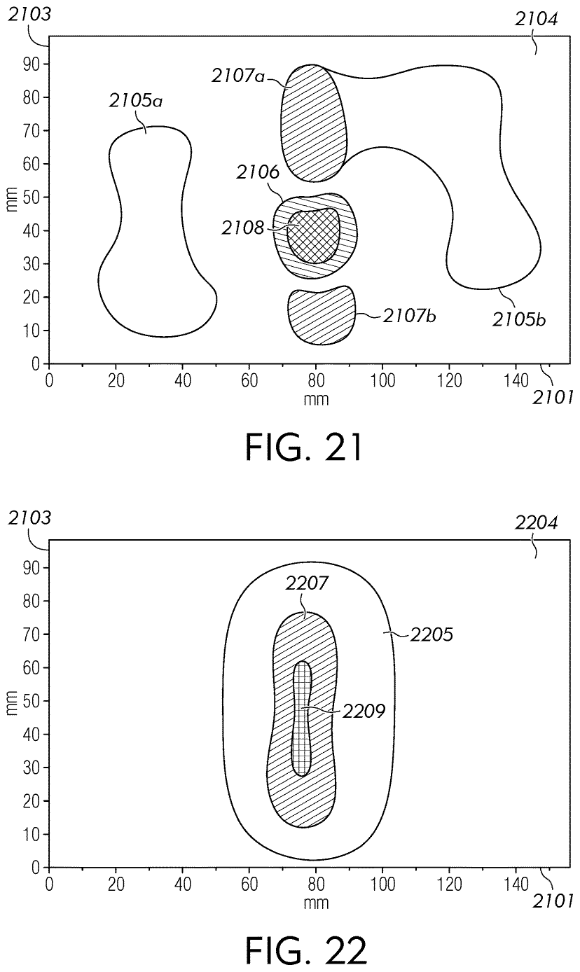

As shown in FIG. 18, after the etching, the compressive stress of the first portion (“+”) and the central portion (“x”) are still greater than or equal to 500 MPa. Further, Examples S2-L4, L1-S3 through L5-S3, and L1-S4 through L5-S4 have compressive stresses grater than or equal to 600 MPa; and Examples L1-S4 through L5-S4 have compressive stresses greater than or equal to 650 MPa. Additionally, the difference between compressive stress of the first portion (“+”) and the centra portion (“x”) is still small (i.e., less than about 100 MPa for most conditions), which indicates that a comparable amount of compressive stress was removed by the etching (since the compressive stress before the etching was also comparable). For comparison, the sample treated with Condition L1 alone and then etched has a compressive stress of about 430 MPa. Consequently, the compressive stresses for the double ion-exchange conditions (L1-L5+S1-S4) followed by etching (shown here) achieve increased compressive stresses (compared to Condition L1 alone followed by etching). Additionally, as discussed below with reference to the deviations, curvatures, and surface profiles shown in FIGS. 21-32 (especially FIGS. 25, 30, and 31) samples treated in accordance with aspects of the present disclosure are able to go from a strengthened (intermediate) article with a buckled central portion to a resulting (final) article (i.e., foldable substrate) that is free of buckling in the central portion.

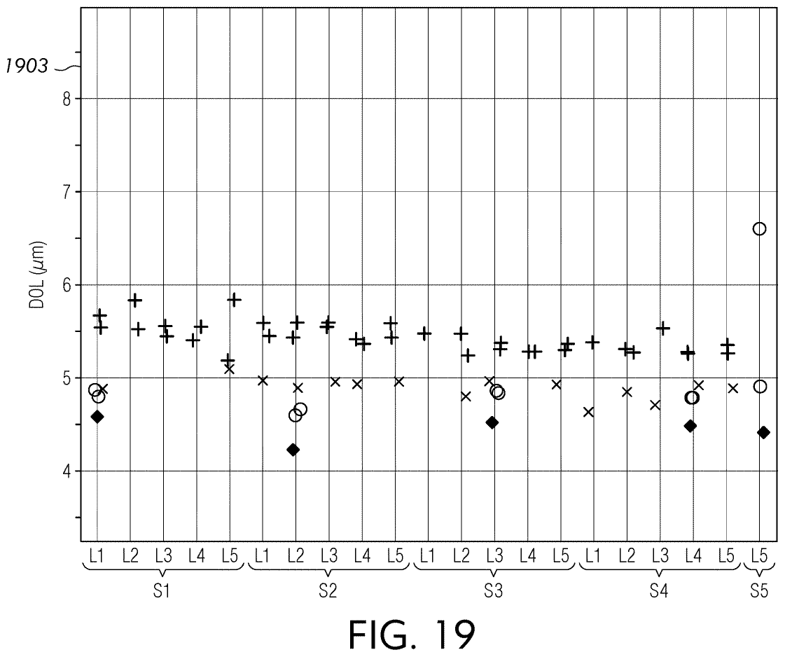

FIG. 19 illustrates depth of layer (DOL) of potassium in micrometers (μm) on the vertical axis 1903 (i.e., y-axis) in the first portion (“+”) and the central portion (“x”), respectively, for examples treated with one of conditions L1-L5 followed by one of conditions S1-S4 after a subsequent etching treatment. This can be viewed in combination with the DOL following Conditions L1-L5 discussed above with reference to FIG. 17, which are shown in open circles (first portion) and solid diamonds (central portion) spread across the horizontal axis for readability. Also, to simply FIG. 19, the DOL after the two ion-exchange treatments but before the etching has been omitted since this is directly related to the data shown for the DOL after the etching based on the thickness of the outer layer removed by the etching. As shown, the DOL for the first portion and the central portion are within about 1 μm (e.g., 0.5 μm) of each other (e.g., also corresponding to a ratio of the DOL of the central portion DOL(C) to the DOL of the first portion DOL(1): DOL(C)/DOL(1) from 0.7 to 1.5 or even from about 0.9 to about 1.1), which is consistent with and reflects that the entire sample was chemically strengthened simultaneously without the use of any masks or other barriers. Generally, the DOL for the first portion is slightly larger than the DOL for the central portion here. Also, the DOLs following the etching are still greater than the DOLs following the first ion-exchange treatment. This indicates that the DOL increased (in the second ion-exchange treatment) by a depth greater than the thickness of the outer layer removed by the etching.

Now, deviations from reference planes for the first major surface and the first central surface area will be discussed with reference to contour plots shown in FIGS. 21-25, which can be evaluated for signs of warpage, buckling, or other mechanical instabilities that may be present in the resulting sample after etching. The surface deviations (as well as curvatures and surface profiles) were determined as described above. As a representative example, these figures focus on the second ion-exchange condition of Condition S4 to evaluate the effect of the earlier ion-exchange treatment with Conditions L1-L5 on the resulting article with the understanding that the result for Conditions S1-S3 can be expected to have less expansion-induced strain differences (using the sign convention of FIGS. 14-15) based on the differences shown in FIG. 15 between segments 1511, 1513, and 1515 compared to segment 1517 for the corresponding first ion-exchange condition. In FIGS. 21-25, horizontal axis 2101 (i.e., x-axis) corresponds to distance in millimeters (mm) along the length of the sample with the central portion positioned between 70 mm and 90 mm on this axis; and the vertical axis 2103 (i.e., y-axis) corresponds to distance in mm along the width of the sample.

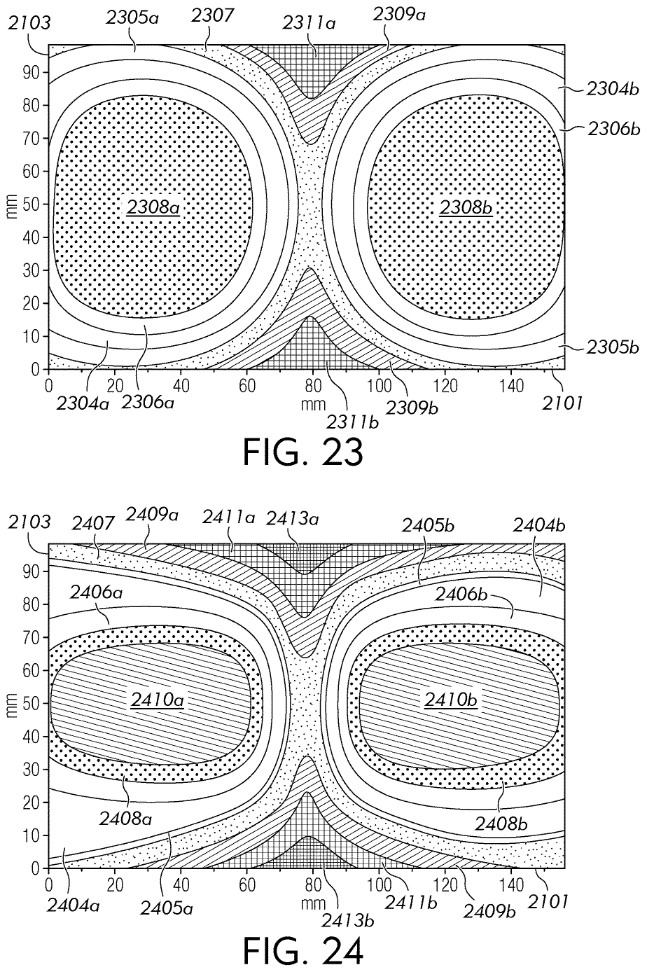

FIG. 21 represents deviations for Example L1-S4 (i.e., a glass-based substrate sequentially treated with condition L1, condition S4, and an etching treatment). FIG. 22 represents deviations for Example L2-S4 (i.e., a glass-based substrate sequentially treated with condition L2, condition S4, and an etching treatment). FIG. 25 represents deviations for Example L3-S4 (i.e., a glass-based substrate sequentially treated with condition L3, condition S4, and an etching treatment). FIG. 23 represents deviations for Example L4-S4 (i.e., a glass-based substrate sequentially treated with condition L4, condition S4, and an etching treatment). FIG. 24 represents deviations for Example L5-S4 (i.e., a glass-based substrate sequentially treated with condition L5, condition S4, and an etching treatment). In FIGS. 21-25, region 2104, 2204, 2304a-2304b, 2404a-2404b, and 2504 correspond to substantially no deviation (e.g., less than about 0.1 mm). From that, each contour further from those regions represents greater (in magnitude-absolute value) deviations. Positive deviations are indicated by odd reference numbers (e.g., regions 2105a-2105b and 2107a-2170b) while negative deviations are indicated by even reference numbers (e.g., regions 2106 and 2108) with higher reference numbers (in a given contour plot) corresponding to higher magnitude deviations.

In FIG. 21 (Example L1-S4), moderate warp is seen in the central portion with regions 2106 and 2108 having negative deviations and regions 2107a-2107b having slight positive deviations. The warp here is still less than 1 mm. In the first portion and second portion, slight deviations are seen in regions 2105a-2105b. Overall, Example L1-S4 has moderate warp (less than 1 mm) but is free of buckling or other mechanical instabilities in the central portion. From FIG. 15, it can be seen that Example L1-S4 is expected to be closest to the critical buckling strain of Examples L1-S4 through L5-S4 shown in FIGS. 21-25; however, even Example L1-S4 appears to be free of buckling based on FIG. 21 even though the intermediate (after Condition S4 but before the etching) was buckled.

In FIG. 22 (Example L2-S4), slight warp is seen in the central portion with regions 2205, 2207, and 2209 having positive deviations that are all less than 0.3 mm. The warp here is less than 0.5 mm (and about 0.3 mm or less). In the first portion and second portion, no noticeable deviations are seen. Overall, Example L1-S4 has slight warp (less than 1 mm, less than 0.5 mm, and even less than about 0.3 mm) and is free of buckling or other mechanical instabilities in the central portion.

In FIG. 23 (Example L4-S4), significant warp is seen in the central portion (and throughout the sample) with regions 2307, 2309a-2309b, and 2311a-2311b having positive deviations. The first portion and the second portion are warped in the opposite direction with region 2305a-2305b having slight positive deviations while regions 2306a-2306b, and 2308a-2308b have negative deviations. Overall, Example L4-S4 has significant warp throughout. With reference to FIGS. 14-15, it would appear that the etching brought the strain difference below dashed line 1413 from the non-buckled region 1421 to the warpage region 1425. This is further supported by the warp seen in FIG. 24 (discussed next).

In FIG. 24 (Example L5-S4), significant warp is seen in the central portion (and throughout the sample) with regions 2407, 2409a-2409b, 2411a-2411b, and 2413a-2413b having positive deviations. The first portion and the second portion are warped in the opposite direction with may of the regions discussed above with positive deviations as well region 2405a-2405b having slight positive deviations and regions 2406a-2406b, 2408a-2408b, and 2410a-2410b have negative deviations. Overall, Example L4-S4 has significant warp throughout.

In FIG. 25 (Example L3-S4), there is little to no deviations visible. Only slight positive deviations in regions 2505a-2505b are seen in the first portion and the second portion. The warp of the central portion is less than 1 mm, less than 0.5 mm, and even less than about 0.1 mm. Overall, Example L3-S4 exhibits no mechanical instabilities (i.e., is free of buckling) and little if any warp.

Based on FIGS. 21-25, it appears that Examples L1-S4 through L5-S4 are all free of buckling, but Examples L4-S4 and L5-S4 have significant warp. Examples L1-S4, L2-S4, and L3-S4 have moderate warp or less corresponding to a warp less than or equal to 1 mm with Example L3-S4 having few deviations visible at all.

Now, local curvatures in the first major surface and the first central surface area will be discussed with reference to contour plots shown in FIGS. 26-30, which can more readily be evaluated for signs of buckling or other mechanical instabilities that may be present in the resulting sample after etching. The Examples shown in FIGS. 26-30 correspond to those of FIGS. 21-25, respectively. In FIGS. 26-30, horizontal axis 2601 (i.e., x-axis) corresponds to distance in millimeters (mm) along the length of the sample with the central portion positioned between 70 mm and 90 mm on this axis; and the vertical axis 2603 (i.e., y-axis) corresponds to distance in mm along the width of the sample. Also, solid lines are shown for the boundary between the first portion or second portion and the central portion since the curvature at this location is not an indication of any mechanical instability but rather the shape of the transition between the first portion or the second portion and the central portion. In FIGS. 26-30, regions 2604a-2604b, 2704a-2704b, 2804a-2804b, 2904a-2904b, and 3004a-3004b correspond to substantially no curvature (e.g., less than 0.5 D). From that, each contour further from those regions represents greater (in magnitude-absolute value) deviations. Generally, positive curvatures are indicated by odd reference numbers (e.g., regions 2605a-2605b, 2607, 2609a-2609b, and 2611a-2611c) while negative curvatures are indicated by even reference numbers (e.g., regions 2606a-2606b, 2608a-2608c, and 2610a-2610c) with higher reference numbers (in a given contour plot) corresponding to higher magnitude deviations. As discussed above with reference to the maximum curvature, the maximum of the different local curvatures at each location were taken for these contour plots.

In FIG. 26 (Example L1-S4), significant local curvature is seen in the central portion with regions of significant positive and negative curvature. Indeed, the regions 2610a-2610c with the strongest negative curvature form an x-shaped pattern centered on region 2608c. The regions 2611a-2611c with the strongest positive curvature form an oval shaped patterned centered on this same location (region 2608c). Additionally, regions 2606a-2606b with negative curvature and regions 2605a-2605b extend into the first portion and the second portion is a starburst pattern. The maximum local curvatures seen in the central portion have absolute values of about 5 or more. While not easily discernable in FIG. 21, based on FIG. 26, it appears that the strain difference on the central portion in Example L1-S4 may be close to the critical buckling strain.

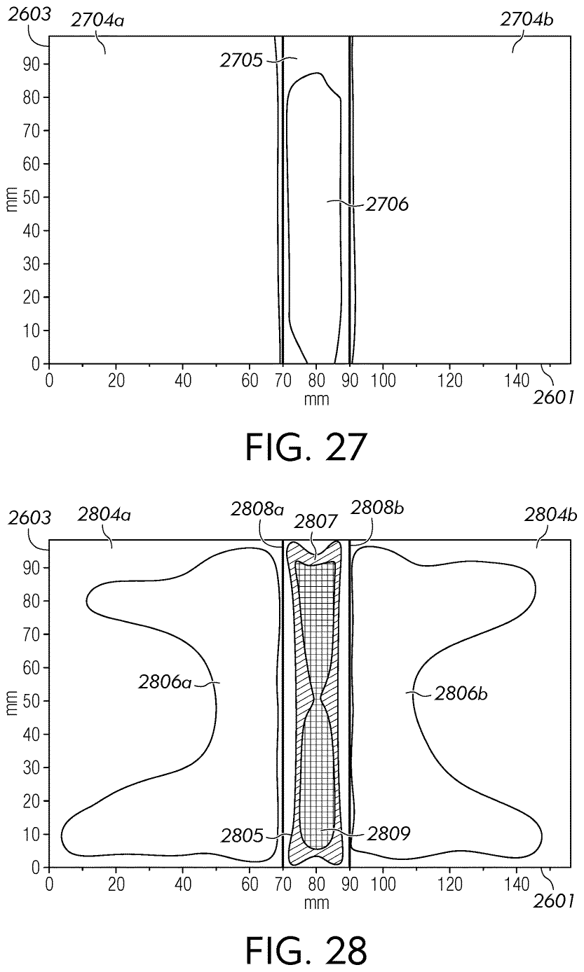

In FIG. 27 (Example L2-S4), moderate local curvature is seen in the central portion. Region 2706 having slight positive curvature is surrounded by region 2705 having slight negative curvature. The first portion and second portion do not have noticeable curvature as indicated by regions 2704a-2704b. The maximum local curvatures seen in the central portion have absolute values of about 1 or less. These moderate curvatures in the arrangement seen in FIG. 27 confirms that Example L2-S4 is free of buckling or other mechanical instabilities.

In FIG. 28 (Example L4-S4), positive curvature is localized in the central portion. Concentric regions (regions 2805, 2807, and 2809) having positive curvature are seen in the central portion. The first portion and second portion have regions 2806a-2806b of slight negative curvature adjacent the central portion. Also, the rest of the central portion has a region 2808a-2808b of more negative curvature. The maximum local curvatures seen in the central portion have absolute values less than or equal to 3. These curvatures in the arrangement seen in FIG. 28 confirms that Example L4-S4 is free of buckling or other mechanical instabilities.

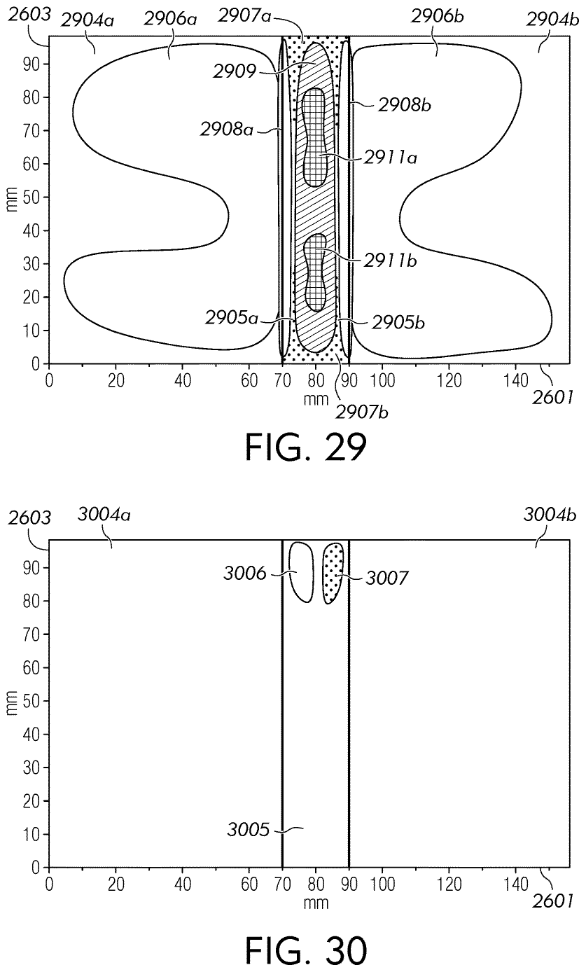

In FIG. 29 (Example L5-S4), positive curvature is localized in the central portion with significant negative curvature (in region 2908a-2908b) near the boundary between the first portion or the second portion and the central portion. Regions 2905a-2905b, 2907a-2907b, 2909, and 2911a-b have positive curvature and are located in the central portion. The first portion and second portion have regions 2906a-2906b of slight negative curvature adjacent the central portion (beyond regions 2908a-2908b). The maximum local curvatures seen in the central portion have absolute values less than or equal to 3. These curvatures in the arrangement seen in FIG. 29 (Example L5-S4) are not indicative of buckling or other mechanical instabilities.

In FIG. 30 (Example L3-S4), some local curvature is seen at one end of the central portion. The majority of the central portion is in region 3005 corresponding to slightly negative local curvature. Region 3006 has negative curvature and region 3007 has positive curvature. The first portion and second portion do not have noticeable curvature as indicated by regions 3004a-3004b. The maximum local curvatures seen in the central portion have absolute values less than or equal to about 2. The local curvatures seen in FIG. 30 confirms that Example L3-S4 is free of buckling or other mechanical instabilities.

Overall, FIGS. 26-30 largely confirm the observation from FIGS. 21-30. At one end, the strain difference on the central portion in Example L1-S4 may be near the critical buckling limit. At the other end, Examples L4-S4 and L5-S4 have warp but are free of buckling or other mechanical instabilities. In between, Examples L2-S4 and L3-S4 are free of significant warp and free of buckling or other mechanical instabilities.

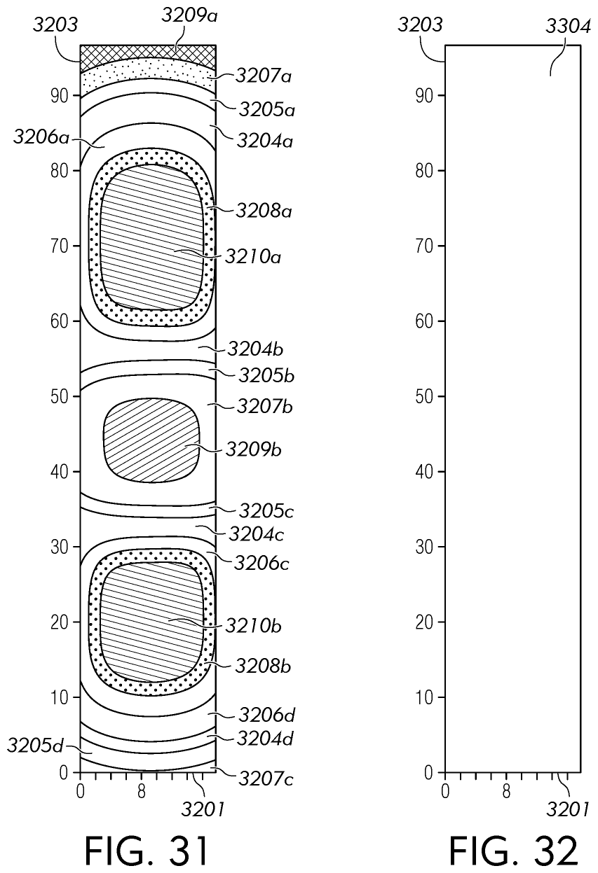

FIGS. 31-32 illustrate contour maps of a surface profile of the first central surface area of the central portion of Example L2-S4 before etching and after etching, respectively. The surface profiles were measured using the SpecGAGE3D (available from Irsa Vision) deflectometer, as described above. In FIGS. 31-32, the horizontal axis 3201 (i.e., x-axis) corresponds to distance in mm along the central portion (excluding where the central portion meets the first portion and second portion), and the vertical axis 3203 (i.e., y-axis). Regions 3204a-3204d and 3304 correspond to substantially no deviations. As with FIGS. 21-25, in FIGS. 31-32, positive deviations in the surface profile are indicated with odd reference numbers (e.g., regions 3205a-3205d, 3207a-3207c, 3209a-3209b) and negative deviations in the surface profile are indicated with even reference numbers (e.g., regions 3206a-3206d, 3208b-3208b, 3210a-3210b).

In FIG. 31, the surface profile is noticeably non-parabolic. For example, there are regions of negative curvature (e.g., regions 3210a and 3210b) with a region of positive curvature (e.g., region 3209b) therebetween and additional regions of positive curvature (regions 3207a or 3209a and region 3207c) outside thereof. Consequently, the surface profile is discernably non-parabolic. Therefore, Example L2-S4 before the etching (as shown in FIG. 31) has a buckled central portion. In contrast, as shown in FIG. 32, the surface profile has no noticeable deviations, as indicated by region 3304. Consequently, the surface profile of Example L2-S4 after the etching (as shown in FIG. 32) is both substantially parabolic and substantially planar. Additionally, the central portion (e.g., surface profile) of Example L2-S4 after the etching has no discernable warp and is free of buckling or other mechanical instabilities. This demonstrates that a non-buckled and low warp central portion (e.g., surface profile) can be formed from an intermediate having a buckled central portion.

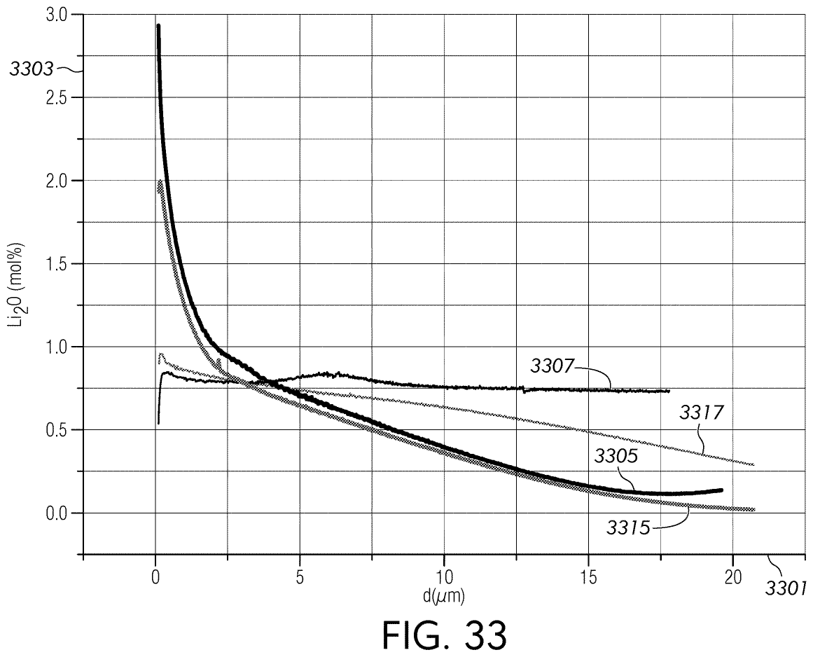

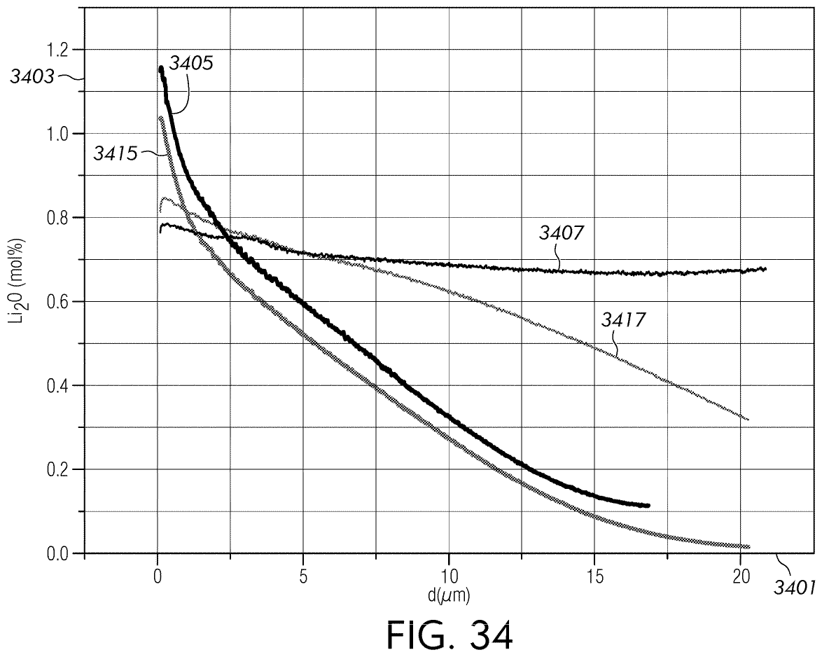

FIGS. 33-38 present concentration profiles of alkali metal oxides (e.g., Li₂O, Na₂O, K₂O) measured using GDOES. These concentration profiles provide insights on the slope of the concentration profile (similar to what could be obtained by dynamic SIMS) in addition to the surface concentration. As discussed above, the surface concentration (of the first major surface in the first portion and the first central surface area in the central portion) can also be obtained by SIMS. Here, the concentration of the alkali metal oxides at the midpoint of the first portion and the central portion were inferred based on the trend at the deeper depths measured compared with the bulk composition. Generally, the concentration of alkali metal oxides at the first midpoint (of the first portion) was the same as the bulk composition since the alkali metal oxides introduced by the ion-exchange conditions did not have sufficient time (at elevated temperatures) to diffuse that deep into the first portion. In contrast, as shown in FIGS. 33-34, lithium appears to be elevated throughout the entirety of the central thickness of the central portion.

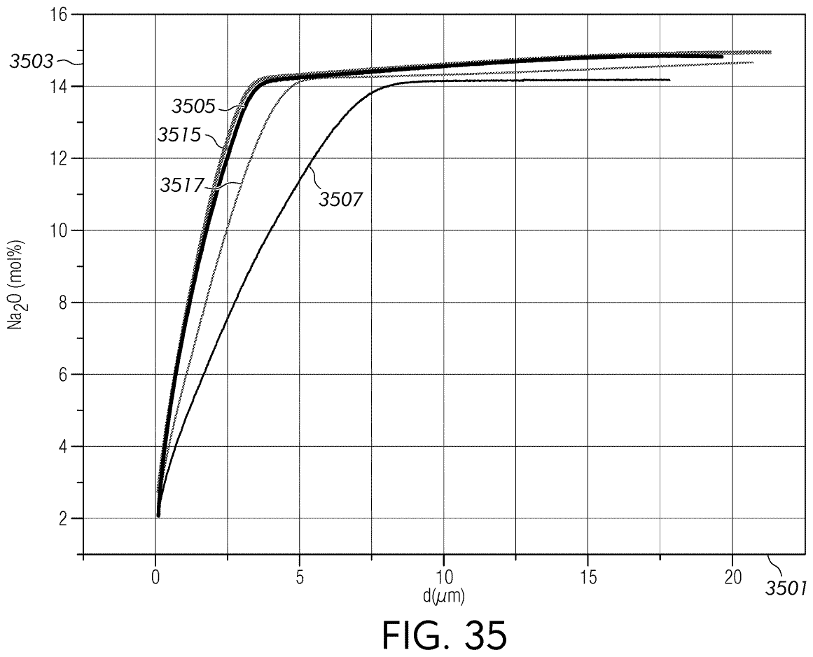

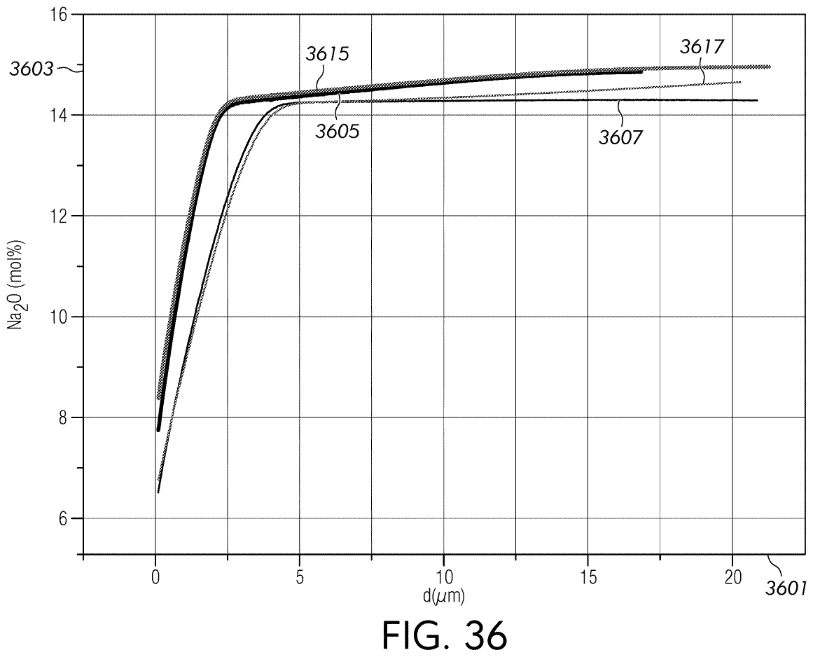

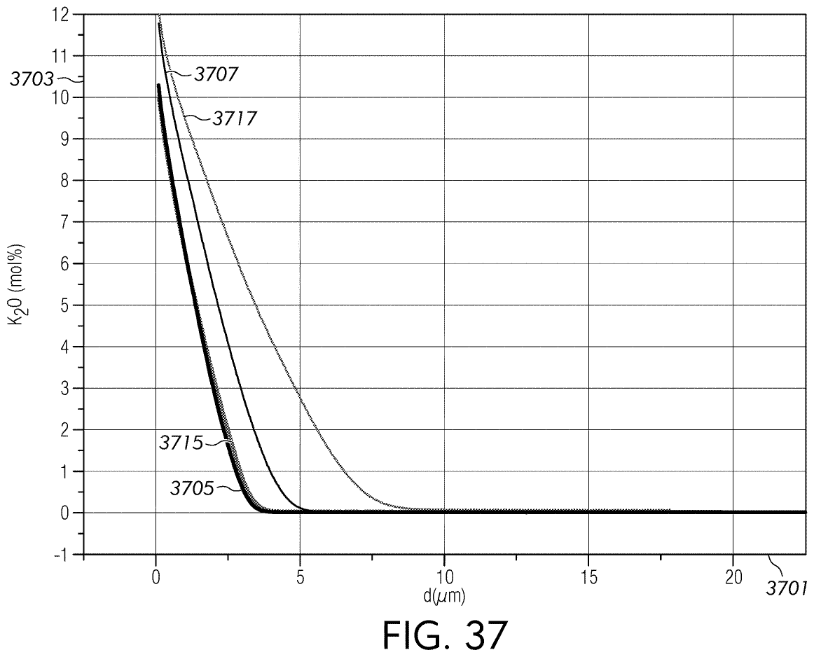

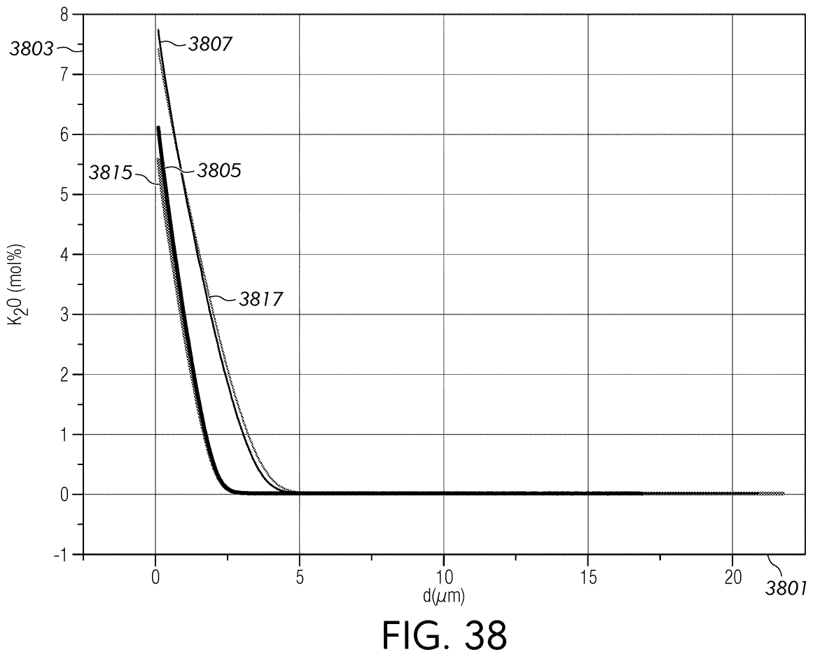

FIGS. 33-38 compare concentration profiles in Example L1 (i.e., only condition L1 with or without a subsequent etching treatment) with corresponding concentration profiles in Example L3-S4 (i.e., condition L3 followed by S4 with or without a subsequent etching treatment). FIGS. 33, 35, and 37 are for Examples L1 and L3-S4 without a subsequent etching treatment; FIGS. 34, 36, and 38 are for Examples L1 and L3-S4 after the subsequent etching treatment (as described above). In FIGS. 33-38, the horizontal axis 3301, 3401, 3501, 3601, 3701, and 3801 (i.e., x-axis) corresponds to depth (d) in micrometers (μm) from a corresponding surface (in the first portion or the central portion). The vertical axis 3303, 3403, 3503, 3603, 3703, and 3803 (i.e., y-axis) corresponds to concentrations of an alkali metal oxide (i.e., lithium oxide (Li₂O) in FIGS. 33-34, sodium oxide (Na₂O) in FIGS. 35-36, and potassium oxide (K₂O) in FIGS. 37-38) in mol %.

FIG. 33 illustrates concentration profiles of lithium oxide (Li₂O) for Examples L1 and L3-S4 (both) without a subsequent etching treatment. In FIG. 33, curves 3305 and 3315 correspond to Example L1, where curve 3305 corresponds to the concentration profile of Li₂O in the central portion (from the first central surface area) and curve 3315 corresponds to the concentration profile of Li₂O in the first portion (from the first major surface). Curves 3307 and 3317 correspond to Example L3-S4, where curve 3307 corresponds to the concentration profile of Li₂O in the central portion (from the first central surface area) and curve 3317 corresponds to the concentration profile of Li₂O in the first portion (from the first major surface).

In FIG. 33, curves 3305 and 3315 (Example L1) fall from a surface concentration of about 2.0 mol % or more to less than 0.25 mol % at a depth of 20 μm from the corresponding surface. For curve 3315, the Li₂O concentration profile declines over the whole range shown, which suggests that the concentration would continue to decrease to the bulk concentration (i.e., 0 mol % here) by the first point. In contrast, the Li₂O concentration profile shown in curve 3305 appears to level off from 15 μm to 20 μm, which suggests that the central concentration of Li₂O for Example L1 may be greater than the bulk concentration by from 0.1 mol % to 0.2 mol %. Compared with curves 3305 and 3315 corresponding to Example L1, curves 3307 and 3317 corresponding to Example L3-S4 have lower surface concentrations of Li₂O but higher Li₂O concentrations at depths greater than about 5 μm. The decreased surface concentration of Li₂O is expected due to the second ion-exchange step (condition S4) in Condition L3-S4 that exchanges near-surface alkali metals with those in the molten salt solution of condition S4, whereas Example L1 does not have a corresponding second ion-exchange treatment. At the same time, the elevated Li₂O concentration at depths greater than about 5 μm is likely a combination of (1) the increased lithium content in condition L3 compared with condition L1 (0.85 wt %>0.5 wt %) and (2) the additional time at elevated temperatures during condition L4 allows the lithium (and other alkali metals) to diffuse within the glass-based substrate. This diffusion has the effect of reducing the slope of the concentration profile as there is a net flow of Li₂O from regions of high concentration to those with lower concentration. This can be seen most directly in curve 3307, where the Li₂O concentration profile is substantially flat with a surface concentration of about 0.8 mol % and a concentration at a depth of 15 μm of about 0.7 mol %—as compared with the decrease from a surface concentration 2.0 mol % to less than 0.25 mol % in curve 3305. Consequently, it is believed that the concentration profile of Li₂O in the central portion for Example L3-S4 would be elevated by at least 0.3 mol % (e.g., from about 0.5 mol % to 0.7 mol %) at the central midpoint based on curve 3307—relative to the corresponding concentration in the bulk (e.g., at the first midpoint of the first portion). In the first portion, curve 3317 decreases more gradually than curve 3315, but curve 3317 still decreases for the entire region shown, which suggests that the first point of lithium is likely equal to the bulk concentration of 0. This corresponds to a midpoint lithium difference of at least 0.3 mol % (e.g., from about 0.5 mol % to 0.7 mol %) and a central surface lithium difference of less than 0.3 mol % (e.g., from about 0.1 mol % to 0.2 mol %).

FIG. 34 illustrates concentration profiles of lithium oxide (Li₂O) for Examples L1 and L3-S4 (both) after a subsequent etching treatment. In FIG. 34, curves 3405 and 3415 correspond to Example L1, where curve 3405 corresponds to the concentration profile of Li₂O in the central portion (from the first central surface area) and curve 3415 corresponds to the concentration profile of Li₂O in the first portion (from the first major surface). Curves 3407 and 3417 correspond to Example L3-S4, where curve 3407 corresponds to the concentration profile of Li₂O in the central portion (from the first central surface area) and curve 3417 corresponds to the concentration profile of Li₂O in the first portion (from the first major surface).

In FIG. 34, the surface concentrations for curves 3405 and 3415 are between 1.0 mol % and 1.2 mol %. Compared to curves 3305 and 3315 in FIG. 33, the surface concentration in curves 3405 and 3415, respectively, are noticeably reduced in FIG. 34. In contrast, the surface concentration of curves 3407 and 3417 in FIG. 34 are comparable to the surface concentration of curves 3405 and 3415, respectively, in FIG. 33. This appears to be the result of the relatively flat Li₂O concentration profile for Example L3-S4 (especially in the central portion as shown in curve 3407) relative to Example L1. Consequently, the midpoint lithium differences and central surface lithium difference for Example L3-S4 is substantially unchanged between FIGS. 33-34.

FIG. 35 illustrates concentration profiles of sodium oxide (Na₂O) for Examples L1 and L3-S4 (both) without a subsequent etching treatment. In FIG. 35, curves 3505 and 3515 correspond to Example L1, where curve 3505 corresponds to the concentration profile of Na₂O in the central portion (from the first central surface area) and curve 3515 corresponds to the concentration profile of Na₂O in the first portion (from the first major surface). Curves 3507 and 3517 correspond to Example L3-S4, where curve 3507 corresponds to the concentration profile of Na₂O in the central portion (from the first central surface area) and curve 3517 corresponds to the concentration profile of Na₂O in the first portion (from the first major surface).

In FIG. 35, curves 3505 and 3515 (Example L1) have a surface concentration of Na₂O less than 3.0 mol % and continuously increases towards the bulk concentration over the whole range shown. Similarly, curves 3507 and 3517 (Example L3-S4) have a surface concentration less than 3.0 mol % and continuously increases towards the bulk concentration over the whole range shown. Curves 3507 and 3517 (Example L3-S4) differ from curves 3505 and 3515 (Example L1) in that the Na₂O concentration increases more gradually from the corresponding surface. Also, curves 3507 and 3517 (Example L3-S4) have a deeper “knee” (e.g., between a steeper near-surface slope and a shallower deeper slope) of about 5 μm or more compared to the corresponding knee in curves 3505 and 3515 (Example L1) at about 3 μm. The differences in slope and knee position are due to the potassium-containing second ion-exchange treatment (condition S4) for Example L3-S4 that decreases the near-surface Na₂O concentration whereas there is no corresponding second ion-exchange treatment for Example L1.

FIG. 36 illustrates concentration profiles of sodium oxide (Na₂O) for Examples L1 and L3-S4 (both) after a subsequent etching treatment. In FIG. 36, curves 3605 and 3615 correspond to Example L1, where curve 3605 corresponds to the concentration profile of Na₂O in the central portion (from the first central surface area) and curve 3615 corresponds to the concentration profile of Na₂O in the first portion (from the first major surface). Curves 3607 and 3617 correspond to Example L3-S4, where curve 3607 corresponds to the concentration profile of Na₂O in the central portion (from the first central surface area) and curve 3617 corresponds to the concentration profile of Na₂O in the first portion (from the first major surface).

In FIG. 36, the Na₂O surface concentrations for curves 3605, 3615, 3607, and 3617 are all elevated (e.g., greater than 6 mol %) relative to their counterparts in FIG. 35 (i.e., curves 3505, 3515, 3507, and 3617, respectively, having Na₂O surface concentrations less than 3 mol %). This is consistent with the etching removing a portion of the substrate near the corresponding surface, which effectively shifts the concentration profiles in FIG. 35 to the left by the thickness removed (to arrive at the concentration profiles shown in FIG. 36). Also, the Na₂O surface concentrations for Example L1 (about 8 mol % in curves 3605 and 3615) is higher than the Na₂O surface concentrations for Example L3-S4 (about 6.5 mol % in curves 3607 and 3617). As discussed for FIG. 35, the difference between the Na₂O surface concentrations for Examples L1 and L3-S4 is due to the second ion-exchange treatment in Example L3-S4 (condition S4). It is to be understood that the surface concentration (and near-surface concentration) of Na₂O would be higher (relative to Example L3-S4) if the molten salt solution for the second ion-exchange condition had more sodium salt (i.e., a mixture of a sodium salt and the larger alkali metal salt (e.g., potassium salt)) rather than the potassium salt molten salt solution used in condition S4.

FIG. 37 illustrates concentration profiles of potassium oxide (K₂O) for Examples L1 and L3-S4 (both) without a subsequent etching treatment. In FIG. 37, curves 3705 and 3715 correspond to Example L1, where curve 3705 corresponds to the concentration profile of K₂O in the central portion (from the first central surface area) and curve 3715 corresponds to the concentration profile of K₂O in the first portion (from the first major surface). Curves 3707 and 3717 correspond to Example L3-S4, where curve 3707 corresponds to the concentration profile of K₂O in the central portion (from the first central surface area) and curve 3717 corresponds to the concentration profile of K₂O in the first portion (from the first major surface).

In FIG. 37, curves 3705 and 3715 (Example L1) have a surface concentration of K₂O of about 10.2 mol % continuously decreases towards the bulk concentration (i.e., 0 mol %) over about the first 3 μm. Curves 3707 and 3717 (Example L3-S4) have a surface concentration greater than 11 mol % (e.g., about 12 mol %) continuously decreases over the first 5 μm to about 8 μm. The greater K₂O surface concentration in Example L3-S4 (relative to Example L1 in FIG. 37) is due to the second ion-exchange treatment (condition S4). The deeper depth of elevated K₂O concentration in Example L3-S4 (relative to Example L1 in FIG. 37) is a combination of the potassium introduced in the second ion-exchange treatment as well as the additional time at elevated temperature associated with condition S4. Notably, curves 3707 and 3717 have greater K₂O concentrations than curves 3705 and 3715 over at least the first 5 μm from the surface. Consequently, as shown in FIG. 38 (discussed below), after etching both Examples L1 and L3-S4, the near-surface K₂O concentration profile is still greater for Example L3-S4 than for Example L1.

FIG. 38 illustrates concentration profiles of potassium oxide (K₂O) for Examples L1 and L3-S4 (both) after a subsequent etching treatment. In FIG. 38, curves 3805 and 3815 correspond to Example L1, where curve 3805 corresponds to the concentration profile of K₂O in the central portion (from the first central surface area) and curve 3815 corresponds to the concentration profile of K₂O in the first portion (from the first major surface). Curves 3807 and 3817 correspond to Example L3-S4, where curve 3807 corresponds to the concentration profile of K₂O in the central portion (from the first central surface area) and curve 3817 corresponds to the concentration profile of K₂O in the first portion (from the first major surface).

In FIG. 38, the K₂O surface concentrations for curves 3805, 3815, 3807, and 3817 are all lower than their counterparts in FIG. 37 (i.e., curves 3705, 3715, 3707, and 3717, respectively). This is consistent with the etching removing a portion of the substrate near the corresponding surface, which effectively shifts the concentration profiles in FIG. 37 to the left by the thickness removed (to arrive at the concentration profiles shown in FIG. 38). Also, the K₂O surface concentrations for Example L3-S4 (about 7.5 mol % in curves 3807 and 3817) is higher than the K₂O surface concentrations for Example L1 (about 5.5 mol % to 6 mol % in curve 3805 and 3815). As discussed for FIG. 37, the difference between the K₂O surface concentrations for Examples L1 and L3-S4 is due to the second ion-exchange treatment in Example L3-S4 (condition S4). It is to be understood that the surface concentration (and near-surface concentration) of K₂O would be lower (relative to Example L3-S4) if the molten salt solution for the second ion-exchange condition had more sodium salt (i.e., a mixture of a sodium salt and the larger alkali metal salt (e.g., potassium salt)) rather than the potassium salt molten salt solution used in condition S4. Also, as shown, the depth of layer is equal between curves 3807 and 3817, which is attributed to simultaneously ion-exchanging the first portion and the central portion without any masks or other barriers between the corresponding molten salt solution(s) and the portions of the glass-based substrate.

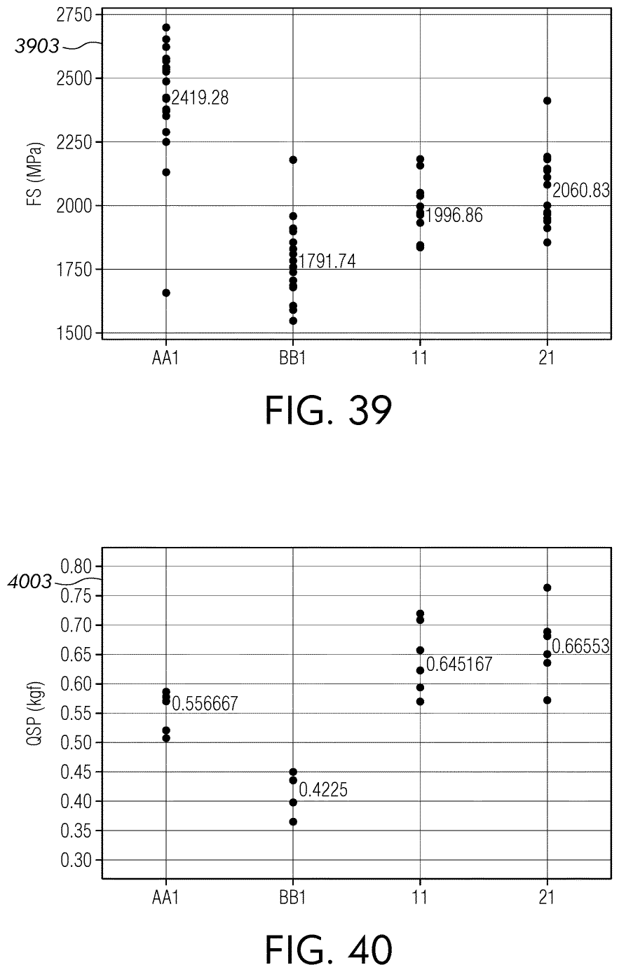

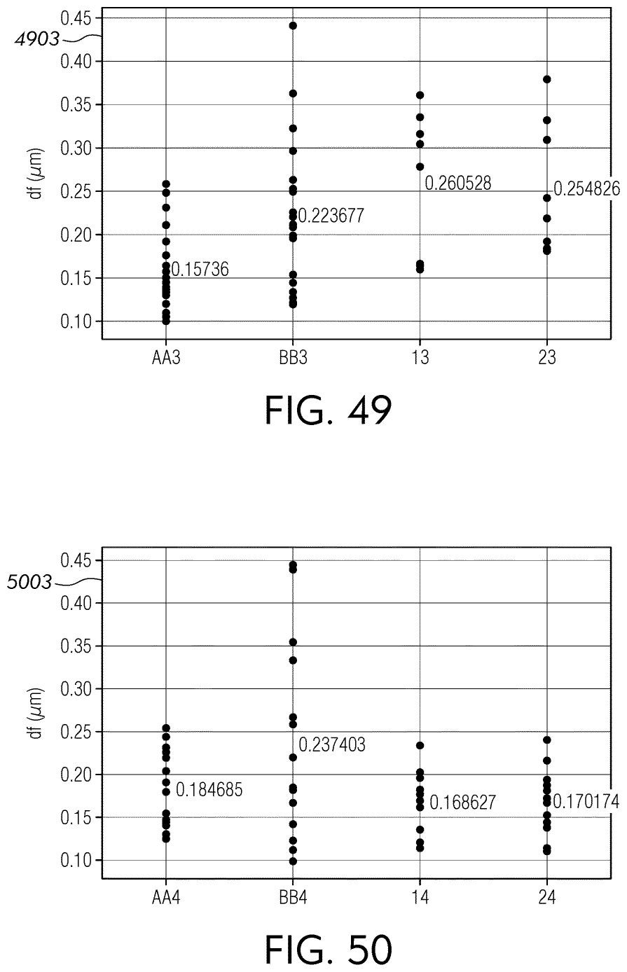

FIGS. 39-52 present properties of Examples 11-14, 21-24, AA1-AA4, and/or BB1-BB4. The conditions for making Examples 11-14, 21-24, AA1-AA4, and/or BB1-BB4 are provided in Table 4. The substrate thickness for all of Examples 11-14, 21-24, AA1-AA4, and/or BB1-BB4 was nominally 40 μm after the etching. Consequently, the thickness before the etching mentioned in Table 4 was greater than 40 μm by twice the amount (if any) etched from each side. For example, Example AA3 had a thickness of 41 μm before 0.5 μm was etched from each of the first major surface and the second major surface (i.e., per side) to arrive at a final thickness of 40 μm. Examples AA1-AA4 used glass substrates without a thinner central portion (uniform substrate thickness of 40 μm) while Examples BB1-BB4, 11-14, and 21-24 had a thinner central portion (40 μm central thickness) than the substrate thickness (80 μm substrate thickness). The reported CS and DOL in Table 4 refers to the portion of the example substrate having the thickness of 40 μm (either the entire substrate for Examples AA1-AA4 or the central portion having the central thickness in Examples BB1-BB4, 11-14, and 21-24).

TABLE 4
Conditions for Examples 11-14, 21-24, AA1-AA4, and BB1-BB4

| | | | Thickness | | |
|---|---|---|---|---|---|
| | Substrate | | Etched per | CS | DOL |
| Example | Configuration | IOX Conditions | Side (μm) | (MPa) | (μm) |
| AA1 | Uniform thickness | 100 wt % KNO₃ | 0 (none) | 1053 | 8.1 |
| AA2 | (40 μm) | 380 °C for 18 min | 0.25 | 962 | 7.1 |
| AA3 | | | 0.5 | 960 | 7.1 |
| AA4 | | | 0.75 | 917 | 6.8 |
| BB1 | 80 μm substrate | (L1) | 0 (none) | 802 | 4.6 |
| BB2 | thickness + | 0.5 wt % LiNO₃ + | 0.25 | 754 | 4.5 |
| BB3 | 40 μm central | 99.5 wt % KNO₃ | 0.5 | 720 | 4.5 |
| BB4 | thickness | 410 °C for 2 min | 0.75 | 676 | 4.4 |
| 11 | 80 μm substrate | (L2 + S4) | 0 (none) | 1010 | 6.8 |
| 12 | thickness + | 0.65 wt % LiNO₃ + | 0.25 | 894 | 5.2 |
| 13 | 40 μm central | 99.35 wt % KNO₃ | 0.5 | 876 | 5.2 |
| 14 | thickness | 410 °C for 2 min | 0.75 | 762 | 5.1 |
| | | then | | | |
| | | 100 wt % KNO₃ | | | |
| | | 410 °C for 2 min | | | |
| 21 | 80 μm substrate | 0.8 wt % LiNO₃ + | 0 (none) | 1009 | 6.1 |
| 22 | thickness + | 99.2 wt % KNO₃ | 0.25 | 894 | 5.2 |
| 23 | 40 μm central | 410 °C for 2 min | 0.5 | 881 | 5.2 |
| 24 | thickness | then (S4) | 0.75 | 744 | 5.0 |
| | | 100 wt % KNO₃ | | | |
| | | 410 °C for 2 min | | | |

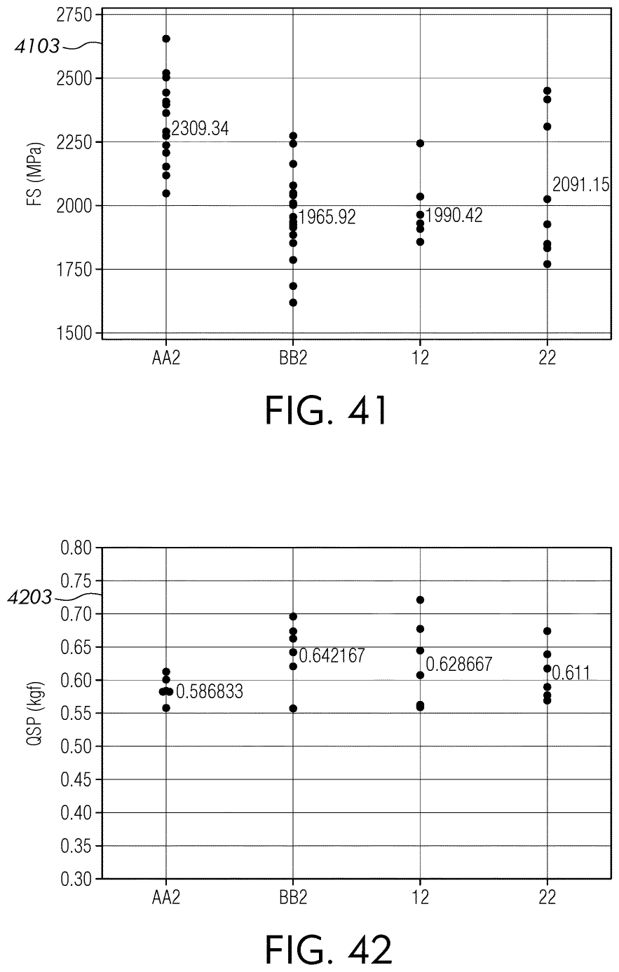

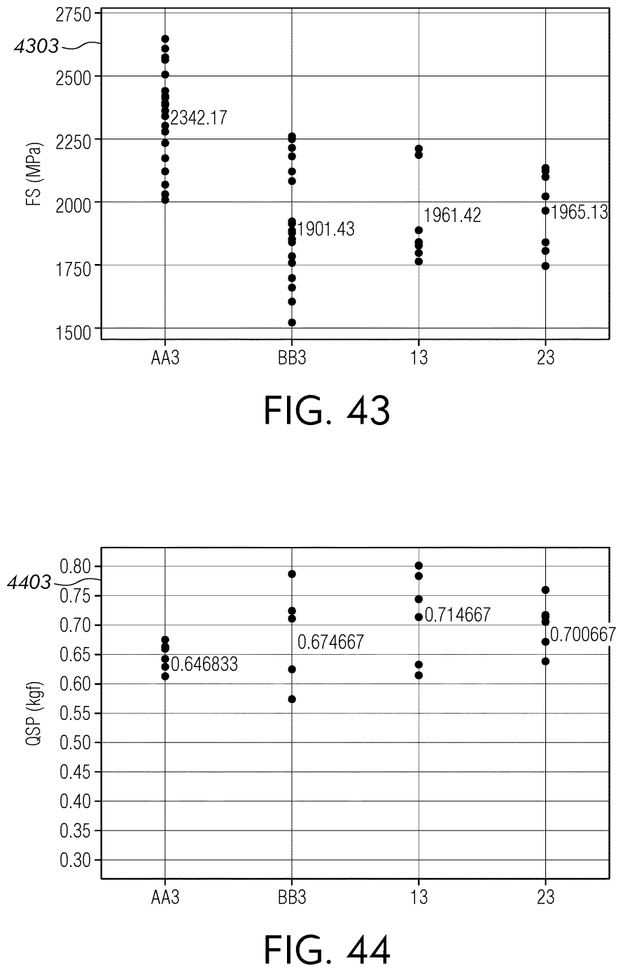

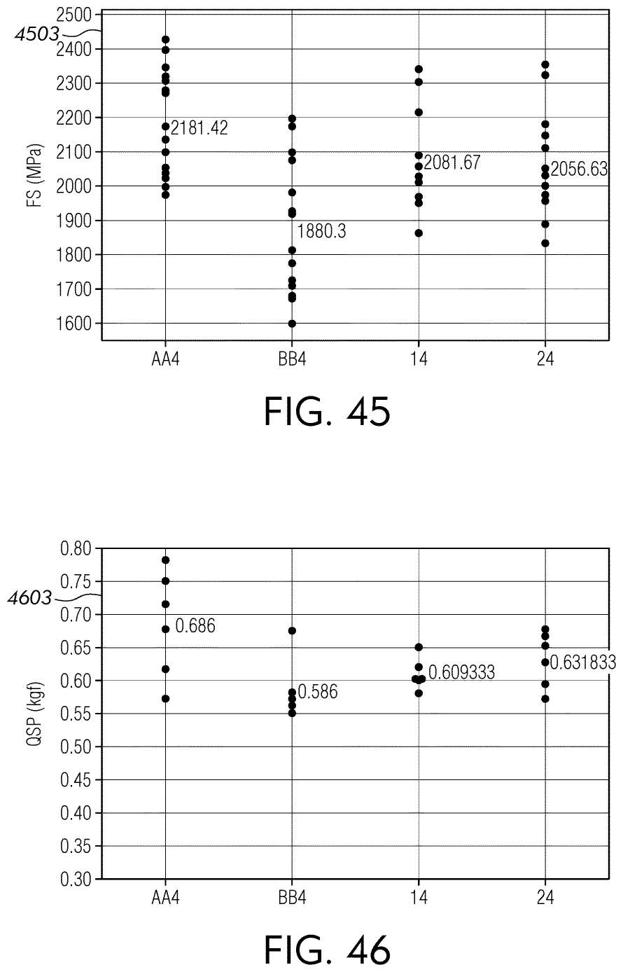

Table 5 presents the properties of Examples 11-14, 21-24, AA1-AA4, and BB1-BB4. FIGS. 39, 41, 43, and 45 illustrate failure strength (FS) in MegaPascals (MPa) on the vertical axis 3903, 4103, 4303, and 4503 (i.e., y-axis) for the Examples. The examples shown in FIG. 39 did not have any etching after the ion-exchange (IOX) conditions stated in Table 4. In FIG. 39, Example BB1 had the lowest failure strength (e.g., median failure strength of less than 1800 MPa) and Example AA1 had the highest failure strength while Examples 11 and 21 had failure strength (e.g., about 2000 MPa or more) that was in between these extremes. A similar (albeit less pronounced) trend is seen for the failure strength shown in FIG. 41 for the examples with 0.25 μm etched from each surface. Going from FIG. 39 to FIG. 41, the smallest changes in failure strength are seen going from Example 11 to Example 12 (0.65 wt % LiNO₃) and from Examples 21 to Example 22 (0.8 wt % LiNO₃). Likewise, the trend in FIG. 43 (for examples with 0.5 μm etched from each side) is similar to that seen in FIGS. 39 and 41. In FIG. 43, Examples 13 and/or 23 have a failure strength of greater than about 1960 MPa or about 1965 MPa. While the overall trend in FIG. 45 (for examples with 0.75 μm etched from each side) is similar to that seen in FIGS. 39, 41, and 43, the failure strength for Examples 14 and 24 increased relative to Examples 12 and 22, respectively. This increase in failure strength from etching additional thickness is unexpected since it would be expected that removing addition thickness corresponding to the compressive stress region would weaken the article. Here, Examples 14 and 24 have a failure strength greater than 1990 MPa, greater than 2000 MPa, and even greater than or equal to 2050 MPa. Overall, Examples 11-14 and 21-24 had failure strengths greater than or equal to the corresponding example of Examples BB1-BB4.

TABLE 5
Properties of Examples 11-14, 21-24, AA1-AA4, and BB1-BB4

| | Thickness | | | | | |
|---|---|---|---|---|---|---|
| | Etched per | CS | DOL | FS | QSP | df |
| Example | Side (μm) | (MPa) | (μm) | (MPa) | (kgf) | (μm) |
| AA1 | 0 (none) | 1053 | 8.1 | 2419.28 | 0.5567 | 0.1798 |
| AA2 | 0.25 | 962 | 7.1 | 2309.34 | 0.5868 | 0.1625 |
| AA3 | 0.5 | 960 | 7.1 | 2342.17 | 0.6468 | 0.1574 |
| AA4 | 0.75 | 917 | 6.8 | 2181.42 | 0.6860 | 0.1847 |
| BB1 | 0 (none) | 802 | 4.6 | 1791.74 | 0.4225 | 0.3038 |
| BB2 | 0.25 | 754 | 4.5 | 1965.92 | 0.6422 | 0.2497 |
| BB3 | 0.5 | 720 | 4.5 | 1901.43 | 0.6747 | 0.2237 |
| BB4 | 0.75 | 676 | 4.4 | 1880.30 | 0.5860 | 0.2374 |
| 11 | 0 (none) | 1010 | 6.8 | 1996.86 | 0.6452 | 0.3021 |
| 12 | 0.25 | 894 | 5.2 | 1990.42 | 0.6287 | 0.2438 |
| 13 | 0.5 | 876 | 5.2 | 1961.42 | 0.7147 | 0.2605 |
| 14 | 0.75 | 762 | 5.1 | 2081.67 | 0.6093 | 0.1686 |
| 21 | 0 (none) | 1009 | 6.1 | 2060.83 | 0.6655 | 0.2689 |
| 22 | 0.25 | 894 | 5.2 | 2091.15 | 0.6110 | 0.2232 |
| 23 | 0.5 | 881 | 5.2 | 1965.13 | 0.7007 | 0.2548 |
| 24 | 0.75 | 744 | 5.0 | 2056.63 | 0.6318 | 0.1702 |

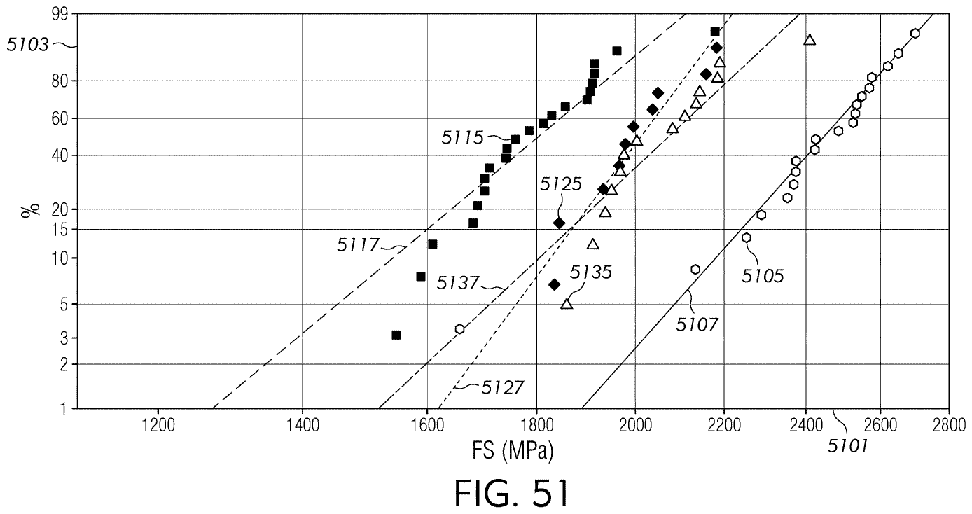

FIG. 51 illustrates a Weibull distribution for Examples AA1, BB1, 11, and 21 showing failure probability in percent (%) on the vertical axis 5103 (i.e., y-axis) as a function of failure strength (FS) in MegaPascals (MPa) on the horizontal axis 5101 (i.e., x-axis). Points 5105 represents experimentally measured values of Example AA1 with the trend indicated by line 5107. Points 5115 correspond to experimentally measured values of Example BB1 with the trend indicated by line 5117. Points 5125 correspond to experimentally measured values of Example 11 with the trend indicated by line 5127. Points 5135 correspond to experimentally measured values of Example 21 with the trend indicated by line 5137. As in FIG. 39, the failure strength for Example AA1 (line 5107) is greater than Example BB1 (line 5117) (at a the same failure percentage). Examples 11 and 12 (lines 5127 and 5137) are in between the performance of Examples BB1 and AA1 (lines 5117 and 5107). As used herein, the B10 failure strength corresponds to the failure strength value with a failure probability of 10% in a Weibull distribution (as shown in FIG. 51). Here, Examples 11 and 21 had B10 failure strengths of about 1800 MPa or more.

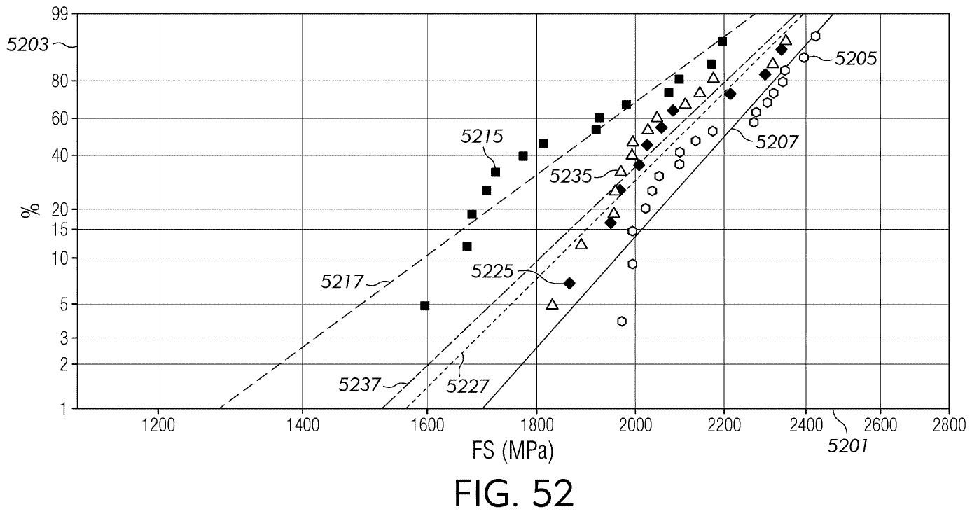

FIG. 52 illustrates a Weibull distribution for Examples AA4, BB4, 14, and 24 showing failure probability in percent (%) on the vertical axis 5203 (i.e., y-axis) as a function of failure strength (FS) in MegaPascals (MPa) on the horizontal axis 5201 (i.e., x-axis). Points 5205 represents experimentally measured values of Example AA4 with the trend indicated by line 5207. Points 5215 correspond to experimentally measured values of Example BB4 with the trend indicated by line 5217. Points 5225 correspond to experimentally measured values of Example 14 with the trend indicated by line 5227. Points 5235 correspond to experimentally measured values of Example 24 with the trend indicated by line 5237. As in FIG. 45, the failure strength for Example AA4 (line 5207) is greater than Example BB4 (line 5217) (at a the same failure percentage). Examples 14 and 14 (lines 5227 and 5237) are in between the performance of Examples BB4 and AA4 (lines 5217 and 5207). Compared to the relationship between the examples (e.g., lines) in FIG. 51, in FIG. 52 Examples 14 and 24 (lines 5227 and 5237) are much closer to Example AA4 (line 5207) (than Examples 11 and 21 are to Example AA1 in FIG. 51). Indeed, as shown in FIG. 52, the difference in B10 failure strength of Example AA4 and either of Examples 14 or 24 is about 200 MPa or less (whereas the corresponding difference is much greater for the examples shown in FIG. 51). Here, the B10 failure strength of Examples 14 and 24 is about 1800 MPa. Notably, the failure strength of Examples 14 and 24 (having 0.75 μm etched from each side) is comparable to the failure strength of Examples 11 and 21 (no etching after IOX) despite (or because of) the post-IOX etching.

FIGS. 40, 42, 44, and 46 illustrates puncture resistance as measured in the Quasi-Static Puncture Test (QSP) in kilograms-force (kgf) on the vertical axis 4003, 4203, 4403, and 4403 (i.e., y-axis). The puncture strength was measured in the portion of the examples having a thickness of 40 μm for all articles. In FIG. 40, Example BB1 has a lower puncture resistance than Example AA1. Examples 11 and 21 have greater puncture resistance (e.g., greater than or equal to 0.60 kgf or greater than or equal to 0.64 kgf) than Examples AA1 and BB1. Compared to the failure strength in FIG. 39, the higher puncture resistance of Examples 11 and 21 relative to Example AA1 in FIG. 40 is unexpected since the complex geometry of these examples (having the difference in thickness and associated chemical strengthening-induced strain) would be expected to decrease the mechanical strength (including the puncture resistance) of the central portion.

In FIG. 42 (examples having 0.25 μm etched from each side), the puncture resistance of Examples 12 and 22 is greater than or equal to 0.60 kgf, although puncture resistance for Example BB2 is slightly greater than that for Examples 12 and 22. In FIG. 44 (examples having 0.50 μm etched from each side), Examples 13 and 14 have greater puncture resistance (e.g., greater than or equal to 0.70 kgf) than Examples AA3 and BB3. Also, the examples in FIG. 44 (0.50 μm etched from each side) had greater puncture resistance than the examples in FIG. 42 (0.25 μm etched from each side) despite having more thickness (and therefore more of the compressive stress region) removed by etching.

In FIG. 46, Examples 14 and 24 have a puncture resistance of greater than or equal to about 0.60 kgf (or 0.61 kgf). Also, the failure strength of Example 14 and 24 is in between that of Examples BB4 and AA4. Combining FIGS. 45-46, Examples 14 and 24 are able to simultaneously achieve a failure strength greater than or equal to 2050 MPa and a puncture resistance greater than or equal to about 0.61 kgf. These properties (for Example 14 and 24) are comparable to that of Example AA4 (having no lithium IOX and without a thinned central portion).

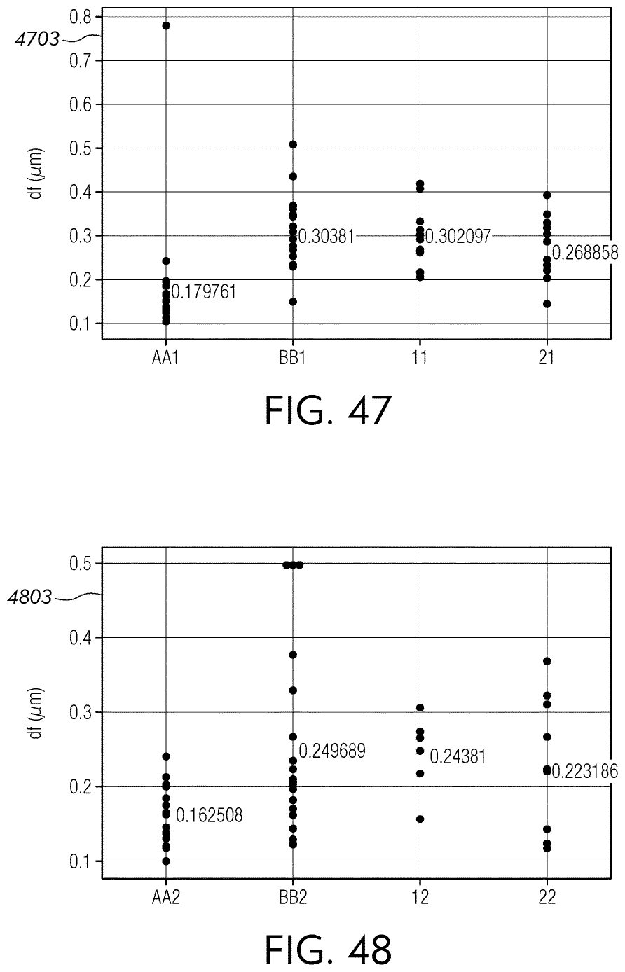

FIGS. 47-50 illustrate flaw depth (df) in micrometers (μm) on the vertical axis 4703, 4803, 4903, and 5003 (i.e., y-axis). As discussed above, lower calculated flaw depths are associated with higher strength. Consequently the trends in FIGS. 47-50 are the same as that in FIGS. 39, 41, 43, and 45 (with higher FS and lower flaw depths being associated with higher strength). Across FIGS. 47-50, the flaw depth significantly decreases in FIG. 50 for Examples 14 and 24 (relative to Examples 11-13 and 21-23, respectively) to less than 0.20 μm (from etching 0.75 μm from each side) while the flaw depth is either the same or higher as the amount etch increases between 0.25 μm (or 0.50 μm) and 0.75 μm for Examples AA2-AA4 and BB2-BB4.

As discussed above, Example L1 after the etching had a maximum compressive stress of 430 MPa and a depth of layer of 3 μm. After the etching, Example L3-S4 had a surface compressive stress of 670 MPa (36% increase relative to Example L1) and a depth of layer 4 μm (25% increase relative to Example L1). Compared to Example L1, the increase in surface compressive stress and depth of layer is due to the second ion-exchange treatment (condition S4). At the same time, Example L3-S4 represents an increase in surface compressive stress and depth of layer relative to a glass-based substrate formed without the lithium salt in the first molten salt solution that does not exhibit buckling before etching. For example, with reference to the discussion of the schematic stress profiles in FIG. 20 above, curve 2007 (pure potassium molten salt solution) can have essentially the same stress profile as curve 2015 (e.g., in accordance with aspects of the present disclosure) beyond dashed line 2009 (e.g., depth that the substrate may be etched to) but the extent of buckling or other mechanical instabilities would be less for curve 2015 than curve 2005 due to the lower expansion-induced strain (attributable to the lithium salt in the first molten salt solution—as illustrated in FIGS. 14-15). Further, as discussed herein, the compressive stress after etching would be even lower if the pure potassium molten salt solution (in line with the approach discussed with reference to curve 2007) was used to produce a glass-based substrate without buckling or other mechanical buckling throughout processing. Additionally, as discussed with reference to FIG. 20, it is believed that the combination of a lithium-containing molten salt solution for an earlier ion-exchange treatment along with etching to recover a buckling-free glass-based substrate after a later ion-exchange treatment (in accordance with the present disclosure) can be used to achieve even greater surface compressive stresses and/or deeper depths of layer through the use of a mixed alkali metal molten salt solution.

The above observations can be combined to provide foldable apparatus comprising foldable substrates, foldable substrates, and method of making the same comprising a first portion, a second portion, and a central portion positioned therebetween. The foldable substrate can comprise a glass-based and/or ceramic-based material, which can provide good dimensional stability, reduced incidence of mechanical instabilities, good impact resistance, and/or good puncture resistance. The glass-based and/or ceramic-based material of the foldable substrate comprises one or more compressive stress regions, which can further provide increased impact resistance and/or increased puncture resistance while simultaneously facilitating good folding performance. Providing foldable substrates comprising a central portion comprising a central thickness that is less than a substrate thickness (e.g., first thickness of the first portion and/or second thickness of the second portion) (e.g., by 10 μm or more) can enable a small parallel plate distance (e.g., 10 millimeters or less) based on the reduced thickness in the central portion, which can enable the foldability and/or rollability of the foldable substrate and/or foldable apparatus.

The present disclosure demonstrates that buckling-free and low warp foldable substrates can be obtained that have high compressive stress in the central portion. It has unexpectedly been demonstrated that a foldable substrate can be formed from a precursor (e.g., strengthened substrate) with a buckled central portion that is etched to become free of buckling. Previously, it was thought to be beneficial to avoid buckling throughout the entire process of making a foldable substrate because it was believed that buckling could not be undone once induced due to the non-linear behavior that occurs when the critical buckling strain is exceeded. However, allowing the presence of buckling during methods of the present disclosure enables higher compressive stress to be achieved for foldable substrates (and through methods of present disclosure). Further, the resulting foldable substrate herein can be closer to the critical buckling strain than previously thought possible that have a low warp and a free of buckling. Additionally, as demonstrated herein, foldable substrates that are free of buckling and have low warp can be achieved through a series of chemical strengthening steps.

Additionally, methods of present disclosure allow for the formation of foldable substrates without masks or other barriers during the chemical strengthening steps. Consequently, in aspects, the first depth of layer can be equal to the first central depth of layer, and/or the first maximum compressive stress can be substantially equal to the first central maximum compressive stress. Providing a first depth of layer that is equal to the first central depth of layer can be consistent with the first portion and the central portion being subjected to similar and/or simultaneous chemical strengthening treatment(s).

Foldable substrates can have a higher concentration of lithium at a midpoint of the central portion having the central thickness than at the midpoint of the first portion having the substrate thickness such that the foldable substrate exhibits a non-zero central surface lithium difference. Without wishing to be bound by theory, the central surface lithium difference can reflect the final chemical strengthening treatment performed since the alkali metal ions (including lithium) exchanged between the substrate and the corresponding molten salt solution are located near the surface, especially when the duration of the corresponding chemical strengthening treatment is short. Consequently, a negative central surface lithium difference can correspond to a final (e.g., second) chemical strengthening treatment having less (compared to an earlier chemical strengthening treatment) or even being substantially free of lithium. Further, a negative central surface lithium difference in combination with a positive midpoint lithium difference can correspond to or otherwise be consistent with the methods of the present disclosure since (1) an earlier (e.g., first) chemical strengthening treatment added lithium through the central portion (including the central midpoint) but that earlier chemical strengthening treatment did not add lithium throughout the entire first portion (including the first midpoint) and (2) the molten salt solution for the final (e.g., second, later) chemical strengthening treatment had lower lithium concentration than the earlier chemical strengthening treatments (and/or the molten salt bath for the later chemical strengthening treatment was substantially free of lithium) and/or high amounts of a larger alkali metal ion (e.g., the alkali metal described by the depth of compression associated with the corresponding compressive stress regions).

Providing from 0.1 wt % to 2.0 wt % (e.g., from 0.25 wt % to 1.0 wt %, from 0.45 wt % to 0.85 wt %) of a lithium salt in the first molten salt solution can generate an expansion-induced strain difference between the first portion and the second portion that is opposite of that normally encountered when chemically strengthening a foldable substrate having a central portion thinner than an adjacent first portion since lithium has the opposite effect of the larger alkali metal. This can be the case even when the first molten salt solution comprises both the lithium salt and a larger alkali metal salt (e.g., potassium salt). It is believed that without the lithium salt in the first molten salt bath it would not be possible to achieve the compressive stress and mechanical performance of the resulting foldable substrate without buckling or severe warping of the central portion and/or making the central portion frangible, especially when no masks or other barriers are placed between any portion of the foldable substrate and the corresponding molten salt solution throughout the chemical strengthening steps herein.

As demonstrated by the Examples herein, the etching can remove enough of the corresponding compressive stress region(s) (including the near-surface portions potentially having the highest concentration of the larger alkali metal oxide) to reduce the expansion-induced strain experience by the central portion below the critical buckling strain, which is evidenced by the absence of buckling in the resulting foldable substrate.

Directional terms as used herein—for example, up, down, right, left, front, back, top, bottom—are made only with reference to the figures as drawn and are not intended to imply absolute orientation.

It will be appreciated that the various disclosed aspects may involve features, elements, or steps that are described in connection with that aspect. It will also be appreciated that a feature, element, or step, although described in relation to one aspect, may be interchanged or combined with alternate aspects in various non-illustrated combinations or permutations.

It is also to be understood that, as used herein the terms “the,” “a,” or “an,” mean “at least one,” and should not be limited to “only one” unless explicitly indicated to the contrary. For example, reference to “a component” comprises aspects having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Ranges can be expressed herein as from “about” one particular value, and/or to “about” another particular value. When such a range is expressed, aspects include from the one particular value and/or to the other particular value. Similarly, when values are expressed as approximations, by use of the antecedent “about,” it will be understood that the particular value forms another aspect. Whether or not a numerical value or endpoint of a range in the specification recites “about,” the numerical value or endpoint of a range is intended to include two aspects: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In aspects, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred.

While various features, elements, or steps of particular aspects may be disclosed using the transitional phrase “comprising,” it is to be understood that alternative aspects, including those that may be described using the transitional phrases “consisting of” or “consisting essentially of,” are implied. Thus, for example, implied alternative aspects to an apparatus that comprises A+B+C include aspects where an apparatus consists of A+B+C and aspects where an apparatus consists essentially of A+B+C. As used herein, the terms “comprising” and “including”, and variations thereof shall be construed as synonymous and open-ended unless otherwise indicated.

The above aspects, and the features of those aspects, are exemplary and can be provided alone or in any combination with any one or more features of other aspects provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the aspects herein provided they come within the scope of the appended claims and their equivalents.

What is claimed is:

1. A foldable apparatus comprising a substrate comprising:
a substrate thickness defined between a first major surface and a second major surface opposite the first major surface, the substrate comprising a glass-based material;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface;
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, the first central surface area is recessed from the first major surface by a first distance, and the central thickness is less than the substrate thickness, wherein a central midpoint is located midway between the first central surface area and the second central surface area, and a first midpoint is located midway between the first major surface and the second major surface in the first portion; and
a surface profile of the first central surface area along a midline midway between the first portion and the second portion, wherein the surface profile exhibits a warp of less than or equal to 1 millimeter, and the central portion is free of buckling,
wherein a first maximum compressive stress at the first major surface is from greater than or equal to 600 MegaPascals to less than or equal to 1,500 MegaPascals, and a first central maximum compressive stress at the first central surface area is from greater than or equal to 600 MegaPascals to less than or equal to 1,500 MegaPascals.

2. The foldable apparatus of claim 1, wherein the surface profile of the first central surface area exhibits one or more of:
an average gradient of less than or equal to 0.018 mm/mm;
a maximum local curvature of less than or equal to 10 Diopters; or combinations thereof.

3. The foldable apparatus of claim 1, wherein the first central surface area is substantially parabolic or substantially planar.

4. The foldable apparatus of claim 1, wherein a midpoint lithium difference defined as a central concentration of lithium oxide at the central midpoint of the central portion minus a first concentration of lithium oxide at the first midpoint of the first portion is from greater than or equal to 0.2 mol % to less than or equal to 2 mol %.

5. The foldable apparatus of claim 1, wherein a central surface lithium difference defined as a first central surface concentration of lithium oxide minus a central concentration of lithium oxide at the central midpoint of the central portion is from greater than or equal to −0.5 mol % to less than or equal to 0.5 mol %.

6. The foldable apparatus of claim 1, wherein a central surface larger alkali difference defined as a first central surface concentration of a larger alkali metal oxide at the first central surface area minus a central concentration of the larger alkali metal oxide at the central midpoint is from greater than or equal to 4 mol % to less than or equal to 14 mol %, wherein the larger alkali metal oxide is selected from a group of potassium oxide, rubidium oxide, cesium oxide, and francium oxide.

7. The foldable apparatus of claim 1, wherein the first maximum compressive stress is from greater than or equal to 650 MegaPascals to less than or equal to 1,300 MegaPascals, and the first central maximum compressive stress is from greater than or equal to 650 MegaPascals to less than or equal to 1,300 MegaPascals, and wherein an absolute value of a difference between the first maximum compressive stress and the first central maximum compressive stress is from greater than or equal to 0 MegaPascals to less than or equal to 100 MegaPascals.

8. The foldable apparatus of claim 1, comprising a first depth of layer of the larger alkali metal oxide in the first portion from the first major surface, a first central depth of layer of the larger alkali metal oxide in the central portion from the first central surface area, wherein a ratio of the first depth of layer to the first central depth of layer is from greater than or equal to 0.7 to less than or equal to 1.5.

9. The foldable apparatus of claim 8, wherein the central thickness is from greater than or equal to 20 micrometers to less than or equal to 120 micrometers, the substrate thickness as a multiple of the central thickness is from greater than or equal to 2 to less than or equal to 200.

10. The foldable apparatus of claim 1, wherein the foldable substrate exhibits one or more of:
a failure strength of 1965 MegaPascals or more;
a puncture resistance as measured in a Quasi-Static Puncture Test of 0.61 kgf or more; or
a flaw depth of 0.2 micrometers or less.

11. A method of making a foldable substrate comprising:
chemically strengthening a substrate in a first molten salt solution maintained at from greater than or equal to 350 °C to less than or equal to 500 °C for a first period of time from greater than or equal to 1 minute to less than or equal to 0.5 hours to form an intermediate substrate, the first molten salt solution comprises from greater than or equal to 0.1 wt % to less than or equal to 1.0 wt % of a lithium salt based on 100 wt % of the first molten salt solution, the substrate being chemically strengthened comprises:
an existing first major surface and an existing second major surface opposite the first major surface present in a first portion and a second portion; and
a central portion positioned between the first portion and the second portion, the central portion comprising an existing central thickness defined between an existing first central surface area and an existing second central surface area opposite the existing first central surface area, the existing first central surface area is recessed from the existing first major surface by an existing first distance;
immersing the intermediate substrate in a second molten salt solution comprising a potassium salt maintained at from greater than or equal to 350 °C to less than or equal to 500 °C for a second period of time from greater than or equal to 1 minute to less than or equal to 0.5 hours to form a strengthened substrate; and then
etching the strengthened substrate with an etchant solution to remove at least a first outer layer from the existing first central surface area having a first outer thickness from greater than or equal to 10 nanometers to less than or equal to 10 micrometers to form the foldable substrate,
wherein the foldable substrate is a glass-based substrate comprising:
the first portion comprising a substrate thickness, a first compressive stress region extending to a first depth of compression from a first major surface, a second compressive stress region extending to a second depth of compression from a second major surface;
the second portion comprising the substrate thickness, a third compressive stress region extending to a third depth of compression from the first major surface, a fourth compressive stress region extending to a fourth depth of compression from the second major surface; and
the central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from a second central surface area, the first central surface area is recessed from the first major surface by a first distance, and the central thickness is less than the substrate thickness,
wherein the central portion of the strengthened substrate is buckled, and the central portion of the foldable substrate is free of buckling.

12. The method of claim 11, wherein a surface profile of the central portion of the strengthened substrate has a maximum local curvature of greater than or equal to 10 Diopters, and a surface profile of the central portion of the foldable substrate has a maximum local curvature of less than or equal to 10 Diopters, and the surface profile of the first central surface area is taken along a midline midway between the first portion and the second portion.

13. The method of claim 11, wherein the existing first central surface area of the strengthened substrate is non-planar and non-parabolic, and the first central surface area of the foldable substrate is substantially parabolic or substantially planar.

14. The method of claim 11, wherein the first molten salt solution comprises, based on 100 wt % of the first molten salt solution, from greater than or equal to 0.45 wt % to less than or equal to 0.85 wt % of the lithium salt.

15. The method of claim 11, wherein the first molten salt solution simultaneously contacts the existing first major surface and the existing first central surface area, the second molten salt solution simultaneously contacts the existing first major surface and the existing first central surface area, the substrate is substantially unstrengthened prior to the chemically strengthening the substrate in the first molten salt solution, and the second molten salt solution is substantially free of lithium before contacting the initially strengthened substrate with the second molten salt solution.

16. The method of claim 11, wherein the first maximum compressive stress of the first compressive stress region is from greater than or equal to 650 MegaPascals to less than or equal to 1300 MegaPascals, and a first central maximum compressive stress of the first central compressive stress region is from greater than or equal to 650 MegaPascals to less than or equal to 1300 MegaPascals, and wherein an absolute value of a difference between the first maximum compressive stress and the first central maximum compressive stress is from greater than or equal to 0 MegaPascals to less than or equal to 100 MegaPascals.

17. The method of claim 11, comprising a first depth of layer of potassium oxide in the first portion from the first major surface, a first central depth of layer of potassium oxide in the central portion from the first central surface area, wherein a ratio of the first depth of layer to the first central depth of layer is from greater than or equal to 0.7 to less than or equal to 1.5.

18. The method of claim 11, wherein the foldable substrate comprises:
a midpoint lithium difference defined as a central concentration of lithium oxide at a central midpoint of the central portion minus a first concentration of lithium oxide at a first midpoint of the first portion is from greater than or equal to 0.2 mol % to less than or equal to 2 mol %, wherein the central midpoint is midway between the first central surface area and the second central surface area, and the first midpoint is midway between the first major surface and the second major surface in the first portion; and
a central surface larger alkali difference defined as a first central surface concentration of potassium oxide at the first central surface area minus a central concentration of potassium oxide at the central midpoint is from greater than or equal to 4 mol % to less than or equal to 14 mol %.

19. The method of claim 11, wherein the foldable substrate exhibits a central surface lithium difference defined as a first central surface concentration of lithium oxide minus the central concentration of lithium oxide at the central midpoint of the central portion is from greater than or equal to −0.5 mol % to less than or equal to 0.5 mol %, wherein the central midpoint is midway between the first central surface area and the second central surface area, and the first midpoint is midway between the first major surface and the second major surface in the first portion.

20. The method of claim 11, wherein the first outer thickness is from greater than or equal to 0.5 micrometers to less than or equal to 1.0 micrometer.
